(19) United States
(12) Patent Application Publication
(10) Pub. No.: US 2026/0076190 A1
(43) Pub. Date: Mar. 12, 2026

(54) RECONSTITUTED WAFER PRODUCT WITH VARIABLE THICKNESS DIES CONTAINING DIAMOND

(71) Applicant: Diamond Foundry Inc., South San Francisco, CA (US)

(72) Inventors: Martin Roscheisen, San Francisco, CA (US); Jeroen Van Duren, Fremont, CA (US); Liubo Hong, San Jose, CA (US); Michael Shirk, Brentwood, CA (US); Braden Henderson, Mountain View, CA (US); Peter Baumgart, Walnut Creek, CA (US); Tuan Mai, San Jose, CA (US)

(21) Appl. No.: 19/297,100

(22) Filed: Aug. 12, 2025

Related U.S. Application Data
(60) Provisional application No. 63/691,630, filed on Sep. 6, 2024.
(60) Provisional application No. 63/703,607, filed on Oct. 4, 2024.
(60) Provisional application No. 63/715,488, filed on Nov. 1, 2024.
(60) Provisional application No. 63/763,416, filed on Feb. 26, 2025.

(51) Int. Cl. H01L 23/373; H01L 23/00

(52) U.S. Cl. CPC H10W 40/254; H10W 72/0198

(57) ABSTRACT

A reconstituted wafer product may include a plurality of die structures bonded to a wafer in a manner that provides a thermally conductive connection between the wafer and the plurality of die structures. The wafer is compatible with semiconductor processing. Each die structure may include a die containing diamond bonded to a heatsink-side surface of the wafer. Two or more dies containing diamond in the plurality of die structures are of different thickness.

### CLAIM OF PRIORITY

This application claims the priority benefit of U.S. Provisional Application No. 63/763,416, filed Feb. 26, 2025, the entire contents of which are incorporated herein by reference. This application is claims the priority benefit of U.S. Provisional Application No. 63/715,488 to Martin Roscheisen et al. filed Nov. 1, 2024, the entire contents of which are incorporated herein by reference. This application claims the priority benefit of U.S. Provisional Application No. 63/703,607 to Jeroen K. J. Van Duren et al. filed Oct. 4, 2024, the entire contents of which are incorporated herein by reference. This application claims the priority benefit of U.S. Provisional Patent Application No. 63/691,630 to Jeroen K. J. Van Duren and Martin R. Roscheisen, filed Sep. 6, 2024, the entire contents of which are incorporated herein by reference.

### CROSS-REFERENCE TO RELATED APPLICATION

This application is related to U.S. Provisional Patent Application No. 63/539,983 to Jeroen K. J. Van Duren and Martin R. Roscheisen, filed Sep. 22, 2023, the entire contents of which are incorporated herein by reference. This application is also related to International Patent Application Number PCT/US23/86169 filed Dec. 28, 2023, the entire contents of which are incorporated herein by reference. This application is also related to International Patent Application Number PCT/US24/30242, filed May 20, 2024, the entire contents of which are incorporated herein by reference. This application is also related to U.S. patent application Ser. No. 18/761,091, filed Jul. 1, 2024, the entire contents of which are incorporated herein by reference.

### BACKGROUND

It is well known that diamond conducts heat very well and can serve as a heat spreader in electronics devices. This holds for both single crystal and polycrystalline diamond. It is advantageous to integrate a diamond layer between an integrated circuit device and a heat sink in a die stack. The advantage of integrating a layer of diamond, e.g., single crystal diamond (SCD), into a stack with an integrated circuit (IC) semiconductor die is that the diamond layer efficiently spreads the heat generated by the IC die during operation. Such heat spreading reduces the formation of localized “hot spots” that can negatively impact device performance, power consumption, and reliability.

Previous patent applications have focused on (1) integrating polished SCD dies into the final customer chip package, (2) “height matching” SCD-based dies with high-bandwidth memory (HBM) in an advanced package by use of a filler material instead of just thick SCD, since thick SCD is costly, and (3) introducing a “smoothening material” or “compliant bond material” to allow for less SCD polishing, since polishing SCD is difficult. Where polishing SCD dies is difficult, polishing large SCD wafers is even more difficult. Yet the infrastructure for semiconductor manufacturing is dominated by wafer processing, e.g., 300 mm diameter silicon wafers for CMOS designed for AI. Processing diamond dies, a foreign (non-silicon) material sized as a small plate instead of a round wafer poses integration challenges. Surprisingly, the thermal impact of the incorporation of an additional thin layer of silicon between a rough diamond and the integrated circuit is minimal on the benefit of the SCD heat spreading where the SCD roughness can even be beneficial. The benefit of SCD heat spreading can be further improved by tackling thermal resistance not just on a chip level or package level, but also on a system level.

It is within this context that aspects of the present disclosure arise.

### BRIEF DESCRIPTION OF THE DRAWINGS

FIG. 1 is a side cut-away view of diamond dies sandwiched between a first and second wafer with a gap filler material according to an aspect of the present disclosure.

FIG. 2 is a side cut-away view of diamond dies sandwiched between a first and second wafer with smoothening layers on the diamond dies according to an aspect of the present disclosure.

FIG. 3 is a side cut-away view of diamond dies coupled to a first wafer according to an aspect of the present disclosure.

FIG. 4 is a top-down cut-away view of a reconstituted wafer according to an aspect of the present disclosure.

FIG. 5 is a top-down cut-away view of a reconstituted wafer with a through-hole wafer gap filler according to an aspect of the present disclosure.

FIG. 6 is a side cut-away view showing a method for making a reconstituted wafer product with a through hole gap filler wafer according to an aspect of the present disclosure.

FIG. 7 depicts a side cut-away view of a reconstituted wafer with polished diamond dies on a carrier such as a tape in frame according to an aspect of the present disclosure.

FIG. 8 depicts a tape on reel delivery of diamond dies with cover tape according to aspects of the present disclosure.

FIG. 9 depicts another implementation of a reconstituted wafer without gap filler according to aspects of the present disclosure.

FIG. 10 shows a reconstituted wafer heat spreader product incorporated into a Chip on Wafer on Substrate (CoWoS) system stack according to an aspect of the present disclosure.

FIG. 11 shows a graph of absorption coefficient and penetration depth as a function of photon energy.

FIG. 12A is a side cut-away view of diamond dies sandwiched between a first and second wafer wherein each of the diamond dies are bonded in a deep pocket of the first wafer (logic side wafer).

FIG. 12B is a side cut-away view of diamond dies sandwiched between a first and second wafer wherein each of the diamond dies are bonded in a deep pocket of the second wafer (heatsink side wafer).

FIG. 12C is a side cut-away view of diamond dies sandwiched between a first and second wafer wherein the diamond dies are bonded in a shared shallow pocket of the second wafer (heatsink side wafer).

FIG. 12D is a side cut-away view of diamond dies sandwiched between a first and second wafer wherein each of the diamond dies are bonded in individual pockets in both the first wafer and the second wafer.

FIG. 12E is a side cut-away view of diamond dies sandwiched between a first and second wafer wherein each of the diamond dies are bonded in a shared pocket in both the first wafer and the second wafer.

FIG. 13 is a side cut-away view of diamond dies bonded in a deep pocket in the first wafer (logic side) which completely encompasses the thickness of diamond die and the second wafer is bonded to the first wafer via hybrid bonding or silicon to silicon bonding.

FIG. 14A shows a reconstituted wafer heat spreader product incorporated into a Chip on Wafer on Substrate (CoWoS) system stack with a jet impingement cooler implemented with lid and stiffener according to an aspect of the present disclosure.

FIG. 14B shows a reconstituted wafer heat spreader product incorporated into a Chip on Wafer on Substrate (CoWoS) system stack with a jet impingement cooler over the reconstituted heat spreader product according to an aspect of the present disclosure.

FIG. 14C shows a reconstituted wafer heat spreader product incorporated into a Chip on Wafer on Substrate (CoWoS) system stack with a jet impingement cooler over the reconstituted heat spreader product and HBM stacks according to an aspect of the present disclosure.

FIG. 14D shows a diamond die heat spreader product incorporated into an advanced chip package, e.g., CoWoS, with the jet impingement cooler directly spraying onto the diamond die surface according to an aspect of the present disclosure.

FIG. 14E shows a reconstituted wafer heat spreader product incorporated into an advanced chip package, e.g., CoWoS, with the sprayed surface of the impingement cooler below the surface of the surrounding HBM stacks according to an aspect of the present disclosure.

FIG. 14F shows a diamond die heat spreader product incorporated into an advanced chip package, e.g., CoWoS, with the jet impingement cooler cooling the logic elements and the HBM stacks simultaneously, yet with the sprayed surface of the logic elements below the top surface of the HBM stacks according to aspects of the present disclosure.

FIG. 15 shows a reconstituted wafer heat spreader product incorporated into a Chip on Wafer on Substrate (CoWoS) system stack with microchannel cooling integrated into the second silicon wafer (heatsink) according to an aspect of the present disclosure.

FIG. 16A depicts a reconstituted wafer heat spreader product incorporated into a Chip on Wafer on Substrate (CoWoS) system stack with immersion cooling according to an aspect of the present disclosure.

FIG. 16B depicts a reconstituted wafer heat spreader product incorporated into a Chip on Wafer on Substrate (CoWoS) system stack with hybrid jet impingement and immersion cooling according to an aspect of the present disclosure.

FIG. 17 shows a finished product of and method for creation of a full reconstituted wafer product from four smaller diamond wafers according to an aspect of the present disclosure.

FIG. 18 shows a plan view of a reconstituted wafer product having multiple die structures on a wafer, wherein the die structures include dies containing diamond.

FIGS. 19A-19F are side view cross-sectional schematic diagrams illustrating semiconductor device processing with a reconstituted wafer product of the type shown in FIG. 18.

FIG. 20A is a simplified side cross-section of a CoWoS package utilizing diamond containing dies according to an aspect of the present disclosure.

FIG. 20B is a simplified flow diagram depicting a generalized process for fabricating a CoWoS package utilizing diamond containing dies according to an aspect of the present disclosure.

FIG. 20C is a simplified flow diagram depicting a generalized plasma assisted bonding (PAB) process for fabricating a CoWoS package utilizing diamond containing dies according to an aspect of the present disclosure.

FIG. 21 is a flow diagram depicting a first simplified process for fabricating a CoWoS package utilizing diamond-containing dies sandwiched between two wafers according to an aspect of the present disclosure.

FIG. 22 is a flow diagram depicting a first simplified process for fabricating a CoWoS package in which individual die structures are bonded to a wafer according to an aspect of the present disclosure.

### DETAILED DESCRIPTION

### Introduction

It is often prohibitively expensive or impractical to fabricate an SCD wafer or polycrystalline diamond (PCD) wafer of certain standard semiconductor wafer diameters, such as 300 mm or 450 mm, with semiconductor surface specifications. According to aspects of the present disclosure, it would be desirable to produce a reconstituted wafer having an array of diamond (e.g., SCD or PCD) dies or diamond die stacks that can be shipped to a semiconductor device fabrication plant (sometimes called a “fab” or “foundry”) in a configuration that is compatible with semiconductor processing done by the plant. The same holds for shipping to Outsourced Assembly and Test (OSAT) facilities. As used herein, a “reconstituted wafer” refers to a wafer where multiple diamond (e.g., SCD or PCD) dies are placed on a temporary or permanent carrier wafer. There are a number of technical challenges to configuring and fabricating such a reconstituted wafer.

One challenge is to make the diamond die surface smooth enough for bonding and to make the diamond die thickness tolerance tight enough for bonding. In some implementations a smoothening layer or compliant layer may be used between the diamond die and the layers above and/or below it to ensure the desired smoothness and/or thickness tolerance.

Another challenge is that the surface of the diamond die or smoothening material may be incompatible with typical semiconductor fabrication processes. To address such challenges, in some implementations a wafer, e.g., a silicon wafer, may be bonded to the logic-facing surface of the diamond dies or die stacks and thinned, e.g., to <100 μm or <10 μm. The resulting stack may be easily bonded to a semiconductor wafer on which logic elements are formed. Making the wafer that is bonded to the diamond very thin adds little thermal resistance to the overall diamond die stack.

Yet another challenge is that the diamond dies or die stacks are typically placed on an underlying wafer (sometimes called a carrier wafer) with gaps between adjacent dies. Such gaps may present challenges during subsequent processing steps. For example, the gaps may lead to structural support issues, e.g., if the diamond dies or die stacks are covered by a layer of material that is thinner than the width of the gaps, or if the diamond dies or die stacks are placed on a wafer that is significantly thinner than the width of the gaps. Furthermore, the gaps may present problems of edge rounding during subsequent surface finishing steps, e.g., during chemical mechanical polishing (CMP). Additionally, the gaps may trap contaminants that are hard to remove. To address such challenges, the gaps may be filled with appropriate gap-filling materials.

It has further been realized that there is a need for a fabrication method for reconstituted diamond wafers with low thermal resistance, while simultaneously minimizing reconstituted wafer warpage, damage, and thermomechanical stress due to excessive thermal budgets during fabrication. As such, there is a need for a low-temperature reconstituted wafer fabrication method while ensuring low thermal resistance. Extremely high-force copper-to-copper thermocompression bonding (TCB) is typically not considered with IC logic wafers, yet suitable for passive stacks like the reconstituted wafer. The compressibility (malleability) of metals (especially after annealing to soften the metals) make metals the perfect low thermal resistance bond material for extremely high force, yet low temperature, bonding, but IC logic is susceptible to stress induced breakage and damage and therefore extremely high force bonding is not typically used in fabrication of fragile parts in IC related products, e.g., ultrathin IC wafers. The benefits of extremely high force metal bonding are minimizing voids around particles, ensuring improved bonding to diamond die edges despite CMP roll-off of metal films (e.g., copper) on diamond dies, reduced need of CMP due to improved compatibility with rougher surfaces, reduced sensitivity to metal oxides impeding metal interdiffusion, and bonding at lower temperatures avoiding excessive thermal stress due to CTE mismatch between high CTE metals and low CTE silicon and diamond. As a rule of thumb, high-force thermocompression bonding (TCB) allows for high thermal conductivity (low thermal resistance) bonds when using high purity single-element metals (e.g., copper, silver, gold, aluminum), whereas low-force bonding often results in deterioration of thermal conductivity of the bond, due to the use of multinary metals or compounds, e.g., multinary metals like solder, eutectics, transient liquid phase bond materials, or bonding with amorphous or polycrystalline materials. As an example, porous, low-k dielectrics in BEOL of IC wafers may be more vulnerable to damage due to bond force (pressure), and the gaps (pores) may reduce its mechanical properties by 50%, thereby reducing the damage threshold to e.g., below 50 MPa limit. Furthermore, strain engineering to enhance performance of transistors in CMOS is sensitive to externally applied stress. This lower damage threshold for IC wafers may not exist when bonding diamond by high-force metal bonding to silicon wafers into a reconstituted wafer thus aspects of the present disclosure may implement high force bonding techniques with the diamond dies and silicon wafers which were previously considered too damaging to use on IC related devices.

Historically, thermal management was tackled on a chip level, package level, and system level separately and sequentially in the design phase, since it was not considered high priority. Thermal issues have recently become high priority since it is limiting performance, reliability and energy efficiency of high-power advanced chip packages, e.g., AI chips. The need to reduce thermal resistance on a chip level, package level, and system level are more pressing than ever. Thermal resistance on a chip level can be reduced to a large extent by thinning the semiconductor wafer, e.g., by removing the silicon underneath the IC. However, the mechanical integrity of the thinned IC dies needs to be maintained, e.g., by bonding to another stiff material. However, this stiff material cannot add thermal resistance. Thermal resistance on a package level can be reduced to a large extent by reducing the need for a thick thermal interface material and by using improved heat spreaders, e.g., by bonding single crystal diamond heat spreaders directly to a thinned semiconductor IC die, thereby avoiding the thermal resistance of the thick semiconductor and the thick thermal interface material, while maintaining mechanical integrity of the IC die. Reducing thermal resistance on a system level needs a solution of direct cooling, e.g., jet impingement cooling, on to an improved heat spreader, e.g., single crystal diamond, with the SCD close to the heat producing IC. This low thermal resistance solution needs to be compatible with advanced chip packages.

According to aspects of the present disclosure, a large diameter (e.g., ≥300 mm diameter) product may be shipped to a fab as a reconstituted wafer, having diamond dies in various forms (e.g., with or without filler, with or without a smoothening layer, with or without a compliant layer) temporarily or permanently bonded to one or two wafers, e.g., single crystal silicon (sc-Si). One or both wafers may be thinned prior to shipping the reconstituted wafer to the foundry (fab) or OSAT, and/or thinned at the foundry (fab) or OSAT. Additionally, having an ultrathin silicon wafer (e.g., 10 μm or thinner) sandwiched between the diamond dies and the logic elements adds very minimal thermal resistance to the overall device stack. Similarly, the roughness of the diamond die does not negatively impact the performance of the reconstituted wafer heat spreader product. Shipping a 300 mm product helps with integration in a semiconductor 300 mm foundry (e.g., cleaning, thin film deposition, annealing, CMP, bonding), since these fabs typically have the infrastructure and experience to deal with 300 mm wafers but might not have infrastructure and experience to deal with diamond dies.

The following figures contain schematics that are not to scale.

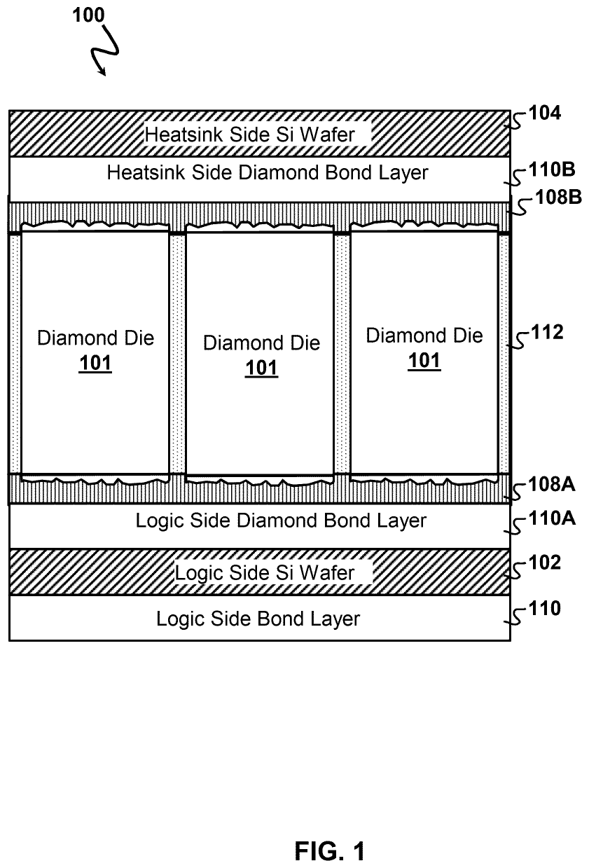

As shown in FIG. 1 one or more dies containing diamond 101, hereinafter diamond dies, may be sandwiched between a first wafer 102 and second wafer 104 to form a reconstituted wafer 100. In the implementation shown an array of diamond dies 101 having rough top and bottom surfaces may be coated with an adhesion layer. Adhesion layer materials include, for example and without limitation, Titanium, Titanium-carbide, Chromium, and Chromium-Carbide. In some alternative implementations the adhesion layer may be omitted. For example, and without limitation, a smoothening layer such as silicon (e.g., polycrystalline or amorphous) may not require the adhesion layer to be deposited on and may form strong bonds with the diamond dies. The diamond dies are arranged close together and their rough logic-side surfaces are coated with a continuous smoothening layer 108A. Here the smoothening layer partially fills gaps between each of the diamond dies creating a smoothened diamond die assembly. The resulting smoothened diamond die assembly is bonded to the first wafer 102 by a logic-side diamond bond material 110A; here the first wafer is the logic side wafer, which means that this wafer may be attached to another semiconductor wafer (not shown) on which integrated circuits are formed or will be formed. The second wafer 104 is referred to herein as the “heatsink-side” wafer, which means that this wafer may be attached to a heatsink, or a wafer on which a heat sink is or will be formed, or a temporary wafer that will be removed prior to introducing the heat sink.

The diamond dies, or dies containing diamond 101, may be single-crystal diamond (SCD), polycrystalline diamond (PCD), or composites of diamond with metals, e.g., a mixture of diamond and copper, or a mixture of diamond and silver, or a mixture of diamond and silicon carbide, or a mixture of diamond and silicon. A mixture might mean a random 3-dimensional distribution of one material in the other material. A mixture might mean an organized 3-dimensional structure of one material in the other material. A mixture might mean a combination of a random and organized distribution of one material in the other material. Similarly, diamond dies may be stacks of diamond with copper, or diamond with silicon carbide, or diamond with silicon, or diamond with aluminum. The diamond dies may be stacks that incorporate adhesion layers, diffusion barriers, smoothening layers, bond layers 110, 110A, 110B, filler materials for height matching in advanced chip packages, or precursors to bond line materials. As used herein the terms diamond die and dies containing diamond may be used interchangeably. In addition to the diamond dies, dummy dies may be placed in the reconstituted wafer product at locations corresponding to the location of logic elements that are not known good dies. This results in a reconstituted wafer product with diamond dies located at the position of known good dies, and dummy dies at the location of logic elements that are not known good dies. Dummy dies may be made out of any suitable thermally conductive material for example and without limitation, silicon. Additionally in some implementations, for stability, dummy dies may be placed in locations in the reconstituted wafer corresponding to empty spaces between the attached logic elements and/or locations that promote structural stability of the reconstituted wafer product. Composites of diamonds may be with copper, silver, gold, aluminum, or zinc. In some implementations the dummy dies may be placed near the edge of the wafer to accommodate gap filling. The crystal orientation of the main surface of the diamond dies may be for example and without limitation, (100), (110), (111), or (113). The crystal orientation of the edges of the diamond dies may be for example and without limitation, (100), (110), (111), or (113). The crystal orientation of the diamond dies may be chosen to enhance thermal performance, mechanical strength, reliability, or ease of integration of the heat spreader product.

The thermal resistance of the reconstituted wafer product from the logic side to the heatsink side when integrated into the final chip package may be less than 2000 m²-K/GW (2 mm²-K/W), more preferably less than 1000 m²-K/GW (1 mm²-K/W), even more preferred less than 500 m²-K/GW (0.5 mm²-K/W). It should be noted that the thermal resistance for the shipped product may be higher, since the wafer on the logic side and/or the wafer on the heat sink side may be thinned at the customer (foundry) site prior to or after bonding to the logic elements. Alternatively, the shipped product may contain a temporary carrier with a temporary adhesive that may be removed at the foundry.

The thermal resistance of the wafers, adhesion layers, diffusion barrier layers, bond layers, smoothening layers, compliant layers, metal foils, filler materials, diamond dies, or other materials that may be used in the reconstituted wafer product and that may be in the path of heat transport may be designed and/or treated to reduce the thermal resistance. Thermal resistance may be reduced by reducing the thickness of the layer. Thermal resistance may be reduced by increasing the thermal conductivity of the layer, e.g., by selecting higher thermal conductivity materials. Thermal conductivity may be enhanced in each layer by selecting higher purity materials. Thermal conductivity may be enhanced by reducing crystal defects, e.g., vacancies, or interstitials, e.g., by annealing. Thermal conductivity may be enhanced by reducing the number of grain boundaries, e.g., by optimized deposition conditions, or by post-deposition treatments, e.g., laser annealing. Thermal conductivity may be enhanced by making the material more isotopically pure, e.g., by using isotopically enriched deposition materials. The directionality of the thermal conductivity of the layer may be controlled by controlling the layer's crystal orientation, e.g., by selecting an optimized wafer crystal orientation, or by optimized deposition conditions. Thermal resistance may be reduced by optimizing the structure of the interface, e.g., the roughness. Thermal resistance may be reduced by optimizing both the thickness and the interface structures of the various layers in the product. Additionally, the thermal resistance may be reduced by increasing the overlap in the vibrational Density of States (DOS) of adjacent layers, or the vibrational spectra, e.g., by taking into account the sound velocity, Debye temperature, and elastic modulus of the layers.

The logic-side wafer 102 may contain silicon (e.g., single crystal silicon) and may be permanently bonded to diamond dies 101. The logic-side wafer may contain silicon (e.g., single crystal silicon) and may be temporarily bonded to the diamond dies 101. The logic-side wafer 102 may contain glass or sapphire or silicon carbide or polycrystalline diamond and may be temporarily bonded to the diamond dies 101.

By way of example, and not by way of limitation, the heatsink-side wafer 104 may contain silicon (e.g., single crystal silicon) and may be permanently bonded to diamond dies 101. The heatsink-side wafer 104 may contain silicon (e.g., single crystal silicon) and may be temporarily bonded to the diamond dies 101. The heatsink-side wafer 104 may contain glass or sapphire or silicon carbide or polycrystalline diamond and may be temporarily bonded to the diamond dies 101. The heatsink-side wafer 104 (e.g., single crystal silicon) may be attached to the diamond dies 101 via thick copper foil.

In other non-limiting example implementations, the reconstituted wafer product 100 may be a permanent stack of a single crystal silicon wafer on the logic side, diamond dies between both wafers, and a single crystal silicon wafer on the heat sink side. The reconstituted wafer product may be a permanent stack of a single crystal silicon wafer on the logic side, diamond dies with copper foil facing the heat sink side, and a single crystal silicon wafer on the heat sink side. The reconstituted wafer may be a stack of a permanently bonded single crystal silicon wafer on the logic side, diamond dies with copper foil facing the heat sink side, and a temporarily bonded wafer (carrier) on the heat sink side.

The reconstituted wafer product 100 may have alignment marks or fiducials to aid accurate alignment during bonding to the logic elements. The alignment marks may be on one or both of the outer surfaces of the reconstituted wafers. The alignment marks may be on one or both of the inner wafer surfaces of the reconstituted wafers.

During production the logic-side wafer 102 may act as a carrier having a thickness of greater than 100 micrometers (microns). Later, after assembly, the logic side wafer may be thinned to less than 100 microns in thickness and in some implementations less than 10 microns in thickness. Before bonding the logic-side wafer 102 may be coated in a bonding layer 110A that is complementary to the smoothening material 108A. For example, and without limitation, if the smoothening material is copper then the bonding layer may also be copper such that the smoothening layer may be used with thermocompression bonding to bond copper on the wafer to copper on the diamond die.

In some implementations, according to aspects of the present disclosure, the locations of each of the diamond dies 101 may correspond to hot spots in logic elements of the targeted logic wafers. In some implementations, according to aspects of the present disclosure, the locations of each of the diamond dies may correspond to the locations of the IC (e.g., logic) dies of the targeted IC (e.g., logic) wafer. In some implementations, according to aspects of the present disclosure, the locations of each of the diamond dies 101 may correspond to the locations of the known good dies (KGD) of the targeted IC (e.g., logic) wafer. In some implementations, according to aspects of the present disclosure, the size of the diamond dies may correspond to the size of the IC (e.g., logic) die of the targeted IC (e.g., logic) wafer. In some implementations, according to aspects of the present disclosure, the size of the diamond dies may be slightly smaller than the size of the IC (e.g., logic) die of the targeted IC (e.g., logic) wafer. In some implementations, according to aspects of the present disclosure, the size of the diamond dies 101 may be slightly larger than the size of the IC (e.g., logic) die of the targeted IC (e.g., logic) wafer and partially or completely cover the dicing street width.

The gaps between adjacent diamond dies 101 are fully filled with a gap filling material 112. In some implementations the gap filling material may partially fill the gaps between the diamond dies 101 instead of completely filling them. As a non-limiting example, the gap may only be filled near the logic side wafer, e.g., filling the gap up to a height of 100 micrometers. As discussed below the gap filling material may be a raw or doped silica glass formed by methods such as spin on glass application. Alternatively in some implementations a through-hole wafer may be used as the gap filling material 112, e.g., a single-crystal silicon through-hole wafer. Furthermore, the gap-filling material may contain one or more of the following: a sol-gel, oxide powder, silicon powder, silicon carbide powder, copper paste or powder, silver paste or powder, graphite or carbon powder, solder, eutectic, brazing material, transient liquid phase precursors mixture, polymer, thermoplastic, curable adhesive (e.g., thermal, optical, or moisture curable), molding compound, epoxies, photoresists, benzocyclobutene (BCB) derivatives, spin-on photo-dielectrics, spin-on glass, polymer-derived ceramics, silicones, polybenzimidazole, or polyimides. In some implementations the gaps may be partially or completely filled by a powder, e.g., silicon powder, and subsequently the powder may be sintered or melted to a (porous) solid, e.g., by laser annealing. In some alternative implementations the gaps may be partially or completely filled by sintering, e.g., copper or silver sintering. Alternatively, the gaps may be partially or completely filled by a copper nanopowder followed by a flash lamp anneal, e.g., PulseForge. In yet other implementations the gaps may be partially or completely filled with a composite of silicon powder and sol-gel. In yet other alternative implementations, the gaps may be partially or completely filled with a composite of silicon powder and a curable adhesive. Alternatively, the gaps may be partially or completely filled with a composite of silicon powder and a thermoplastic. In yet other alternatives the gaps may be partially or completely filled with a composite of a curable adhesive and carbon powder. In some implementations the powder is part of a formulation that includes additives to control stability, e.g., surfactants, and application, e.g., rheology modifiers. A non-exhaustive list of additive examples include binders, anti-settling agents, dispersants, curing agents, anti-foaming agents, and thinners (e.g., solvents). In some preferable implementations, the gap filler is compatible with conventional silicon IC wafer dicing, e.g., the gap filler contains silicon. In some implementations, the gaps may be filled by one method, yet in other embodiments, the gaps may be filled by two or more methods of the above-described alternative methods. The two or more methods may be used sequentially inside the same gaps, or the two or more methods may be used at different locations, e.g., near the wafer center and near the wafer perimeter. In some implementations, the gaps may be filled after bonding the first wafer 102 to the second wafer 104. Filling the gaps post bonding may be performed from the side, e.g., with underfill materials. Filling the gaps post bonding may be performed by creating openings, e.g., round holes or slits, at the gaps between the diamond dies, either in the first wafer, second wafer, or both wafers, followed by depositing a material through the openings, e.g., by injecting or plating.

In implementations with very deep pockets that extend deeper than the height of the dies containing diamond gaps between the pocketed wafer and the second wafer the gaps may be filled with a gap filler material after bonding the pocketed wafer with the second wafer. For example and without limitation, openings may be created into the second wafer at or near each die location, preferably at the location of the dicing streets, and a thermally conductive material may be deposited into the gaps between the dies and the second wafer, e.g., plating of metal, such as copper. Alternatively, in some implementations the holes may be used as inlets and/or outlets for a fluid heat transfer medium as a form of microchannel cooling. In these implementations multiple openings may be created for each diamond die allowing multiple inlet and/or outlets for the fluid heat transfer medium.

A second smoothening layer 108B may be disposed on top of the diamond dies 101 and the gap filling material 112. The second smoothening layer herein may be referred to as the heatsink-side smoothening layer. A second wafer 104 referred to as the heatsink-side wafer may be coated with a heat-sink side diamond bond material 110B that is compatible with the heatsink-side smoothening layer 108B. Thus, a reconstituted wafer product 100 may be created having diamond dies 101 sandwich between two wafers 102, 104. This implementation creates a packaged diamond die product that is resistant to breakage and provides for ease of integration in other products.

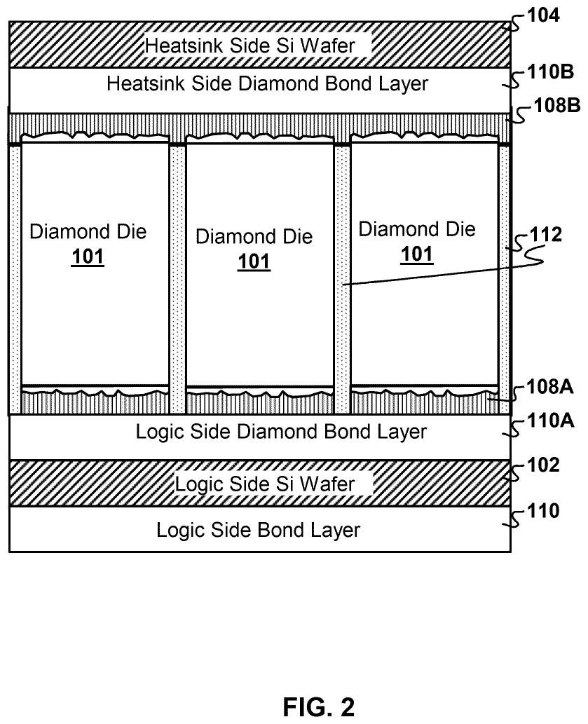

FIG. 2 depicts an alternative implementation of the diamond die package shown in FIG. 1. In this implementation each of the diamond dies 101 is individually coated with a smoothening material 108A. Subsequently each of the diamond dies 101 may be bonded individually with the logic side bond layer on the logic side wafer. As a result, the gap filler material 112 may be deposited in gaps in the smoothening layer 108A between the diamond dies 101 as well as the gaps between each of the diamond dies. Additionally in implementations that use a through-hole wafer gap filler the height of the wafer may be selected to accommodate the height of the diamond dies with the smoothening layer. This implementation may make it easier to accurately place the diamond dies onto the logic side wafer.

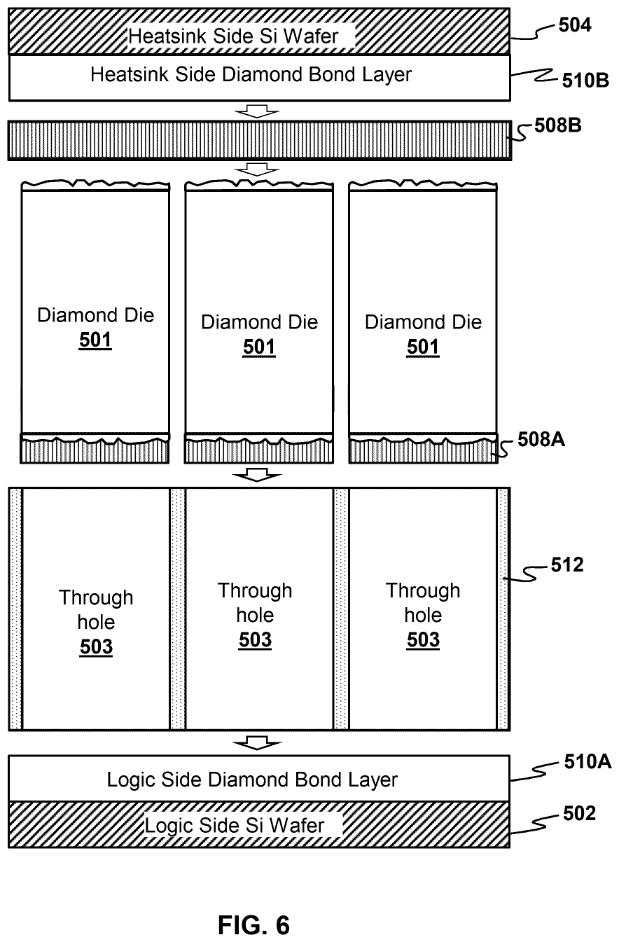

In some implementations, such as those discussed below with respect to FIG. 6, the diamond dies 101 may be inserted into corresponding openings in a through-hole wafer. The material of the through-hole wafer between the openings acts as a gap filler material 112. The diamond dies and through-hole gap filler assembly may be coated in a smoothening layer after the dies have been inserted into the through-holes.

In some implementations, without limitation, diamond dies 101 may be first coated on one or both sides with a smoothening material, e.g., copper, followed by an optional smoothening of one or both top and bottom surfaces, e.g., with CMP, followed by bonding to one of the wafers, e.g., the logic-side wafer 102, followed by depositing an optional gap filler 112 and optional planarization of gap filler, followed by deposition of an optional global smoothening layer 108B (in contrast to a local smoothening layer on each diamond die), followed by an optional smoothening of the global smoothening layer, followed by bonding to an optional second wafer, e.g., the heat sink side wafer 104.

In some implementations, without limitation, diamond dies 101 may first be temporarily placed on a temporary carrier, followed by deposition of a gap filler and an optional planarization of the gap filler, coated globally with a smoothening material, e.g., copper, followed by an optional smoothening of the global smoothening material, e.g., with CMP, followed by bonding to one of the wafers, e.g., the logic side wafer, followed by removing the temporary carrier, followed by deposition of a global smoothening layer, followed by an optional smoothening of the global smoothening layer, followed by bonding to an optional second wafer, e.g., the heat sink side wafer.

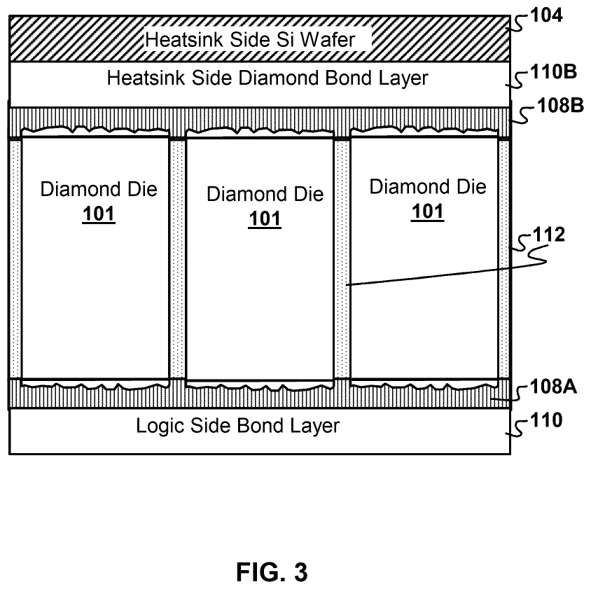

FIG. 3 depicts another alternative implementation of a reconstituted diamond dies wafer 300 according to aspects of the present disclosure. In this implementation the logic-side wafer is omitted as compared to FIG. 1. Instead, a bonding layer 110 is directly deposited on the smoothening layer 108A. This bond layer bonds the reconstituted wafer directly to the logic elements (not shown). The material of the bonding layer 110 is chosen to be compatible for bonding methods to the IC wafer as discussed in the bond sections.

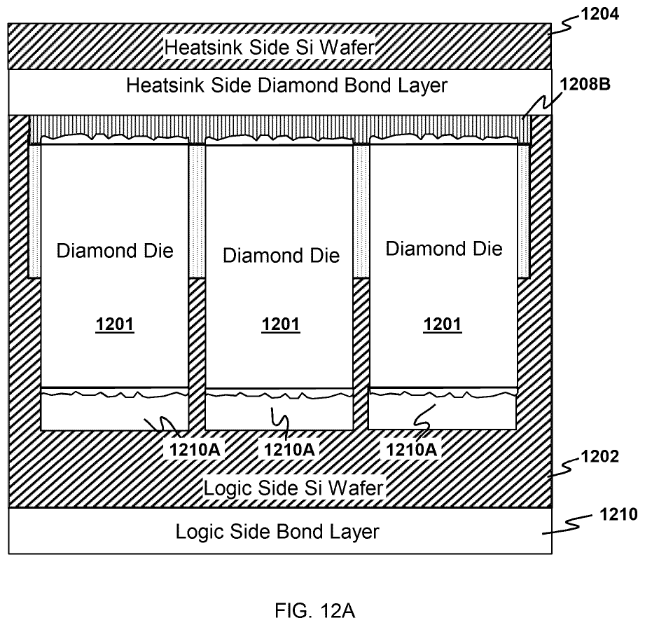

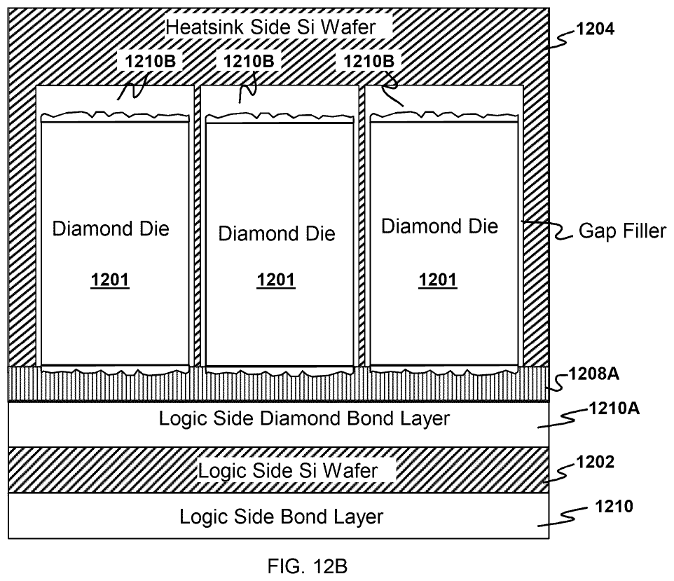

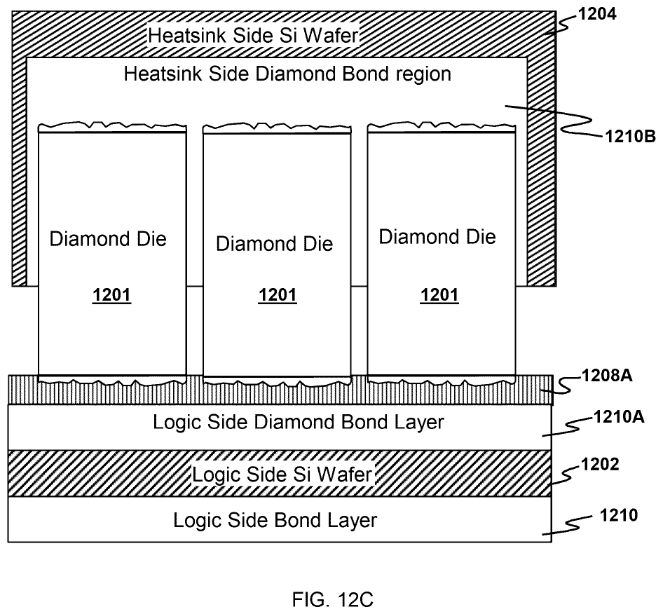

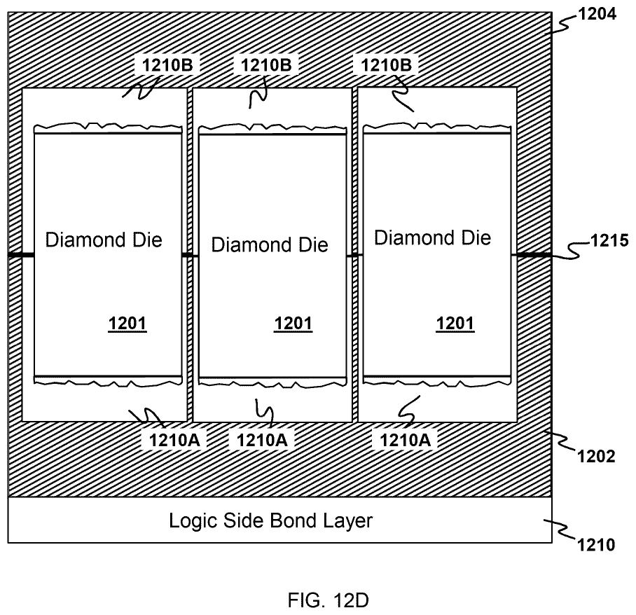

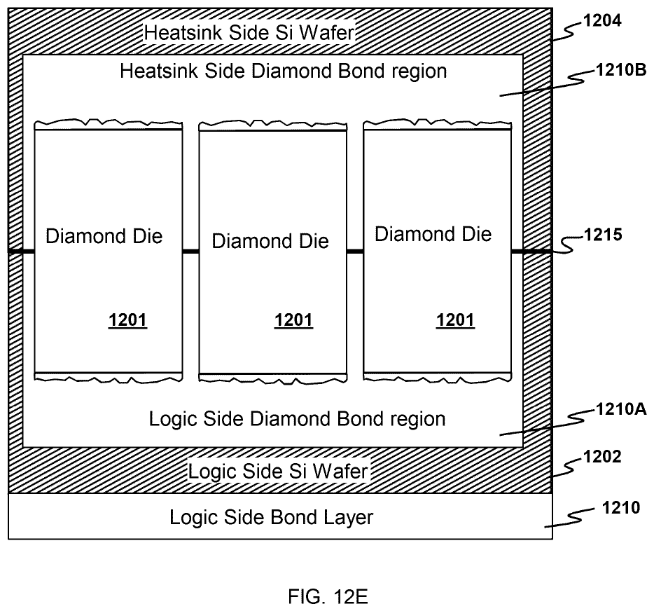

The diamond dies may be sunk into the logic side wafer into blind holes in the silicon wafers as depicted in FIGS. 12A-12E. Blind holes referred to herein as “pockets” may be manufactured on the side facing the diamond die 1201 in the logic-side wafer 1202 as shown in FIG. 12A, on the side facing the diamond die in the heatsink-side wafer 1204 as shown in FIG. 12B, or in both wafers as shown in FIG. 12D. The pockets may be below 10 micrometers deep, but more preferably over 100 micrometers deep, or even more preferred of similar depth as the diamond die thickness (greater than 90 percent of the thickness of the diamond die within the blind hole is referred to herein as a “deep pocket”), or roughly half the diamond die thickness in case of two pocketed wafers, or there may be many different pocket depths distributed over the total diamond die thickness in case of two pocketed wafers. In the example implementation shown in FIGS. 12C and 12E the diamond dies may be sunk into a shared pocket, that is, multiple diamond dies may be bonded to a wafer (either logic side or heatsink side or both) inside a single blind hole. Additionally, as depicted in FIG. 12C the diamond die may be partially sunk into one of the wafers in what is referred to herein as a “shallow pocket” which covers less than 90% of the diamond die. The other wafer may be a flat wafer bonded with a smoothening layer and bond layer similar to as discussed above or may be another wafer with a shallow pocket and the wafers 1202, 1204 bonded at an interface 1215 as shown in FIGS. 12D and 12E. As depicted in FIGS. 12A-12E the bond region or regions may be pockets in the wafer and may also include a bonding material. Alternatively, the bonding region or regions may be pockets of molten silicon that subsequently are recrystallized after the diamond die sunk into them and bonded as will be discussed.

In some implementations a copper foil may be present between the diamond die and the silicon wafer, the pocket depths may be adjusted to accommodate the sum of the diamond die and copper foil thickness. Alternatively, instead of copper foil, aluminum foil, or SiC may be used. As such, the silicon side walls of the pockets fill the gaps between the diamond dies of the reconstituted wafer. These gaps can be 100 micrometers wide or even a few 100 micrometers wide. The width of these gaps may be largely dictated by the wafer map and dicing process details related to the IC (e.g., logic) wafer. These silicon walls may provide mechanical support to the final reconstituted wafer, especially after thinning one or both of the wafers. Additionally, these walls may be in the path of dicing where the dicing equipment and process may be mostly designed to dice through silicon or silicon IC wafers. The pockets may be slightly larger in lateral dimensions than the diamond die to ensure ease of placement inside the pockets, e.g., 10 micrometers, preferably less than 5 micrometers, even more preferably less than 2 micrometers larger than the diamond die. The pockets, e.g., corners or sidewalls, may be used in conjunction with cameras to enhance placement accuracy of the diamond dies. Additionally, the pockets may be used as alignment marks to align the reconstituted wafer with the IC (e.g., logic) wafer. The bonding material (e.g., copper foil, aluminum foil, etc.) may fill the entire pocket after bonding or may be located in a portion of the pocket for example and without limitation, the bottom of the pocket.

The pockets may be created in the bulk material of the wafer, e.g., silicon. Alternatively, these pockets may be created in a top layer containing at least one of the following: silicon, germanium, aluminum, tin, copper, silver, gold, zinc, silicon carbide, silicon oxide, a sol-gel, polymer, thermoplastic, curable adhesive, molding compound, epoxies, photoresists, benzocyclobutene (BCB) derivatives, spin-on photo-dielectrics, spin-on glass, polymer-derived ceramics, silicones, or polyimides. For example, and without limitation, a metal foil may be attached to the wafer, and subsequently pockets are created inside the metal foil, e.g., copper foil, or aluminum foil. The metal foils may be annealed to reduce hardness and tensile strength, and increase ductility, and make the foil softer. In yet another example, a metal layer is deposited onto the wafer, e.g., by plating, and the pockets are created in the deposited layer. The pockets may be created by removing material from the bulk wafer or the top layer, or the pockets may be created by additive manufacturing.

These pockets may be created by removing silicon by mechanical means, e.g., by computer numerical control (CNC) machining, or by optical means, e.g., by laser ablation. Alternatively, these pockets may be created by photolithography and etching. Etching may be performed by wet or dry etching. A hard mask may be formed prior to etching. Wet etching may be isotropic, yet preferably anisotropic. The most common isotropic etchants are a combination of hydrofluoric acid, nitric acid, and acetic acid (HNA); the most common anisotropic etchants are potassium hydroxide (KOH), ethylenediamine pyrocatechol (EDP), and tetramethylammonium hydroxide (TMAH). The wet etching agents may be sprayed onto a rotating wafer. The reaction rate may be roughly 10 micrometers of silicon removal per minute. Alternatively, electrochemical etching may be used. Dry etching may be performed by reactive ion etching (RIE), deep reactive ion etching (DRIE, e.g., the Bosch process), inductively coupled plasma (ICP) etching, or electron cyclotron resonance etching (ECR), typically with fluorine-based gasses. RIE, DRIE, ECR, and ICP are preferred due to their anisotropic nature. Alternatively, plasma etching is used, albeit less preferred due to its isotropic nature. Other dry etching methods that may be used are ion beam etching (IBE), cryogenic RIE, high-density plasma (HDP) etching, atmospheric downstream plasma dry chemical etching (ADP DCE), microwave plasma etching, or electron enhanced material processing (EEMP). Alternatively, these pockets may be created by a combination of two or more of the above methods.

The silicon may be resistive, lightly doped, or heavily doped, albeit preferably not heavily doped. The silicon may originate from silicon ingots grown by the Czochralski (CZ) method or the Float Zone (FZ) method. Furthermore, the silicon may have a typical orientation of (100), (111), or (110). The (100) orientation may be preferred for anisotropic wet etching and is most readily available. The (111) orientation may be preferred for mechanical stability after thinning. The (110) may be preferred for the combination of mechanical stability, smoothness, and anisotropic etch ratio. The silicon may have a preferred crystal orientation that promotes bonding by e.g., promoting the preferred crystal orientation of the bond layers, e.g., by promoting a preferred crystal orientation of the seed layer prior to plating, e.g., to form nanotwinned (111) oriented copper bond layers. The silicon thickness may be a standard thickness, e.g., 775 μm thickness for 300 mm diameter wafers. Alternatively, the silicon thickness may deviate from the standard thickness to accommodate both the height necessary for the pockets, and additional thickness for ease of handling during the manufacturing process of the reconstituted wafers. Additionally, methods may be used to reduce wafer-edge defects to ensure high yield bonding to the IC (e.g., logic) wafers. These include techniques involving both wet and dry etching at the wafer edge, chemical mechanical polishing (CMP), edge deposition, and edge trimming steps. The silicon wafer may be a silicon-on-insulator (SOI) wafer. The silicon wafer may have an epitaxial film on the diamond side. Due to the requirements of semiconductor processing, metals and other bonding materials may need to be excluded from the wafer edges. This may be accomplished after bonding by masking and etching or machining a recess and then depositing compatible materials, e.g., polycrystalline silicon. Alternatively during the bonding stages, a masking material may be placed along the edge of the bonding interface and removed after bonding. The gap at the edge of the bonding interface may subsequently be filled with a filler material such as polycrystalline silicon.

In addition to the pockets, simultaneously or sequentially, via the same or similar processes, alignment marks may be created on one or both wafers to improve alignment with the IC (e.g., logic) wafer prior to or during the bonding process. The alignment marks may be located outside the diamond dies areas, e.g., near the perimeter.

The diamond dies may be bonded into the pockets by copper-to-copper bonding, e.g., by copper-to-copper thermocompression bonding (TCB), or copper-to-copper plasma-assisted bonding (PAB), or copper-to-copper surface activated bonding (SAB), or copper-to-copper atomic diffusion bonding (ADB), or copper-to-copper ultrasonic bonding, or by silver-to-silver bonding, e.g., silver-to-silver TCB, SAB or ADB, or by gold-to-gold bonding, e.g., gold-to-gold TCB, SAB, or ADB, or by aluminum-to-aluminum bonding, e.g., aluminum-to-aluminum TCB, SAB, or ADB. TCB may be referred to as solid-solid (inter) diffusion bonding or direct solid-state diffusion bonding. The bond temperature may be reduced by increasing bond force where more force reduces the need for temperature driven atomic diffusion. In some implementations the bond temperature may be reduced to 150 Celsius by passivation layers or cap layers, e.g., gold, on reactive metals like copper. Additionally, the bond temperature may be reduced by plasma passivation, e.g., by atmospheric plasma passivation with nitrogen or hydrogen. In other implementations the bond temperature may be reduced to 150 Celsius when the surface oxide, e.g., copper oxide, is removed prior to bonding, removal of the surface oxide may be performed by one or more of the following methods: wet treatment, e.g., acid treatment like citric acid treatment, dry treatment, e.g., forming gas treatment, or plasma treatment, or ion beam treatment, or vacuum plasma treatment, or atmospheric plasma treatment, etc. In yet other alternatives the bond temperature may be reduced by in-situ cleaning, e.g., oxide removal, and subsequent handling in inert environments prior to bonding, e.g., to minimize surface oxide reformation. The bond temperature may also be reduced by use of self-assembled monolayers (SAM) of alkane-thiols with the aim to protect the metal surface, e.g., copper, against excessive oxidation in metal-to-metal bonding. In some implementations, the bond temperature may be reduced to 150 Celsius by grain size and orientation control, e.g., by using nanotwinned (111) copper at the bond surface. The bond temperature may be reduced to room temperature by using SAB or ADB. In other implementations, the bond temperature may be reduced to 150 Celsius by use of ultrasonics. It should be understood that any of the above-described alternatives for reducing bonding temperature may also be used in combination with each other where compatible.

The diamond dies 1201 may be bonded into the pockets by silver sintering or copper sintering. Alternatively, the diamond dies may be bonded into the pockets by brazing, e.g., with Cu-ABA at 1025 Celsius. In yet other alternative implementations the diamond dies may be bonded into the pockets by eutectic bonding, e.g., the aluminum-silicon eutectic (e.g., 88.3Al/11.7Si by wt.-%) at bond temperatures of roughly 575 Celsius, or e.g., the aluminum-germanium eutectic (e.g., 55Ge/45Al by wt.-%) at bond temperatures of roughly 425 Celsius, or e.g., the zinc-aluminum eutectic (e.g., 95Zn/5Al by wt.-%) at bond temperatures of roughly 385 Celsius.

The diamond dies may be bonded into the pockets by transient liquid phase bonding (TLPB, also referred to as solid-liquid interdiffusion bonding or SLID bonding, or isothermal solidification), e.g., nickel-tin TLPB at bond temperatures of roughly 300 Celsius, or e.g., copper-tin TLPB at bond temperatures of roughly 280 Celsius, or e.g., silver-tin TLPB at bond temperatures of roughly 250 Celsius, or e.g., gold-indium TLPB at bond temperatures of roughly 200 Celsius, or e.g., silver-indium TLPB at bond temperatures of roughly 180 Celsius. TLPB (or SLID bonding) may be achieved by depositing films, e.g., by plating or PVD, of different compositions on each bonding surface, e.g., nickel on one surface, and tin on the other surface. Alternatively, by depositing nickel on both surfaces, and tin on one or both surfaces. Alternatively, TLPB may be achieved by using a paste containing a mixture of nano-sized or micron-sized powders of different compositions, e.g., a mixture of copper-based and tin-based powders. In yet another example, TLPB may be achieved by depositing one or more thin films, e.g., by plating or PVD, on one or both surfaces, in combination with a paste or a foil of a different composition, e.g., silver films in combination with an indium foil. Pastes may be applied by a multi-step process where after paste application, a heating step may be implemented prior to bonding to remove most or all of the volatiles, e.g., organics. TLPB may be based on binary systems, e.g., nickel-tin, copper-tin, gold-tin, silver-tin, copper-indium, gold-indium, silver-indium, copper-gallium, etc. or multinary systems, e.g., copper-bismuth-tin, copper-bismuth-indium, copper-indium-tin, etc. In some implementations, the bond temperature may be reduced by replacing indium with a mixture of indium and bismuth, e.g., the eutectic with a solid-to-liquid temperature of 109 Celsius. In some embodiments, other fusible alloys may be used, e.g., bismuth-containing eutectic fusible alloys, e.g., the eutectic bismuth-tin alloys (e.g., Bi58Sn42 by weight with eutectic temperature of 138 Celsius). Various bond techniques may be aided by ultrasonics, e.g., TLPB may be aided by ultrasonics to increase the shear strength, e.g., ultrasound-induced TLPB, solder bonding may be supported by ultrasonics, etc. TLPB may be performed above or below the melting point of the low-melting metal.

Bonding may involve a low temperature, e.g., below 100 Celsius, or room temperature, e.g., around 25 Celsius, pre-bonding step, e.g., a cold-welding step, prior to a subsequent high temperature, e.g., at or above 150 Celsius, bonding step, e.g., with force, and/or anneal step, e.g., without force. The cold welding may involve gold layers, e.g., gold cap layers on each surface. Alternatively, the cap layer may be silver, titanium, manganese, or palladium. In some implementations the grain size and grain orientation may be controlled to improve bond strength (e.g., nanotwinned (111) copper). Surface contaminants like oxides may be removed by wet and dry cleaning, e.g., a citric acid clean to remove surface copper oxides. In some implementations, surface contamination (e.g., oxides) may be removed by a plasma, a beam, a flux less vapor (e.g., formic acid vapor or anhydrous HF vapor) or atomic layer etch with halogens (e.g., HF, Cl₂). In some implementations, the surface oxide may be removed by annealing prior to bonding, e.g., vacuum annealing. In some implementations, the metal surface may be passivated by an atmospheric plasma (e.g., a helium (He) plasma containing nitrogen). The gold layer may be 25 to 100 nanometers (nm) thick. In general, noble metals may be used as a cap layer on more reactive metals, e.g., copper, to avoid reaction of the more reactive metal with the atmosphere, e.g., oxidation. A thin diffusion barrier, e.g., titanium, may be used in between the more reactive metal, e.g., copper, and the cap layer, e.g., gold. After pre-bonding, and final bonding, the cap layer may have diffused into the more reactive metal.

The diamond die may be bonded into the pockets by wafer surface melting, e.g., by laser assisted heating or laser assisted bonding (LAB), e.g., excimer laser heating, or Continuous-Wave (CW) laser heating. Lasers may be high powered, e.g., one kilowatt or higher. The lasers may be any suitable type of laser for example and without limitation, gas lasers (e.g., excimer, or CO₂), fiber lasers, diode lasers, diode pumped lasers, flashlamp pumped lasers, or pumped solid state lasers, e.g., diode-pumped solid-state lasers. Excimer laser heating may be by high-power (e.g., kW), 1-100 nanosecond pulse length, UV lasers. Excimer laser annealing is commonly used in the display industry to convert CVD-Si thin films on glass substrates deposited at low CVD temperature to high-performance polycrystalline silicon transistors. CW laser assisted bonding may be accomplished by high-power (e.g., kW), 10's millisecond pulse length, blue lasers. CW lasers may be green lasers. LAB may be by solid-state diode lasers, fiber lasers, or infrared (IR) lasers. LAB may be by lasers with microsecond pulse lengths. LAB may be by Quasi-CW (QCW) fiber lasers. LAB may be by high power CO₂ lasers (e.g., 10.6 micrometers). The lasers may reach the bond interface through the diamond dies, e.g., in case of a laser absorbed by the bulk of the silicon wafer. The laser energy may reach the bond interface through the silicon wafer, e.g., for wavelengths not absorbed by the silicon bulk, yet absorbed by an absorption layer at the bond interface. The absorption layer may be an IR absorbing layer. The absorption layer may be a doped silicon layer or a crystallographically modified silicon (Si) layer. The absorption layer may contain germanium, silicon carbide, amorphous silicon, or black silicon. The absorption layer may be deposited onto the pocketed silicon wafer by physical vapor deposition (PVD), or the absorption layer may be deposited onto the pocketed wafer by screen printing, or jetting, and may contain nanosized silicon particles, or nanosized carbon particles, or nanosized silicon carbide particles. Bonding of diamond dies by wafer surface melting may be performed by excimer laser annealing, blue or green CW laser annealing, QCW fiber laser annealing, flash lamp annealing (flash lamp assisted bonding, or FLAB), laser spike annealing, or rapid thermal processing (RTP), depending on the melting point, thermal conductivity, and absorption characteristics of an optional absorption layer, e.g., an absorption layer with a lower melting point than silicon with the absorption layer containing germanium, aluminum, tin, copper, silver, or gold, potentially mixed with silicon. Similarly, silicon on insulator wafers (SOI) may be used for bonding of diamond by wafer surface melting to further increase the temperature for the silicon on top of the oxide layer due to the thermal resistance of the oxide, prior to the oxide layer partially or completely getting disrupted or dissolved due to the excessive heat. The diamond dies bonding based on silicon surface melting may be performed in an inert or a forming-gas atmosphere (e.g., a mixture of hydrogen and nitrogen gas), e.g., an inert gas purged atmosphere (e.g., argon, or nitrogen), or a vacuum atmosphere. Controlled pressure to promote bonding may be applied to the interface during the diamond dies bonding based on silicon surface melting, e.g., incorporating appropriate optically transparent materials to exert that pressure, and adapting their mounting for that functionality. Optically transparent (may include beyond the visible spectrum range) materials may be, without limitation, silica, sapphire, diamond, or silicon carbide. Diamond die roughness may act as a diffuser, e.g., with a collimated beam, and may achieve sufficient power density and a sufficiently high temperature in an extended area, e.g., the entire area of a diamond die. To further control the temperature depth profile, a combination of two or more of the above heat sources may be applied simultaneously, or sequentially, e.g., a hybrid system with the use of a short (e.g., UV) and long (e.g., IR) wavelength heat source. Laser bonding may be aided by ultrasonics, e.g., ultrasonic-assisted laser bonding. Alternatively, the diamond dies may be bonded to one or both wafers without pockets by wafer surface melting, e.g., by laser assisted heating or laser assisted bonding (LAB), as described above. After LAB the diamond bond regions may contain recrystallized silicon thus leaving areas of recrystallized silicon underneath and (in some implementations) around the diamond dies. In some implementations, bonding by wafer surface melting is performed with diamond dies coated with thin films, e.g., a smoothening layer, or a thin film aiding in bonding. In some implementations, bonding by wafer surface melting is performed with heat absorption layers deposited onto the wafers, or both the diamond dies and wafers. In some implementations of bonding by wafer surface melting, the wafers have no pockets. LAB may be performed in air by rastering a small laser spot (e.g., 0.1 mm) over the diamond surface while the diamond is compressed against the wafer by 10 MPa pressure or higher. LAB may be performed in air by full-area exposure of a large laser beam of the same size or larger than the diamond die. LAB may be performed in vacuum with a laser beam of the same size or slightly larger than the diamond die with the diamond pressed against the wafer by 10 MPa or higher. LAB may be performed by repetitive exposure to one or more lasers. LAB may be performed with diamonds that are smooth, e.g., Sa<100 nm, or Sa<5 nm, or Sa<0.5 nm. LAB may be performed with diamonds with a roughness of micrometers, e.g., Sa˜5 μm.

In some implementations, a smoothening layer on the rough diamond dies may be added, e.g., a thin silicon film (e.g., by CVD or PVD), optionally smoothened by CMP, optionally annealed to increase crystallinity and thermal conductivity, and in addition or instead of wafer surface melting, the thin film on the diamond dies may partially or completely melt and aid in bonding to the wafer. In some implementations, the smoothening layer on the diamond dies may be the heat source absorption layer and aid in the bonding to the wafer. In some implementations, the diamond dies are polished SCD dies with a heat source absorption layer aiding in bonding to the wafer. In some implementations the diamond dies may be polished with a surface roughness on at least one side of at least 2 nanometers or greater. In some implementations, the thin film on the diamond dies is a heat source absorption layer aiding in bonding to the wafer where the thin film, and optionally the wafer surface, may partially or completely melt under the influence of a heat source, e.g., laser assisted bonding (LAB) or flash lamp assisted bonding (FLAB), and the thin film contains silicon, germanium, copper, tin, aluminum, silver, or gold. In some implementations of bonding by wafer or diamond die surface melting, the wafers have pockets. In some implementations of bonding by wafer or diamond die surface melting, the wafers have no pockets.

Laser assisted annealing, rapid thermal annealing, flash lamp annealing, and similar heat sources may also be used to increase either the thermal conductivity or increase the bond strength, or both, for bonding diamond dies to wafers involving e.g., semiconductor bond or smoothening materials, metal-based bond or smoothening materials, or dielectric bond or smoothening materials.

Alternatively, the diamond dies may be bonded into the pockets by surface activated bonding (SAB), plasma assisted bonding (PAB), atomic diffusion bonding (ADB), solder bonding, ultrasonic bonding, thermosonic bonding, brazing, or adhesive bonding. PAB bond surfaces may be exposed to water or ammonia prior to bonding. Hydroxyl groups may be formed at the PAB bond surfaces prior to bonding, or amine groups may be formed at the PAB bond surfaces prior to bonding. Adhesive bonds may be created with e.g., SU-8 (negative photoresist), BCB (benzocyclobutene), a prepolymer of PDMS (polydimethylsiloxane), or a dry film resist, e.g., OrdyI® dry film. Ordyl® is a trademark of Elga Europe of Milan, Italy. Adhesives may be thermally cured at low temperatures, UV cured at low temperatures, or moisture-cured at low temperature. It should be understood that any of these listed types of bonding may also be used in combination, where compatible.

All bond surfaces, e.g., wafer, pocket, or diamond dies may be deposited by the necessary bonding materials, e.g., metallization for metal bonding, dielectrics for PAB or SAB. The deposited bond materials may include adhesion, diffusion barrier, and seed layers. All bond surfaces, e.g., diamond dies, may be deposited by the necessary smoothening materials, which may include adhesion, diffusion barrier, and seed layers. All bond surfaces may be deposited by compliant materials for bonding

Heat sources during bonding may be global, e.g., on a wafer level, or local, e.g., on a diamond die level. Local heat sources may be used to minimize the overall thermal budget to the reconstituted wafer in order to minimize damage or warpage, and may be used to minimize thermomechanical stress. Local heat sources may be provided by lasers. Alternatively, local heat sources may be, e.g., resistive heaters, lamp heaters, or inductive heaters. In yet another example, local heat sources may be ultrasonic sources. Yet in other embodiments, local heat sources may be multi-layer thermally reactive stacks or foils that provide instantaneous or extremely rapid heating, e.g., nickel and aluminum multi-layered stacks or foils. When activated by a small pulse of local energy from electrical, optical or thermal sources, the stack or foil reacts exothermically to precisely deliver localized heat up to temperatures of 1500° C. in fractions (thousandths) of a second, and will melt surrounding materials, e.g., solder, eutectics, or TLPB materials. These multi-layer thermally reactive stacks or foils may also be referred to as reactive nano-multilayers, self-propagating exothermic reaction (SPER) bonding materials, integrated reactive multilayer systems (iRMS), or a class of pyrotechnic materials. Alternatively, nano-thermites may be used as a local heat source, an intimate mixture of an oxidizer and a reducing agent, e.g., a metal fuel like aluminum, and an oxidizer like copper oxide. A reactive multi-layer stack for self-propagating exothermic reaction bonding may be fabricated by vapor-depositing thousands of alternating nanoscale layers of Aluminum (Al) and Nickel (Ni), either as a stack onto the wafer or the diamond die, or as a separate foil. By way of example, and not by way of limitation, an Al—Ni multi-layer thermally reactive foil is sold commercially under the name NanoFoil® by Indium Corporation of Clinton New York. Nanofoil® is a registered trademark of Thermal Conductive Bonding, Inc. of Sacramento, California. Other foil compositions may be boron-titanium, aluminum-titanium, titanium-silicon, or aluminum-palladium. In addition to the energetic multi-layer material other materials may be included in the stack that specifically melt, comply with surfaces, and react with the wafers or diamond dies to be bonded, e.g., solder, eutectics, or materials used for TLPB.

The pocketed wafers 1202, 1204 may be bonded to each other via the pocket walls by the same or an alternative bonding process as used for the bonding of the diamond dies into the pockets. The same holds for the sealing of the outer perimeter of the reconstituted wafer.

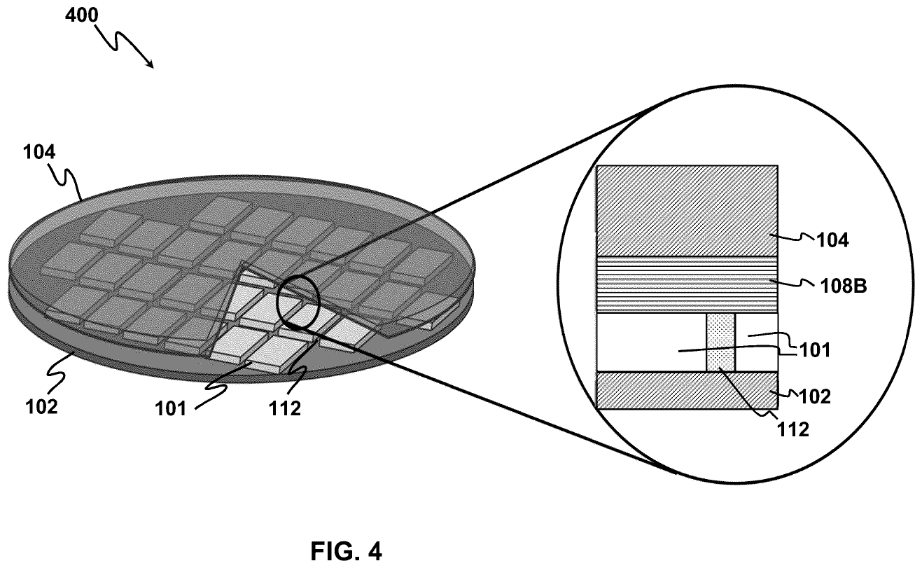

FIG. 4 is a top-down cut-away view of a reconstituted wafer 400 according to an aspect of the present disclosure. In this implementation the diamond dies 101 are disposed on the surface of the logic-side wafer 102. For ease of visualization the heatsink-side wafer 104 has been made to appear semi-transparent. Each of the diamond dies 101 is attached to the logic-side wafer 102, as discussed above. Between each of the diamond dies 102 a gap filling material 112 such as glass has been deposited or otherwise formed. While in this implementation the diamond dies 101 are arranged in a regular pattern on the logic-side wafer 102, aspects of this disclosure are not so limited. For example, and without limitation, the diamond dies 101 may be placed on the logic-side wafer 102 in locations corresponding to one or more hotspots of one or more logic elements which may be coupled to the logic-side wafer.

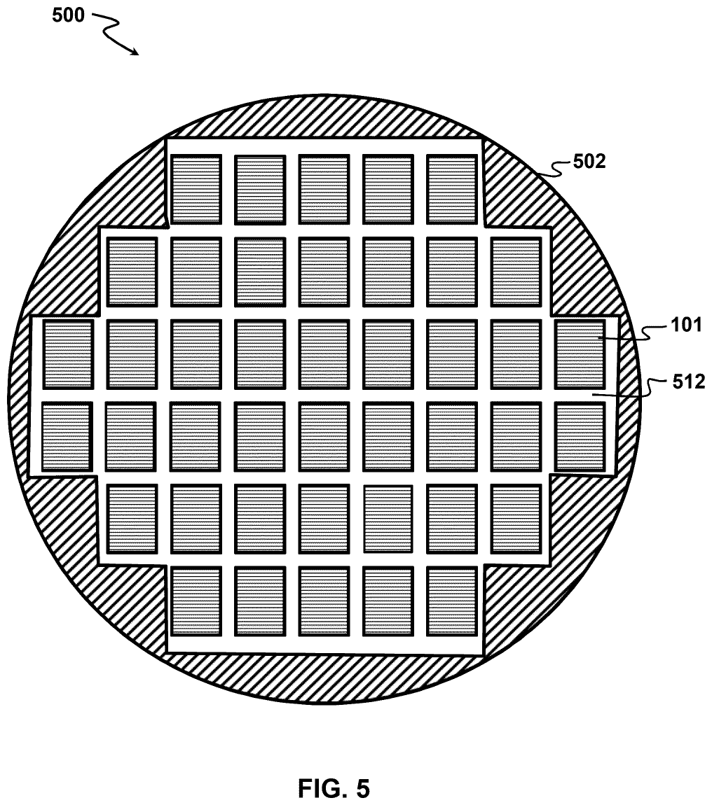

FIG. 5 is a top-down view of a reconstituted wafer 500 similar to that shown in FIG. 4, but with a through-hole wafer gap filler 512 according to an aspect of the present disclosure. As the name suggests, the through-hole wafer gap filler includes holes 503 which are configured, e.g., sized and shaped, to accept diamond dies 501. The dimensions of the holes may be chosen to snugly fit the diamond dies. Alternatively, the dimensions of the diamond dies may be slightly smaller than that of the holes to provide enough clearance that the dies fit easily into the holes. An adhesive material or filler may be placed around diamond dies in the holes to further stabilize the diamond die and gap filler assembly. The through-hole gap filler wafer 512 may be a silicon wafer fabricated by CNC machining or laser machining.

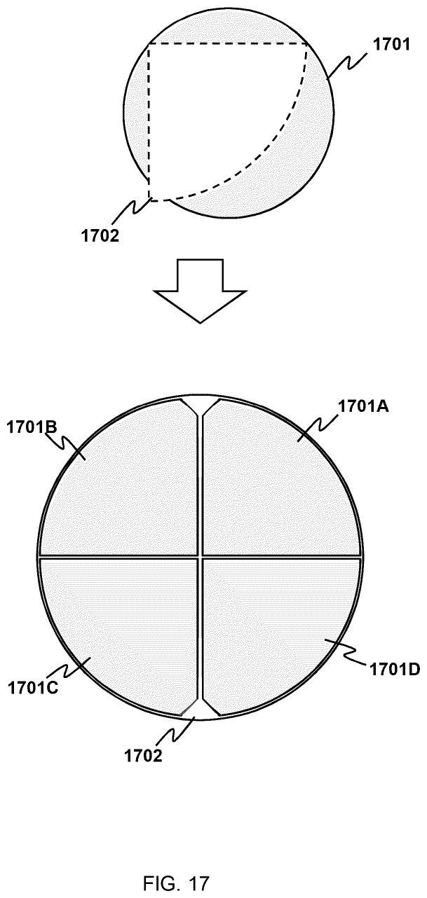

FIG. 17 shows a top-down view of finished product of and method for creation of a reconstituted wafer product 1700 from four smaller diamond dies 1701 according to an aspect of the present disclosure. In this implementation, a reconstituted wafer is for example and without limitation the largest size silicon wafer currently manufacturable which at the current time is around 300 millimeters (300 mm) in diameter. The current limit for creation of diamond dies is smaller than the limit for creation of silicon wafers, the current limit may be for example and without limitation around 200 millimeters in diameter. Thus, as shown, four diamond dies 1701A, 1701B, 1701C, 1701D may be aggregated to form a 300 mm reconstituted wafer by shaping each of the smaller diamond dies to form a quadrant sector 1702 of the larger 300 mm silicon wafer. Here, the quadrant sector of the silicon wafer does not completely fit within the silhouette of a diamond die 1701 and therefore a small corner is left out of the shaped diamond die sector. The diamond dies may be formed into quadrant-sized sectors 1701A, 1701B, 1701C, 1701D, for example and without limitation, by cutting and/or polishing the diamond dies. Each diamond die may be cut by, for example and without limitation, laser ablation, mechanical drilling and shaving, electrical discharge machining, chemical etching, etc. To perform Electronic Discharge Machining the diamond may be coated in an electrically conductive material or may be doped with boron or another dopant chosen to make the surface of the diamond electrically conductive.

Once the diamond dies have been shaped into quadrants 1701A, 1701 1792B, 1701C, 1701D they may be affixed to a silicon wafer. As shown the shapes of the aggregated diamond dies may result in a V shaped notch in two opposing sides of the reconstituted wafer. Generally this is not an issue for most uses as those areas may be used for identification notches and generally are not used for placement or formation of functional devices. As discussed below, in some implementations, the silicon wafer 1702 may be a pocketed wafer and the diamond dies may be sunk into the wafer. A second wafer may cover the top of the diamond dies encapsulating them between the first and second wafers.

These larger reconstituted wafers may be used for production of logic elements. For example and without limitation the full 300 mm reconstituted wafer may be used as a base substrate for the production of transistors such as Field Effect Transistors (FETs) (e.g., Metal Oxide Semiconductor FETs (MOSFET) s, Complementary MOSFETs (CMOS), Fin MOSFETs (FinFET) s, Gate-All-Around FETs, etc.), Integrated Gate Bipolar Transistors (IGBT) s, Bipolar Junction Transistors (BJT) s, transistors, diodes, or switches based on GaN (e.g., HEMTs), SiC, etc. These transistor structures may be formed in one side or both sides of the silicon wafer of the reconstituted wafer product. A problem with production of transistors in the reconstituted wafer is that generally these production processes are not compatible with metals or some bonding materials within the wafer. As such, the diamond dies may be bonded to the wafer via a compatible process such as laser melting or SAB.

In some implementations one or more through silicon vias (TSV) may be formed in the logic side wafer and the heatsink side wafer in areas between the one or more diamond dies. The TSV may be plated with a conductive material for example nickel, copper, tungsten, aluminum, or any combination thereof. The TSV may be used to provide frontside power and/or backside power to devices formed in the logic side wafer. In alternative implementations, through-diamond vias (TDVs) may be created.

FIG. 6 is a side cut-away view showing a method for making a reconstituted wafer product with a through hole gap filler wafer 512 according to an aspect of the present disclosure. In this implementation, a logic-side wafer 502 may be coated in a logic side diamond 510A bond layer 510A which is compatible with bonding to the diamond smoothening layer. Additionally, the logic side diamond bond layer 510A may be compatible with bonding to the through-hole gap filler wafer 512. In some implementations the through-hole gap filler wafer may also be coated in smoothening material or bonding material compatible with bonding with the bonding layer 510A.

Next, according to some aspects of the present disclosure the through-hole gap filler wafer 512 may be bonded to the logic-side wafer 502 with the bond layer 510A. Alternatively, the through-hole gap filler wafer 512 may be bonded to the logic-side wafer 502 after the diamond dies 501 have been bonded to the logic-side wafer. Alternatively, the through-hole gap filler wafer 512 is not bonded, and may be removed (e.g., used repeatedly). The through-holes 503 of the gap filler wafer 512 may be fitted over the diamond dies 501 allowing the gap filler wafer to make contact and bond with the bond layer 510A of the logic-side wafer 502. The through-hole gap filler wafer 512 may be made from silicon, e.g., single crystal silicon, or ceramics, e.g., sapphire, or silicon carbide. The through-hole gap filler wafer 512 may be manufactured by removing material from a solid wafer, e.g., by electrical discharge machining, laser cutting, water jetting, or water-guided laser cutting.

As discussed above, the diamond dies 501 may have their logic side bonding surfaces coated in a smoothening layer 508A. According to some aspects of the present disclosure an adhesion layer may be disposed on the diamond bonding surface prior to the creation of the smoothening layer to improve adhesion of the smoothening layer with the diamond die. Shown here the bottom of the diamond die 501 is the bonding surface for the logic side and may be rough. The smoothening material 508A may fill and even out the rough surface making it suitable for bonding. More commonly, the smoothening material is smoothened after deposition, e.g., by polishing or grinding. The diamond dies 501 may then be fitted into the through-holes 503 of the gap filler wafer 512, e.g., after placing the through-hole gap filler wafer onto the bond layer of the logic-side wafer 502. Sufficient pressure and heat may be applied to the diamond dies 501 to bond to the logic-side wafer 502 with the bond layer 510A along with the through-hole gap filler wafer 512 according to the selected compatible bonding method as will be discussed in the bond sections. Alternatively, the diamond dies 501 may be fit into the through-holes 503 of the gap filler wafer 512 with the through-hole gap filler wafer on a temporary carrier. The smoothening layer 508A may then be applied to the resulting diamond die and gap filler wafer assembly. The assembly may then be bonded to the logic-side wafer 502 with the logic side bond layer 510A. In some implementations after bonding the diamond dies 501 to the logic side wafer 502, the logic side wafer may be thinned to less than 10 or less than 100 microns in thickness. A temporary carrier may be adhered to the logic side wafer to improve stability for subsequent process steps. The temporary carrier may be removed after completion of the product.

After the diamond dies and gap filler wafer are bonded to the logic side wafer, a smoothening layer 508B may be applied to the heatsink side bonding surface of diamond dies 501 (shown here as the top) and the through-hole gap filler wafer 512. Alternatively, the smoothening layer may be applied to the heatsink side of the diamond die 501 prior to placement of the diamond dies in the through-holes 503 of the gap filler wafer 512. In such cases the through-hole gap filler wafer may be bonded to the heatsink-side wafer 504 without the smoothening layer 508B.

Prior to bonding with the diamond die and through-hole gap filler wafer assembly, the heatsink-side wafer 504 may have a heatsink-side diamond bond layer 510B applied to the diamond bonding side of the wafer. The heatsink side wafer diamond bond layer may be a material that is compatible with bonding to the smoothening layer 508B and, in some implementations, the bare gap filler wafer 512. After application of the bond layer, the heatsink-side wafer 504 with bond layer may be attached to the diamond die and gap filler wafer assembly by application of sufficient pressure and heat according to the selected compatible bonding method as will be discussed in the bond sections.

In some alternative implementations the diamond dies which are coated with a smoothening material may be bonded to the heat sink side wafer and the gap filler wafer may be bonded to the logic side wafer. The heatsink-side wafer and diamond die assembly may then have the diamond die porting inserted into the through-holes of the gap filler wafer on the logic side wafer and sufficient bonding pressure and heat applied to attach the two assemblies according to the chosen bonding method as discussed in the bond sections. Thus, may be created a reconstituted wafer product with a through hole gap filler wafer.

Dicing of the bonded pair of the IC (e.g., logic) wafer to the reconstituted diamond wafer may happen after bonding. Dicing of the bonded pair may be based on stealth dicing, plasma dicing, laser dicing, or saw dicing, or a combination. Dicing may happen in one step, or multiple steps, e.g., first dicing through the IC wafer from one side, and subsequently dicing the reconstituted diamond wafer from the opposite side. Dicing through the full thickness of e.g., the heatsink side wafer 504, may happen in steps, e.g., by adding groves or cracks into the wafer prior to assembling the reconstituted wafer, or prior to bonding the reconstituted wafer to the IC (e.g., logic) wafer. Similarly, thinning of the heat sink side wafer may happen prior to bonding to the IC (e.g., logic) wafer, or after bonding to the IC (e.g., logic) wafer.

Additionally, some implementations may require less packaging for the diamond dies. For example and without limitation, the diamond dies may be packaged bare on tape on reel or tape on frame assemblies. The diamond surfaces may be polished, or rough. The diamonds may be coated with a smoothening layer on top and/or bottom side. The smoothening layer may have been smoothened by polishing. The heat sink side of the diamond may be bonded to thick copper foil. The copper foil may be coated with silicon or bonded to silicon. The diamonds may be coated by the precursor to a thermally conductive, compliant material for bonding, e.g., a solder, eutectic, or the precursor to transient liquid phase bonding (TLPB).

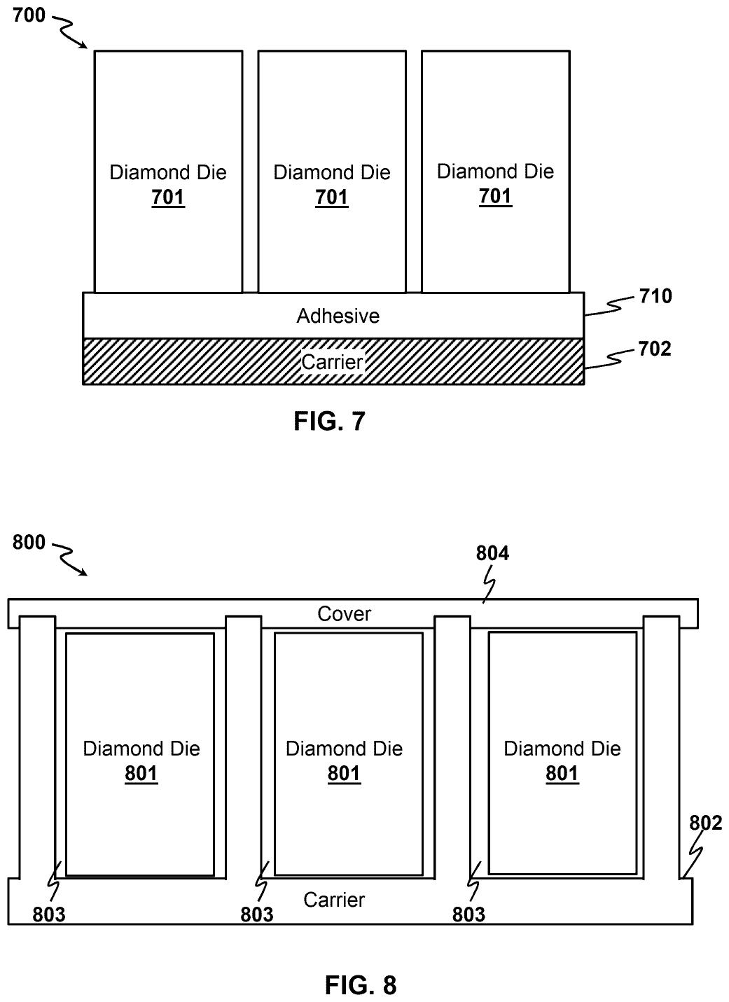

FIG. 7 depicts a side cut-away view of a reconstituted wafer 700 having polished diamond dies 701 on a carrier 702 such as a tape in frame or film frame according to an aspect of the present disclosure. In the implementation shown, the diamond dies 701 may be polished (for example less than 5 nanometers (nm) average surface roughness and less than 5 microns thickness variation) for ease of use. Alternatively, the diamond dies may have an unfinished roughness from production (for example and without limitation, between 100 nm and 300 nm average surface roughness and a thickness variation of between 5 microns and 30 microns), or a lapped finish (for example between 5 nm and 100 nm average surface roughness and less than 5 microns of thickness variation). An adhesive layer may be applied to the carrier 702. The polished diamond dies 701 may then be attached to the carrier with the adhesive. The carrier here may be flexible tape made from a material such as polyolefins, PVC, polyurethanes, or UV-curable tapes for film frame (tape in frame). Alternatively, the carrier 701 may be a rigid material for example and without limitation, a temporary semiconductor or glass wafer. The adhesive layer may be a layer of temporary adhesive such as for example and without limitation a UV curing adhesive tape or a solvent curing adhesive, or pressure sensitive adhesive, or a thermoplastic material. Temporary bonding may be performed by Van Der Waals bonding, e.g., plasma assisted bonding followed by a treatment to make the surfaces hydrophilic, or by adding amine groups to one or both surfaces. The temporary adhesive such as UV cure adhesive may provide for easy removal of the diamond die from the carrier by exposure of the adhesive to the curing agent e.g., UV radiation of the appropriate wavelength. Alternatively, a permanent adhesive may be used and in which case the permanent adhesive and carrier would have to be removed by destructive methods such as grinding and/or polishing.

FIG. 8 depicts a tape on reel delivery of diamond dies 801 with cover tape 804 according to aspects of the present disclosure. As shown in this implementation the carrier substrate includes multiple cavities 803 for diamond dies. The diamond dies 801 may be inserted into the cavities 803 and then covered with the cover tape 804. The carrier substrate 802 may be made from a flexible material for example and without limitation paper, or a plastic such as polycarbonate or polystyrene. Similarly, the cover tape may be made from a flexible material suitable for covering the diamond dies and attaching to dividers of the carrier. The cover tape may be made from for example and without limitation a heat activated plastic or a pressure sensitive adhesive with backing plastic.

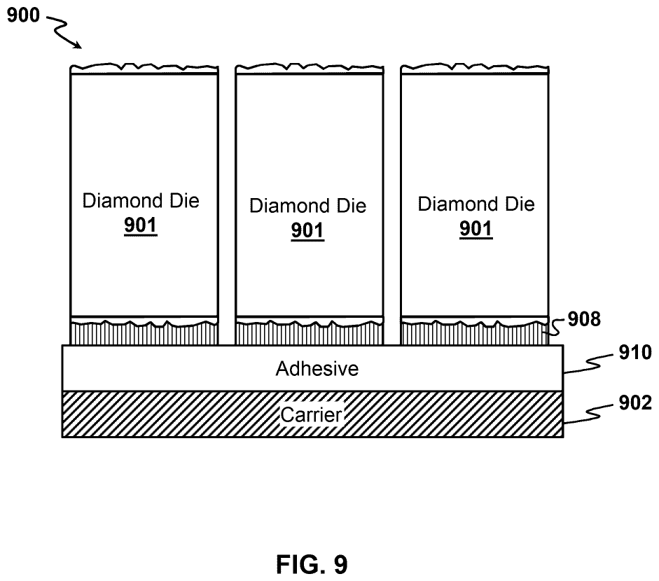

FIG. 9 depicts another implementation of reconstituted wafer 900 without gap filler according to aspects of the present disclosure. Here, the diamond dies 901 have at least one side coated with a smoothening layer 908. In some implementations the surfaces of the diamond dies on which the smoothening layer will be applied may be coated with an adhesion layer to improve the attachment of the smoothening layer to the diamond dies. The carrier may be any suitable rigid material for example in some implementations the carrier may be the logic side wafer or the heatsink side wafer. The carrier may be coated with an adhesive material. The adhesive material may be a UV curing adhesive, solvent curing adhesive, pressure sensitive adhesive, a thermoplastic material, or in some implementations adhesive material may correspond to a bond layer material as discussed above. The smoothening layer may then be attached to the adhesive. In implementations where the adhesive is a bond layer the smoothening layer may be permanently bonded to the carrier using the appropriate bonding method for the smoothening layer and bonding layer materials. As shown this implementation may omit the deposited gap filler material or gap filler wafer as it may provide for easier removal from the carrier and/or better suit requirements of the user.

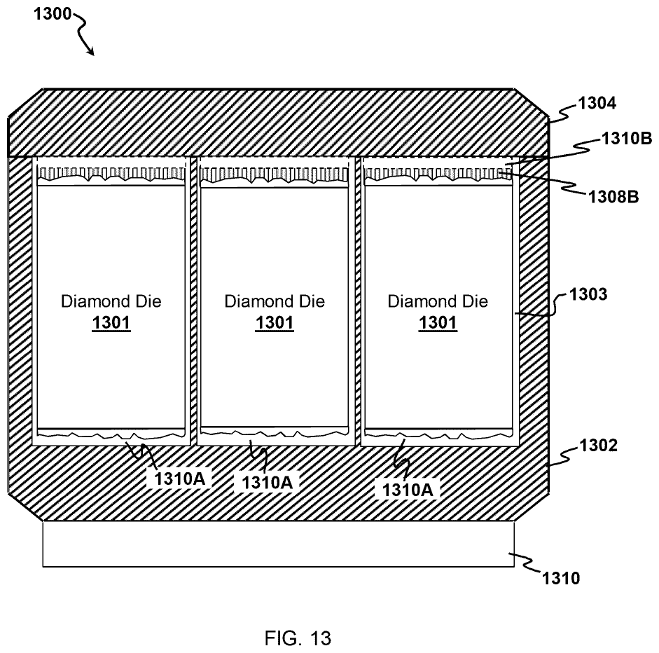

FIG. 13 shows an example of an implementation of a reconstituted wafer product 1300 in which diamond dies 1301 are bonded in a deep pocket in the logic-side wafer 1302. In this implementation, pockets 1303 formed in the logic-side wafer are deeper than the thickness of the diamond dies. Space between the sides of the diamond dies 1301 and sidewalls of the pockets 1303 may be filled with a gap-filling material, as discussed above. As may be seen in

FIG. 13, the pockets 1303 completely encompass the thickness of diamond dies 1301 and the heatsink-side wafer 1304 has no pockets. Aspects of the present disclosure, however, are not limited to such implementations. In alternative implementations, the deep pockets may be formed in the heatsink-side wafer. The diamond dies 1301 may be bonded to the logic-side wafer by bond regions 1310A. The heatsink-side wafer 1304 may be bonded to the logic-side wafer 1302 using a heatsink-side bonding layer 1310B, e.g., via hybrid bonding or silicon to silicon bonding. The logic side wafer 1302 may be attached to a semiconductor wafer or logic element by a bond layer 1310, e.g., a layer of metal such as copper or aluminum.

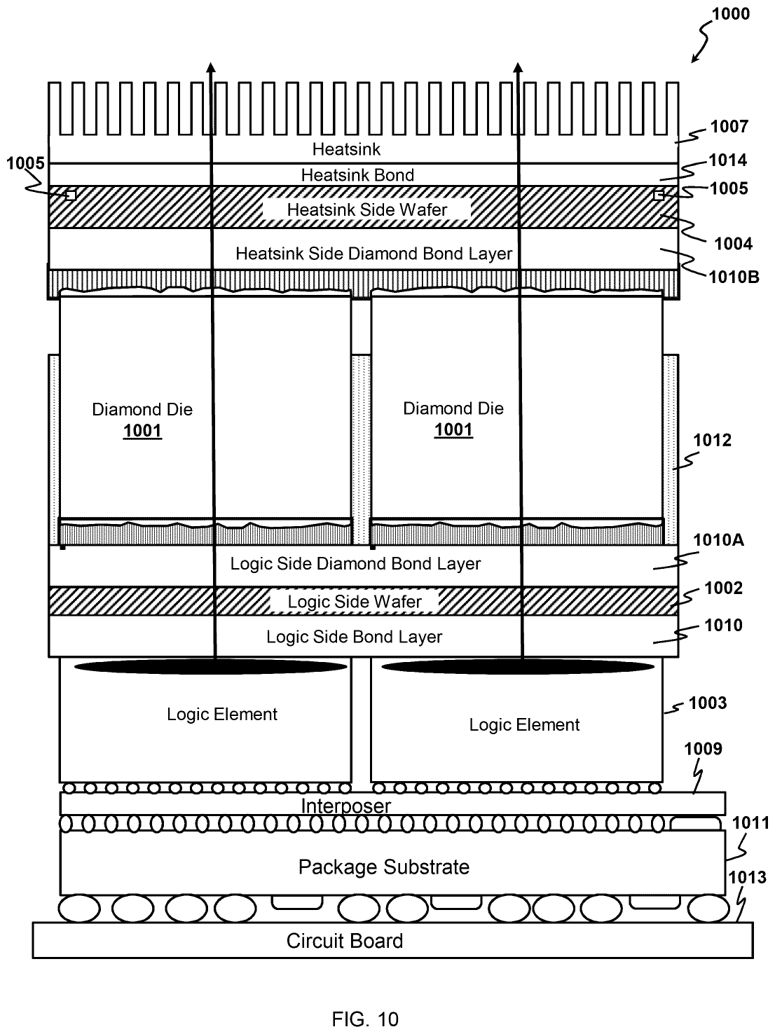

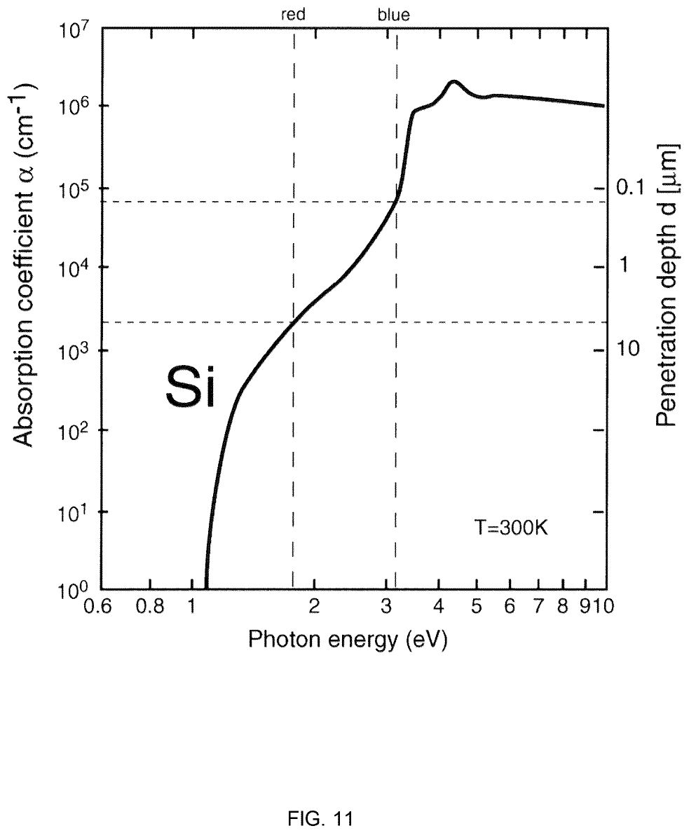

FIG. 10 shows a reconstituted wafer heat spreader product 1000 incorporated into a Chip on Wafer on Substrate (CoWoS) system stack according to an aspect of the present disclosure. As shown in this implementation the logic-side wafer 1002 of the product is bonded to logic elements 1003 with a logic side bond layer 1010. In some implementations, the heat spreader product 1000 may be fabricated using a diamond substrate coated with a precursor to a thermally conductive bond material where the thermally conductive bond material is compliant during bonding to a semiconductor device. The thermally conductive bond material may have thermal conductivity higher than 10 Watts per meter-kelvin) W/m-K after bonding. The bond material may contain lead, tin, indium, bismuth, zinc, gallium, or cadmium or combinations thereof. In some implementations, the bond material may be a eutectic or a transient liquid phase bond material. The precursor may contain copper, aluminum, gold, silver, nickel, silicon, germanium, lead, tin, indium, bismuth, zinc, gallium, or cadmium or combinations thereof.

The logic elements 1003 may be any (integrated) circuit device that produces heat for example and without limitation, transistors, switches, resistors, inductors, lasers, diodes, capacitors, voltage regulators, integrated circuit devices, central processing units (CPUs), graphics processing units (GPUs), tensor processing units (TPUs), neural processing units (NPUs), application specific circuits (ASICs), AI chips, system on chip (SoC), field programmable gate arrays (FGPAs), photonic integrated circuits and its components (e.g., laser, detector, waveguide, modulator), silicon photonics, memory devices, such as random access memory (RAM), static RAM (SRAM), dynamic RAM (DRAM), read-only memory (ROM), volatile memory, etc. The logic side bond layer 1010 may be any material suitable to create a heat conductive interface between one or more logic elements and the logic side wafer. In some implementations the logic side bond layer may be an adhesive or bonding material. In alternative implementations the bond layer may be omitted or may be a heat conductive material and the heat spreader product 1000 may be held in contact with the logic elements by a fastener or housing for the CoWoS system. In some implementations each entire logic element or a portion of each logic element may correspond to a hot spot in a larger integrated circuit device. Thus, the placement of the diamond dies may correspond closely with the location of these hotspots. For example, the diamond dies may be selectively placed to reduce the thermal resistance, thus limiting the temperature increase in the likely heat sensitive logic element 1003. The diamond dies may be attached to the logic-side wafer 1002 by a logic-side diamond bond layer 1010A. Similarly the diamond dies 1001 may be attached to the heatsink-side wafer 1004 by a heatsink-side diamond bond layer 1010B. Gaps between adjacent diamond dies 1001 may be fully or partially filled with gap filling material 1012.

The heatsink side wafer 1004 and/or logic-side wafer 1002 may include one or more alignment marks 1005 or fiducials as shown. The alignment marks may be deposited onto the wafer and/or etched into the wafer to aid in the placement and alignment of the diamond dies. The fiducials or alignment marks may help in aligning the heat sink side wafer to the logic side wafer, and may help in aligning the reconstituted wafer to the IC (e.g., logic) wafer. Alignment mark size, shape, location, material etc., may differ depending upon the chosen alignment system and/or the bonding material(s) chosen. For example and without limitation, an alignment system which uses Infrared (IR) detection for alignment may be incompatible with global metal (e.g., copper) bond layers as it reflects IR radiation, yet the metal may be locally removed or patterned. Alignment marks may be placed on the diamond side of the wafers, or alignment marks may be placed on the outer surface of the reconstituted wafer. In some implementations, the logic side wafer and/or heat sink side wafer may include an alignment feature, such as a D-cut or V-notch to facilitate alignment with other wafers during subsequent processing.

Additionally, as shown the heatsink side wafer of the product may be bonded to a heatsink with a heatsink bond layer, e.g., a metallized surface suitable for a thermal interface material (TIM), silver-filled epoxy, silver sintered bond layer, or copper sintered bond layer. Examples of thermal interface materials are indium-based TIMs, solder-based TIMs, liquid metal (e.g., gallium) based TIMs, etc. The heat sink side bond layer may be any material suitable to create a heat conductive interface between one or more heatsinks and the heatsink side wafer. In some implementations the heatsink side bond layer may be an adhesive or bonding material. In alternative implementations the heatsink bond layer is omitted or is a heat conductive material and the heat spreader product may be held in contact with the heatsink by a fastener or housing for the CoWoS system. The heat conductive material may be a thermal grease, thermal paste, thermal adhesive, thermal pad, carbon-based thermal interface material (TIM) (e.g., graphene or carbon nanotubes), or phase change material. The heatsink here may be any material or device having sufficient size, properties and/or configuration to absorb and/or carry heat away from the CoWoS system with heat spreader product. For example and without limitation the heatsink may be, a larger heat conductive surface (e.g., a metal surface), a finned heat conductive surface (e.g., air cooling finned heat sink), heat conductive surface with heat pipes, a heat conductive surface with one side exposed to a second moving heat transfer medium (e.g., water cooling heat sink), or a heat conductive surface exposed to a heat transfer medium which changes phase (e.g., phase change cooling, and evaporative cooling). The cooling (heat sinking) may happen by air cooling, vapor chambers, heat pipes, liquid cooling, spray cooling, immersion cooling, etc.

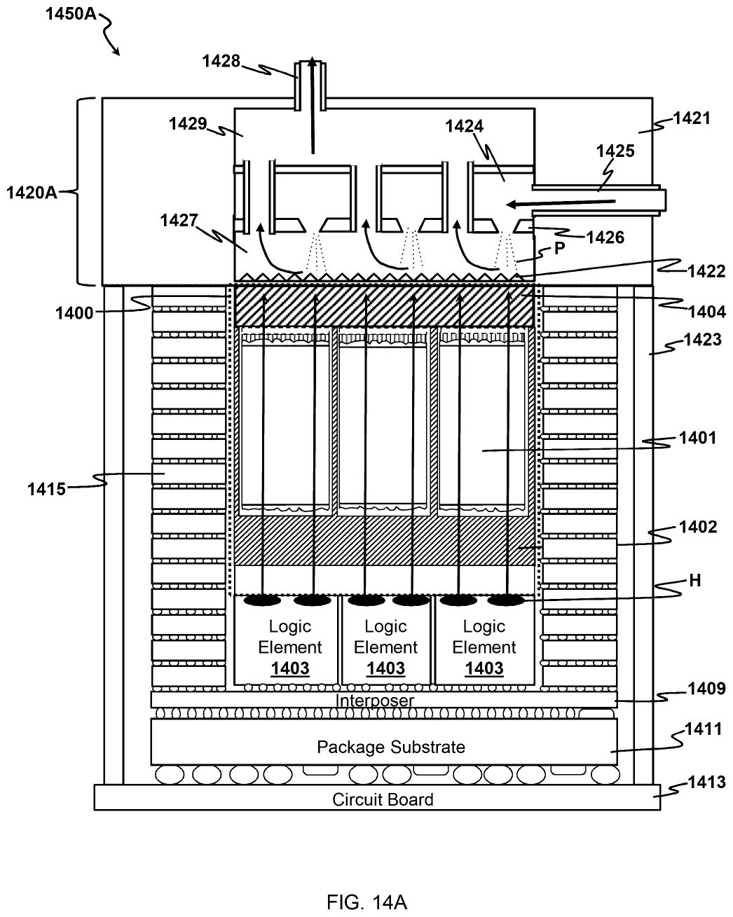

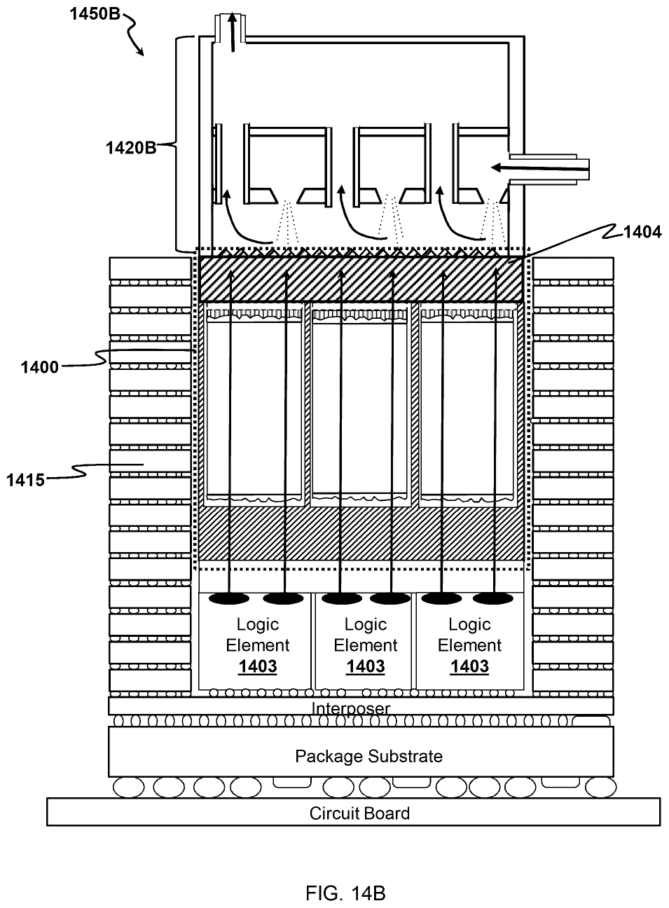

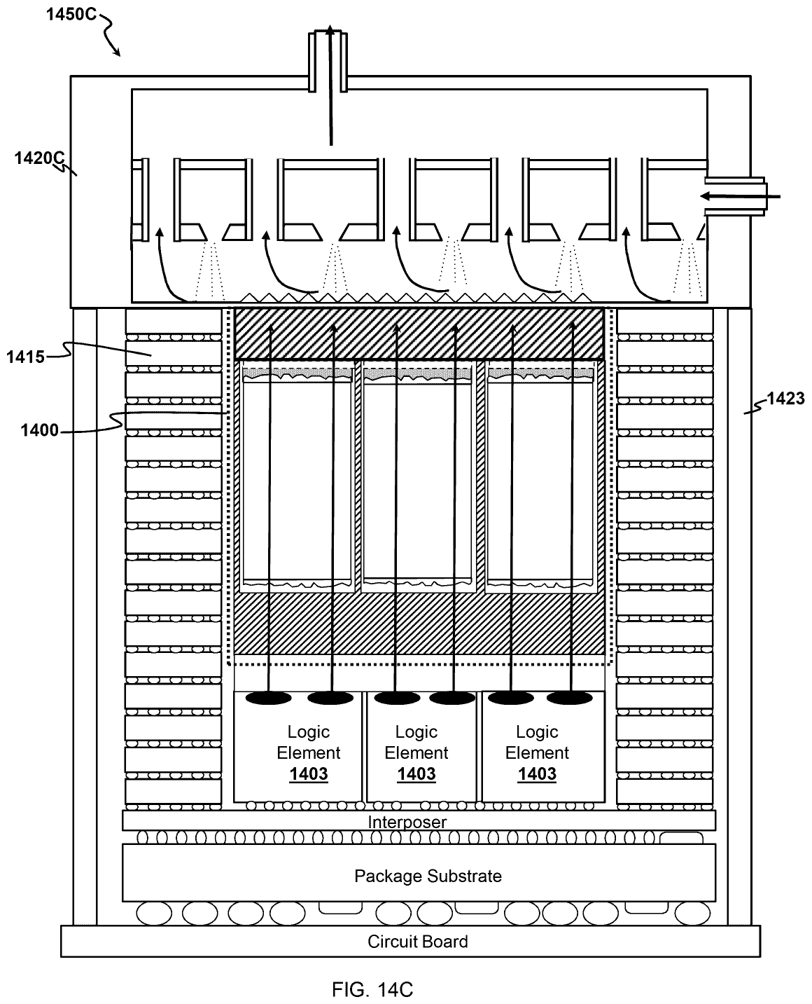

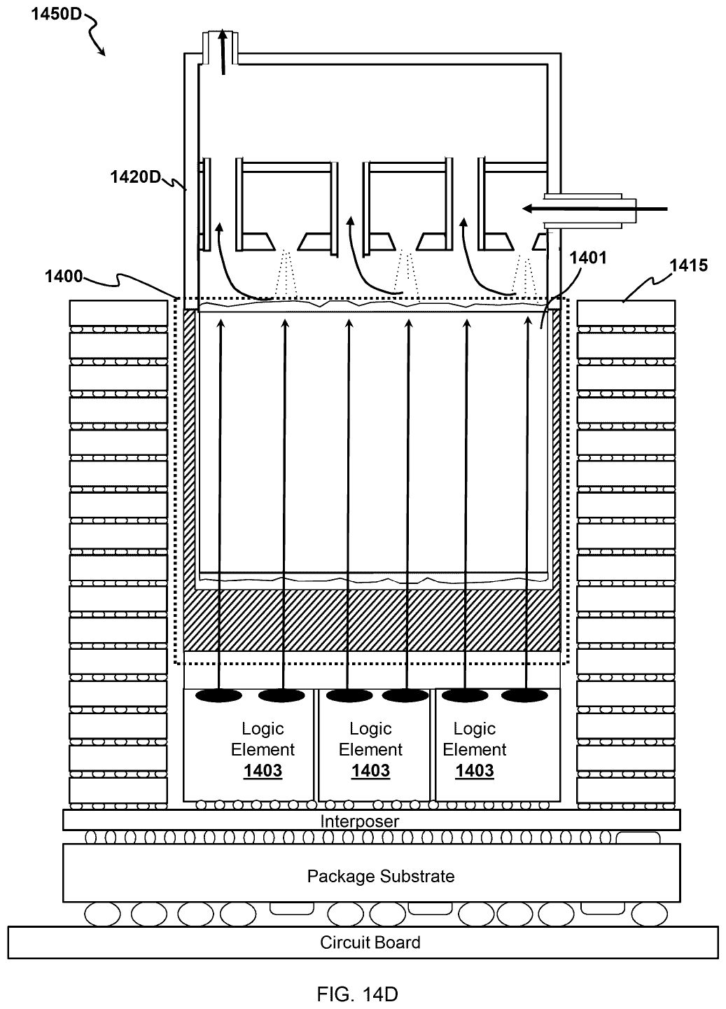

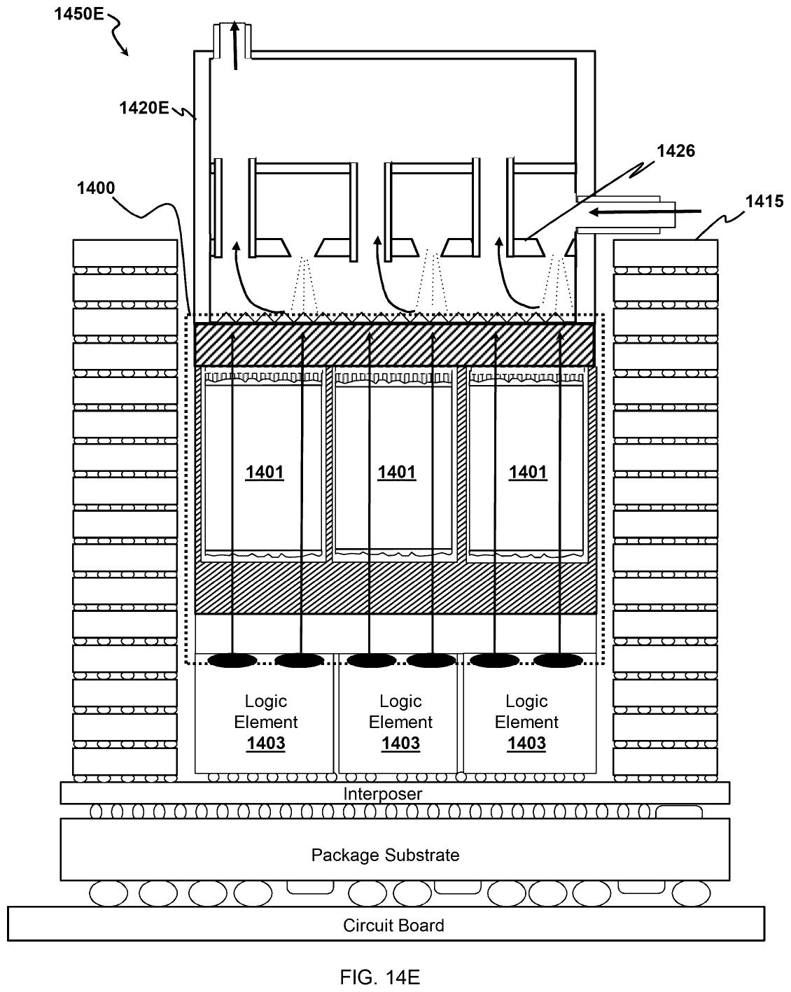

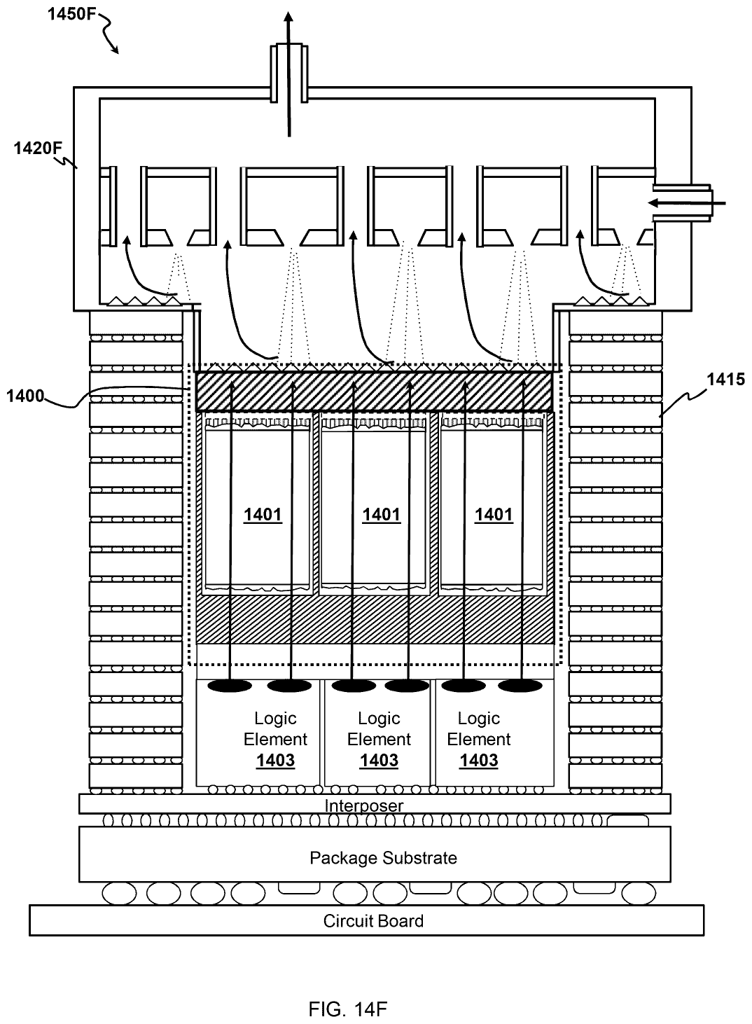

FIG. 14A shows a reconstituted wafer or diamond die heat spreader product 1400 incorporated into an advanced chip package 1450A, e.g., Chip on Wafer on Substrate (CoWoS) system stack, with a jet impingement cooler 1420A implemented with a lid 1421 and stiffener 1423 according to an aspect of the present disclosure. Alternatively, the lid 1421 may be directly attached to the substrate with adhesive without the use of an additional stiffener ring. The lid may be planar, as shown, or its shape and/or surface profile may be adjusted to directly attach to the substrate. As shown, in this implementation the reconstituted wafer product 1400 includes diamond dies 1401 encapsulated by a logic-side wafer 1402. The reconstituted wafer product is height matched with one or more sets of stacked memory modules 1415. The lid 1421 is coupled over the height matched reconstituted wafer heat spreader and the top stacked memory modules. The lid 1421 may be in thermal contact with the stacked memory 1415 and the reconstituted heat spreader product, additionally there may be a TIM between the lid and the top of the stacked memory and the top of the reconstituted heat spreader, e.g., a metal TIM. The bottom of the jet impingement cooler 1420A may be open with the heat transfer fluid in direct contact with the reconstituted wafer product 1400. The perimeter of the cooler 1420A may be attached and sealed to the reconstituted wafer product 1400 to ensure fluid remains inside the cooler. Additionally, the gaps between diamond dies 1401 may be sealed to ensure fluid remains inside the cooler. Furthermore, the cooler may have walls aligned with the gaps between the dies. While the term stacked memory units is used here, it should be understood that in some implementations there may be a single memory unit instead of a stack of two or more memory units. The lid may be attached to the circuit board 1413, e.g., PCB, or package via standoffs or stiffeners. The one or more stiffeners 1423 may be configured to stabilize the lid 1421 and heatsink over the reconstituted heat spreader 1400. The one or more stiffeners may be for example and without limitation, metal posts or tabs soldered to the circuit board or a metal processor backing bracket. The stiffener may be shaped as a window frame, e.g., located on the perimeter of the circuit board 1413.

In some implementations the circuit board may include large vias through which the stiffeners or stiffener fasteners pass to connect the stiffener to a backing bracket. In some implementations the backing bracket may be a metal or plastic clip which extends behind the processor assembly, additionally the backing bracket may be a circuit board backing which extends behind an additional portion of the circuit board not covered by the processor assembly. In some implementations the stiffeners may be connected to standoff fasteners which may provide a gap between the backing and the circuit board. Additionally in some implementations the stiffeners may be connected to a processor assembly device package (not shown). In the implementation shown the lid 1421 includes integrated jet impingement cooling. Jet impingement cooling may use a pressurized fluid heat transfer medium and shaped fluid path to spray a jet plume P of the heat transfer medium onto a thermally conductive surface 1422 dispersing the heat into the jet plume and away from the thermally conductive surface. In the example shown in FIG. 14A, heat spreader 1400 makes thermal contact to the thermally conductive surface 1422 via a heatsink-side wafer 1404.

The thermally conductive surfaces may be in the heat path of hotspots H on the logic elements 1403 and may be thermally coupled to the logic elements through the reconstituted heat spreader product 1400, as shown by the vertical arrows in the figure. Additionally, as discussed above, the heat spreader may include one or more diamond dies 1401 in the thermal path between the hot spots H and the heat conductive surface 1422. The diamond dies act to laterally spread out the heat from the hot spots and also conduct the heat vertically away from the logic element dies 1403. The thermally conductive surface may be the diamond die surface, e.g., the surface of single crystal diamond. The thermally conductive surface may be a silicon surface. The heat conductive surface may be an anti-fouling coating. As shown the heat conductive surfaces may include one or more patterned structures to increase the surface area exposed to the fluid heat transfer medium and direct the jet flow. The patterned structures may include for example and without limitation concentric rings of grooves, broken concentric rings of grooves, spiral grooves, radial channels, parallel vertical line grooves, parallel horizontal line grooves, a crosshatch pattern of grooves, microchannels, pin fin arrays, dimples and protrusions, ribbed or wavy patterns, chevron or herringbone patterns, V-shaped grooves, textures, porous coatings, etc. in the thermally conductive surface. Additionally in some implementations the pattern structures may extend from the thermally conductive surface such as for example and without limitation vertically or horizontally aligned fins, concentrically lined rings of fins, rods etc. The one or more patterned structures may also be attached to the thermally conductive surface. For example and without limitation the one or more patterned structures may be copper fins, iron or aluminum fins attached to the thermally conductive surface inside the second chamber, e.g., by soldering. The thermally conductive surfaces may also be referred to as the surfaces exposed to the jet flow, or sprayed surface.

The fluid heat transfer medium may enter a first chamber 1424 through an inlet 1425, as indicated by the left pointing arrow at the right of the first chamber. The fluid heat transfer medium may be accelerated from the first chamber through holes in a manifold 1426 into a second chamber 1427 and onto a thermally conductive surface in the second chamber. The holes may further be shaped to accelerate and form the flow of heat transfer medium into the jet plume P. The holes may be for example and without limitation venturi shaped. Additionally, in some implementations each jet may be aligned with a hot spot in the logic elements. The jet of heat transfer medium may circulate through the second chamber 1427 and exit through an outlet 1428, as indicated by the upward arrow at the left of a third chamber 1429. The height of each chamber, the locations of the inlet and outlet, the pitch of openings within each manifold, the location of the openings, the thickness of the manifold, the size and shape of each opening, the number of openings, the pattern on the thermally conductive surface, and the choice of heat transfer fluid may be optimized to ensure optimal heat transfer by optimized flow distribution, pressure distribution, flow rate control, minimal flow resistance, minimal fluid stagnation, and optionally optimized phase change control, while ensuring reliable operation, e.g., no clogging, leaking, nozzle erosion, fouling, etc. The cooler design, material and fluid choice may be optimized to reduce both pump power and thermal resistance. The fluid heat transfer medium may be for example and without limitation, water, mineral oil, an alcohol, ethylene glycol, or any combination thereof. Additionally, the cooling may be single-phase cooling or two-phase cooling. The heat transfer fluid may be a similar fluid as used for single-phase or two-phase immersion cooling. The heat transfer fluid may be a hydrocarbon, or may be a fluorochemical. The heat transfer fluid may be a dielectric coolant. The cooler may be manufactured by additive manufacturing. The cooler may be made out of polymer, polymers with fillers to reduce CTE, copper, aluminum, or silicon. The cooler may be made out of ceramics. The cooler may be manufactured out of one part. The cooler may be assembled from multiple parts.

According to aspects of the present disclosure, the jet impingement cooling system may have a separate cooling compartment for each logic element. Each cooling compartment may have one or more jet openings, one or more coolant outlets and sidewalls that isolate the compartment from neighboring compartments. Alternatively, as shown in FIGS. 14A-14E, there may be one cooling compartment for two or more IC dies with all sprayed surfaces in one plane. Furthermore, as shown in FIG. 14F, there may be one cooling compartment for two or more IC dies with at least one sprayed surface in a different plane than the other(s). In addition, aspects of the present disclosure include implementations in which there are two or more jet impingement coolers, each configured to cool one or more diamond dies.

FIG. 14B shows a reconstituted wafer or diamond die heat spreader product 1400 incorporated into an advanced chip package 1450B, e.g., Chip on Wafer on Substrate (CoWoS) system stack, with jet impingement cooler 1420B over the reconstituted heat spreader product according to an aspect of the present disclosure. In this implementation the jet impingement cooler 1420B is located on top of the reconstituted heat spreader 1400 and sprays heat conductive medium directly onto the heatsink-side wafer 1404 of the heat spreader. The jet impingement cooler may be affixed to the reconstituted heatspreader product by for example and without limitations solder, an adhesive, metal sintering or a bonding material.

The heatsink side wafer 1404 may include one or more patterned structures to increase the surface area exposed to the fluid heat transfer medium and direct the jet flow. Additionally one or more patterned structures in the heatsink-side wafer may be coated in a metal or other material. As discussed above, in some implementations the one or more patterned structures may be attached to the top surface of the heatsink-side wafer 1404.

FIG. 14C shows a reconstituted wafer or diamond die heat spreader product 1400 incorporated into an advanced chip package 1450C, e.g., CoWoS, with a jet impingement cooler 1420C cooling the logic elements 1403 and the HBM stacks 1415 simultaneously. The bottom of the jet impingement cooler 1420C may be open with the heat transfer fluid in direct contact with either the reconstituted wafer product 1400, the HBM stacks 1415, or both. A perimeter wall 1423 of the cooler 1420C may be attached and sealed to the HBM stacks 1415 and reconstituted wafer product 1400 to ensure fluid remains inside the cooler. Additionally, the gaps between dies, e.g., between the dies in the HBM stack 1415 or between the HBM stack 1415 and the heat spreader product 1400 and/or logic elements 1403, may be sealed to ensure fluid remains inside the cooler. Furthermore, the cooler may have walls aligned with the gaps between the dies.

FIG. 14D shows a reconstituted wafer or diamond die heat spreader product 1400 incorporated into an advanced chip package 1450D, e.g., CoWoS, with the jet impingement cooler 1420D directly spraying onto the diamond die 1401. The diamond die surface is level with the top surface of the HBM stacks 1415. In some implementations the diamond die surface may have a thin layer of silicon that is patterned. In some implementations, the diamond die 1401 is single crystal diamond and directly bonded to the logic element 1403. In some implementations, the diamond die 1401 reaches from the logic element 1403 to the sprayed surface.

FIG. 14E shows a reconstituted wafer or diamond die heat spreader product 1400 incorporated into an advanced chip package 1450E, e.g., CoWoS, with the sprayed surface of the impingement cooler 1420E below the surface of the surrounding HBM stacks 1415. Height matching the logic elements with the HBM stacks may only be necessary to contact a flat heat spreader or cooler. However, when integrating the cooler 1420E with the advanced chip package 1450E, height matching may not be necessary. Additionally, height matching may still be possible with the bottom manifold 1426 of the impingement cooler 1420E. The bottom manifold may be opened after integrating the diamond die heat spreader product 1400 with the bottom part of the cooler into the advanced package 1450E.

FIG. 14F shows a reconstituted wafer or diamond die heat spreader product 1400 incorporated into an advanced chip package 1450F, e.g., CoWoS, with the jet impingement cooler 1420F cooling the logic elements 1403 and the HBM stacks 1415 simultaneously, yet with the sprayed surface of the logic elements below the top surface of the HBM stacks. The sprayed surface of the heat spreader product 1400 may be single crystal diamond, or a thin patterned film on single crystal diamond.

The jet impingement cooler may cool one IC die. The jet impingement cooler may cool two or more IC dies. The sprayed surface of the two or more IC dies may be in the same plane. The sprayed surface of the two or more IC dies may be in different planes. The jet impingement cooler may cool both one or more logic elements and one or more other dies, e.g., the surrounding HBM stacks. The jet impingement cooler may cool the complete advanced package. The jet impingement cooler may physically cover the complete package and may be adhering to the package at the substrate, interposer, one or more dies, or a combination. The jet impingement cooler may be attached to the PCB board underneath the substrate. The inlet of the jet impingement cooler may be on the top or on the side of the cooler. Similarly, the outlet of the jet impingement cooler may be on the top or the side of the cooler. The jet impingement cooler may have two or more inlets, and two or more outlets. The jet impingement cooler may have one chamber, two chambers, three chambers, or more chambers. The jet impingement cooler may have no manifold, one manifold, two manifolds, or more manifolds. The sprayed surface may be a patterned material, e.g., silicon. The sprayed surface may be patterned mold compound. The sprayed surface may be a smooth diamond die. The sprayed surface may be a patterned diamond die. The sprayed surface may be coated for anti-fouling to prevent buildup of biofilms, minerals, or other contaminations. Anti-fouling coatings may contain epoxies, silicones, copper, or zinc. The anti-fouling coating may be patterned. The anti-fouling coating may only be used on top of a non-diamond surface. A diamond surface may be naturally anti-fouling and does not require an anti-fouling coating. The sprayed surface may be patterned to increase surface area or to direct the heat transfer fluid flow. The advanced package may be cooled by two or more jet impingement coolers. Alternatively, one or more jet impingement coolers may be replaced by microchannel coolers. The jet impingement cooler may have an effective heat transfer coefficient of 100,000 W/m²-K, or higher.

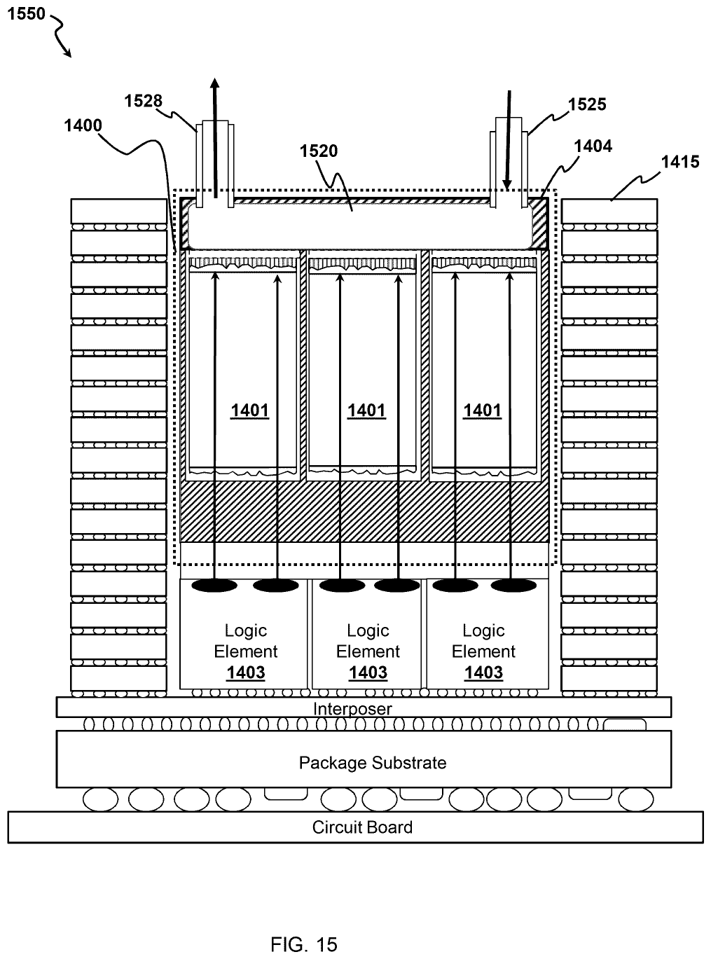

FIG. 15 shows a reconstituted wafer heat spreader product 1400 incorporated into a Chip on Wafer on Substrate (CoWoS) system stack 1550 with microchannel cooling integrated into the heatsink-side wafer 1404 according to an aspect of the present disclosure. In microchannel cooling with the reconstituted wafer, horizontal channels 1520 for a fluid heat transfer medium may be formed in the heatsink side wafer. Fluid may enter the channels through one or more inlets 1525, e.g., vertical vias, and exits the channels through one or more outlets 1528 formed in the heatsink-side wafer 1404. To form the vertical vias, the heatsink-side wafer may have a top plate and a bottom plate which are formed separately and subsequently bonded together by, for example and without limitation, soldering, sintering, silicon to silicon SAB, PAB, etc. The bottom plate may be a diamond die. Channels may be formed between the top and bottom plate. The channels may be formed in the bottom or top plate prior to bonding. The vertical vias may be etched into the top plate, or created by a laser

To facilitate attachment of leak-proof, durable tubing and connections for delivery of the fluid heat transfer medium to the one or more inlets 1525 and one or more outlets 1528 compression fittings may be used. Alternatively, barbed fittings with hose clamps may be used. In yet another example, quick-connect fittings may be used. In another example, threaded fittings may be used. Alternatively, a push-to-connect, swaged, or crimp connection may be used. In yet another example, brazed or soldered connections may be used. In another implementation, flare fittings may be used.

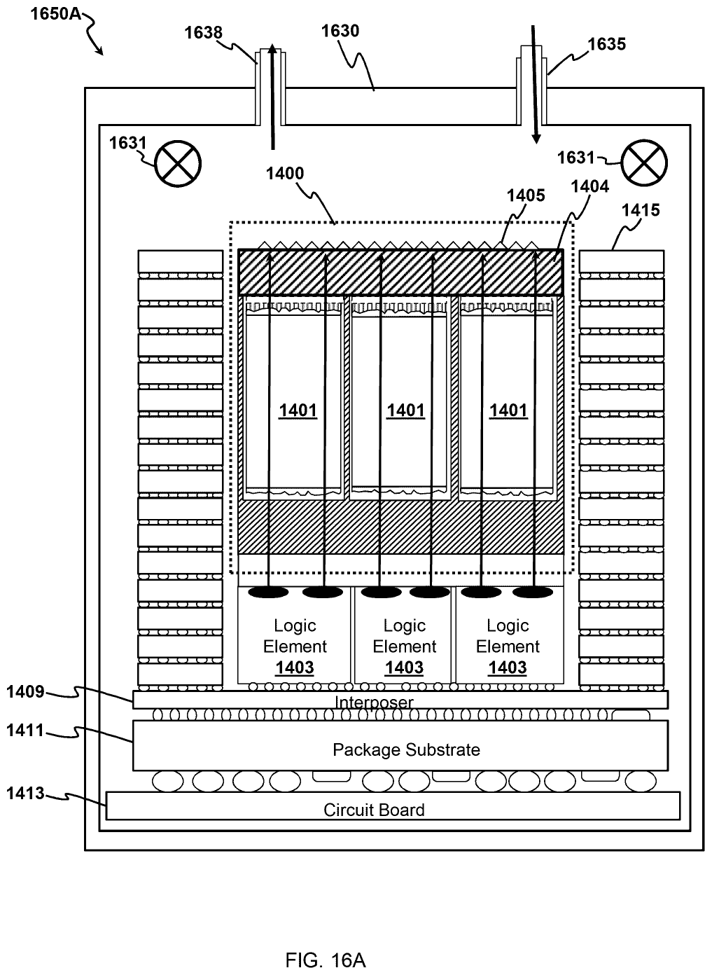

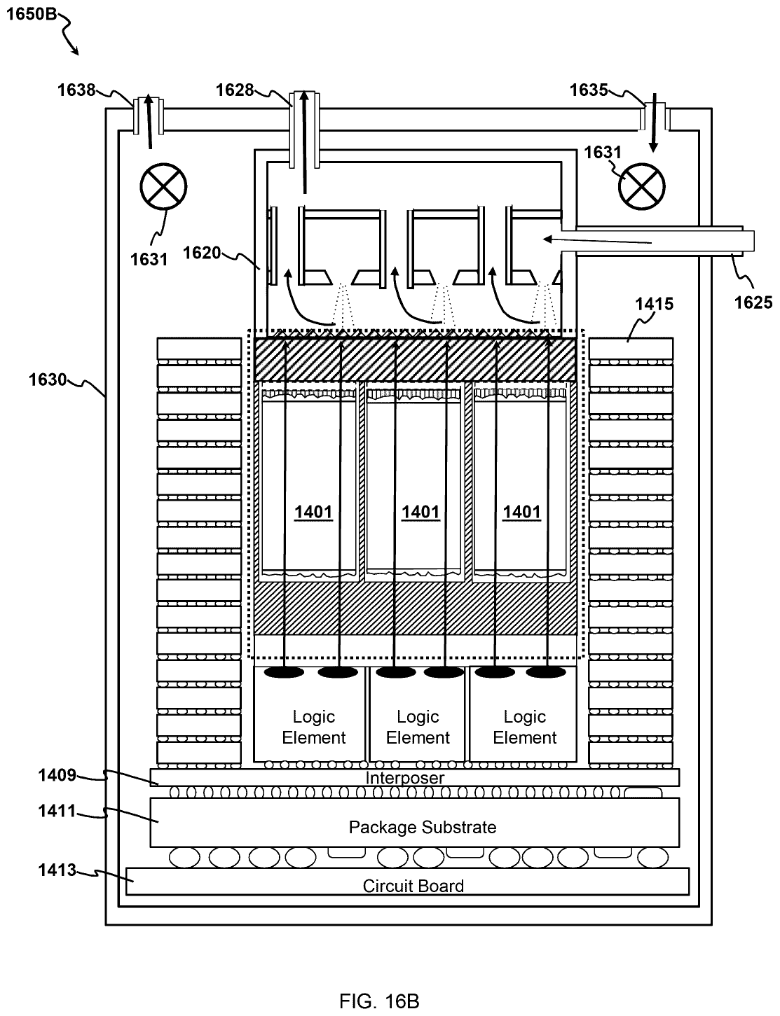

FIG. 16A depicts a reconstituted wafer heat spreader product 1400 incorporated into a Chip on Wafer on Substrate (CoWoS) system stack 1650A with immersion cooling according to an aspect of the present disclosure. As shown in this implementation the entire assembly including the reconstituted wafer heat spreader 1400, logic units 1403, stacked memory units 1415, interposer 1409, package substrate 1411 and circuit board 1413 are immersed in a heat transfer medium. An outer casing 1630 may be used to contain the heat transfer medium. In this implementation, the heat transfer medium may be selected such that it is electrically non-conductive to reduce the chance of unwanted arcing between components. Suitable fluid heat transfer media may be for example and without limitation, hydrocarbons or fluorocarbons in the form of gasses or liquids. Additionally the heat transfer medium may be a single phase coolant or two phase coolant.

In an immersion cooling system which uses a two phase coolant a space in the outer casing above the assembly may be left free from fluid. This space may be filled with the vapor phase of the two phase coolant which may boil to form a vapor when it contacts sufficiently warm surfaces of the assembly. The coolant may enter through an inlet 1635. An outlet 1638 may be located at the top of the two phase cooler and the outlet may be connected (e.g., via tubing) to a condenser (not shown) where the heat may be extracted from the vapor via condensation of the vapor thereby returning the two phase coolant to liquid form. The condenser may be attached to the inlet (via e.g., a return tube) and the liquid coolant may flow back into the outer casing in a closed loop cycle.

By contrast a single phase cooling setup may fill the casing 1630 at least up to the liquid outlet 1638 covering the assembly in the single phase coolant. In its simplest form, a single phase cooling setup may be implemented with a stagnant pool of heat transfer medium which acts as a large heat spreader with the single phase coolant absorbing heat from the assembly. In such an implementation the outer casing 1630 may act as a radiative heat sink. In a more complex implementation, a pump located either near the outlet 1638 or inlet 1635 may cause a pressure gradient in the heat transfer medium moving the medium through the outlet to a heat dump. In an open loop cooling example the heat dump may simply be a drain or a large pool of heat transfer medium. In a closed loop cooling example the heat dump may be a radiator or bulk cooling block which then emits the heats to the surrounding environment away from outer casing and the assembly.

The reconstituted wafer product 1400 may be specialized for immersion cooling for example and, without limitation, the heatsink-side wafer 1404 may include one or more patterned structures 1405 configured for immersion cooling. These patterned structures may include large fins to increase the surface exposure of the heat sink side wafer to the heat transfer medium. These fins may be made from the material of the heatsink-side wafer 1404 or may be made from a second material attached to the heatsink-side wafer. For example and without limitation, the one or more patterned structures 1405 may include copper fins bonded to the heatsink-side wafer 1404. The reconstituted wafer product 1400 may have a boiling-enhancement coating, e.g., made from porous copper. The heat spreader may include single crystal diamond with a boiling-enhacement coating.

The outer case 1630 may additionally have one or more impellers 1631 configured to circulate the fluid heat transfer medium around the outer case. The one or more patterned structures may be arranged with flow of heat transfer medium to be created by the one or more impellers. For example and without limitation the one or more patterned structures may be fins arranged parallel with the flow of heat transfer medium.

FIG. 16B depicts a reconstituted wafer heat spreader product 1400 incorporated into a Chip on Wafer on Substrate (CoWoS) system stack 1650B with hybrid jet impingement and immersion cooling according to an aspect of the present disclosure. A hybrid cooler may combine immersion cooling with a second cooling method. As shown here the hybrid cooler integrates jet cooling into an immersion cooler. An immersion cooler casing 1630 surrounds a jet cooler casing 1620 and the fluid heat transfer medium may also be in contact with the housing of the jet cooler. Heat transfer fluid enters the immersion cooler casing 1630 through an inlet 1635 and exits through an outlet 1638. The immersion cooler here, cools the less heat sensitive components of the assembly such as the memory stacks 1415 and passive components. The jet cooler 1620 in this implementation cools the more heat sensitive components (e.g., the logic elements 1403). Heat transfer fluid enters the jet cooler casing 1620 through a jet cooler inlet 1625 and exits through a jet cooler outlet 1628. The jet cooler inlet and outlet also pass through the immersion cooler casing 1630 to communicate with the jet cooler casing 1620. While this implementation shows a jet cooler it should be understood that the hybrid cooler may implement any type of liquid cooling for example and without limitation, microchannel cooling, traditional liquid cooling, phase change liquid cooling etc.

This hybrid cooler arrangement allows the direct cooling of some heat sensitive elements such as logic elements and immersion cooling of other less sensitive elements. Additionally, this arrangement may allow the use of two different fluid heat transfer media. A first fluid heat transfer medium may be located in the cavity of the immersion cooler casing 1630 outside the casing 1620 of the jet cooler. A second different fluid heat transfer medium may be located within a cavity of the jet cooler casing. Alternatively the fluid heat transfer medium in the immersion cooler's outer casing may be the same material as the fluid heat transfer medium in the second cooler (e.g., a jet impingement cooler).

FIGS. 14A through 16B show multiple logic elements 1403 in an advanced package integrated with one cooler. In alternative implementations, there may be one cooler per diamond die, e.g., with one diamond die per logic element. The diamond die may be a single crystal diamond that reaches from the logic element to the sprayed surface. The diamond die may originate from a temporary carrier, e.g., film frame or tape-and-reel. The diamond die may be diced out of a reconstituted wafer. The multiple diamond dies may be diced out of a reconstituted wafer as individual diamond dies, or as one piece (die) containing two or more diamond dies. While in FIGS. 14A through 16B the diamond dies 1401 are shown as one large piece (die) containing multiple diamond dies diced from a reconstituted wafer and covering multiple logic elements as one heat spreader piece, aspects of this disclosure are not so limited. Alternatively, each logic element may be attached to a single diamond die.

In the implementations shown, the logic elements 1403 are part of a larger integrated circuit device. The logic elements may be communicatively coupled with an interposer 1409. The communicative coupling may be for example and without limitation, through solder connections (e.g., micro solder bumps) or conductive contact pins. The interposer 1409 may include conductive vias and lateral conductive traces to make communicative connections between different elements within the CoWoS stack 1450A, 1450B, 1450C, 1450D, 1450E, 1450F, 1550, 1650A, or 1650B. The interposer 1409 may be communicatively coupled with a package substrate 1411. The communicative coupling to the package substrate may be for example and without limitation, through solder connections (e.g., solder bumps) or conductive contact pins. The package substrate 1411 may include conductive vias and lateral conductive traces to make communicative connections between different elements connected to the package substrate within the CoWoS stack. The package substrate 1411 may be communicatively coupled with a circuit board 1413. The communicative coupling to the circuit board may be for example and without limitation, through solder connections (e.g., solder balls) or conductive contact pins. The circuit board 1413 may include conductive vias and lateral conductive traces to make communicative connections between different elements connected to the circuit board within the CoWoS stack.

It should be noted that prior to affixing the logic side wafer to the logic elements the logic-side wafer may be thinned to <100 μm or <10 μm. Likewise the prior to affixing the heatsink-side wafer to heatsink, it may be thinned. Similarly, the heatsink-side wafer may be thinned <500 μm, <100 μm or <10 μm. Generally, it may be favorable for the logic-side wafer to be thinner than heatsink-side wafer as it is closer to the heat generating elements. It should further be understood that if the thinned wafers are extremely thin a temporary carrier may be adhered to the wafer that is first thinned to improve stability for thinning the second wafer, the temporary carrier may subsequently be removed before bonding.

Wafer thinning may be accomplished, for example and without limitation, by using one or more of the following techniques: abrasive techniques, grinding, lapping, chemical mechanical polishing (CMP), polishing (wet or dry), wet etching, dry etching, or laser ablation. The thinning process may be facilitated by, e.g., a temporary carrier with a temporary adhesive, specialized pads or tapes, or the TAIKO process. In the TAIKO process a thicker ring is left temporarily around the wafer perimeter to support the wafer. Carriers may be used with bonds that are often considered permanent, yet used as a temporary bond, and after thinning the logic side or heat sink side wafer the carrier is removed by for example and without limitation, destruction such as by grinding and polishing. Instead of temporary carriers with temporary adhesives, mobile electrostatic carriers might be used. Furthermore, buried layers may be introduced into the wafers that facilitate thinning to below 10 μm, e.g., to 500 nanometers, or even to 10's nanometers. These buried layers may act as an etch stop, e.g., as used for thinning in backside power delivery processes, may facilitate laser debond, e.g., similar to EVG's IR layer release, or may facilitate film transfer similar to Soitec's SmartCut.

While the implementations depicted in FIGS. 10, 14A, 14B, 14C, 14D, 14E, 14F, 15, 16A, and 16B may represent a CoWoS system it should be understood that aspects of the present disclosure are not so limited and may be implemented in any type of integrated circuit device packaging system including but not limited to 2D, 2.1D, 2.5D, other 3D, and 3.5D packaging systems. As used herein, “2D packaging” refers to a traditional method of packaging semiconductor devices where one or multiple integrated circuits (ICs) or chips are mounted side-by-side on a single (organic laminate) packaging substrate, such as a printed circuit board (PCB), without stacking them vertically. The components are arranged in a single plane, forming a two-dimensional layout. “2.5D packaging” refers to a packaging technique in which multiple integrated circuit chips (sometimes called “dies”) are placed side-by-side on a common interposer, e.g., silicon or an organic interposer, which provides high-density interconnections between the chips. The interposer sits on a packaging substrate. “2.1D packaging” refers to a packaging technique where a redistribution layer (RDL) is used instead of a silicon interposer. “3D packaging” refers to a packaging technology where multiple semiconductor dies (chips) are stacked vertically on top of each other within a single package and interconnects are made vertically between stacked dies, e.g., using through-silicon vias (TSVs) therefore offering a higher packaging density than 2D, 2.1D or 2.5D packaging. “3.5D packaging” refers to a packaging technique that uses a combination of vertically stacked dies and interposers. In some implementations the interposer may be a diamond interposer having one or more layers of dies containing diamond having through diamond vias (TDV) and/or TSVs along with conductive traces between the TDVs and/or TSVs. The layers of dies containing diamond may be solid single crystal diamond layers or layers of multiple single crystal diamond dies with silicon gap fillers between each die.

The reconstituted wafer product may contain diamond dies with adhesion layers, diffusion barriers, smoothening layers, bonding layers, compliant layers, height-matching filler materials on the diamond dies, a wafer on the logic side, a wafer on the heat sink side, adhesion layers on one or both wafers, diffusion barriers on one or both wafers, bond layers on one or both wafers, or even smoothening layers on one or both wafers. In addition, the reconstituted wafer product may contain gap fillers between the diamond dies. Furthermore, the reconstituted wafer product may contain perimeter sealants that partially or completely seal the materials sandwiched between both wafers from the outside, so there is no exposure to these materials during the wafer processing, e.g., cleaning, thin film deposition, film densification, film surface activation, bonding, annealing, thinning, lithography and etching, bumping, and debonding temporary carriers. The sealants may be adhesives, sealants, molding compounds, polymers, thermoplastics, epoxies, photoresists, benzocyclobutene (BCB) derivatives, spin-on photo-dielectrics, silicones, or polyimides. Similarly, spin-on glass or polymer-derived ceramics may be used, e.g., polysilazane derivatives (e.g., polyborosilazane), polysiloxane derivatives, polysilane derivatives (e.g., polycarbosilane), polysilsesquioxanes, polysilsesquiazanes, polysilylcarbodiimides, etc. The sealants may be the same materials as used for the gap fillers. The sealants may be the same bond materials as used for bonding the diamond dies, or bonding the heatsink side wafer to the logic side wafer, e.g., when using one or two pocketed wafers.

### Bond Layers

The material of the bond layers depends partly on the bonding technique that is used and requirements of the fab that receives the reconstituted wafers. For example, some fabs prefer to avoid exposed metals, such as copper. The bond layers may be deposited on the wafers, and may be deposited on the diamond dies, e.g., on the smoothening layers.

By way of example, and not by way of limitation, Copper (Cu) may be used as a bonding layer material in TCB on one or both wafers, and as a smoothening layer on the diamond dies. Both copper and tin (Sn) may be used for transient liquid phase bonding (TLPB), e.g., tin stacked on top of copper on one or both wafers, and copper on the diamond dies. Similarly, instead of copper, either nickel, or gold, or silver may be used in this TLPB example, or instead of tin, indium (In) may be used. A solder may be used as a bonding and/or smoothening layer and/or compliant material in solder bonding on one or both wafers, either applied as a film (coating), pre-form (foil), wire, balls, or paste, e.g., SAC305, or high-temperature Sn—Pb alloys may be used. A eutectic may be used as a bonding and/or smoothening layer and/or compliant material in eutectic bonding on one or both wafers, either applied as a film (coating), pre-form (foil), wire, balls, or paste, e.g., Au—Si, Au—Ge, Au—Sn, or Cu—Sn. Other compositions of interest may be Zn, Zn—Sn (e.g., eutectic), Zn—Al (e.g., eutectic), aluminum-silicon eutectic (e.g., 88.3Al/11.7Si by wt.-%) at bond temperatures of roughly 575 Celsius, or e.g., the aluminum-germanium eutectic (e.g., 55Ge/45Al by wt.-%) at bond temperatures of roughly 425 Celsius, or e.g., the zinc-aluminum eutectic (e.g., 95Zn/5Al by wt.-%) at bond temperatures of roughly 385 Celsius. A brazing material may be used as a bonding and/or smoothening layer and/or compliant material in brazing bonding on one or both wafers, either applied as a film (coating), pre-form (foil), wire, balls, or paste, e.g., Au—Ti, Al—Si, or Al—Zn alloys may be used. A sinter paste may be used as a bonding and/or smoothening layer and/or compliant material in sinter bonding on one or both wafers, dispensed or printed as a paste, e.g., silver paste or copper paste. A metal foil, e.g., copper or aluminum, optionally softened by annealing prior to or during bonding, may be used as a bonding and/or smoothening layer and/or compliant material during bonding (e.g., TCB) with one or both wafers, and one or both wafers optionally metallized, and the diamond dies optionally metallized, with the metallization outer surface e.g., copper, gold, silver, titanium, nickel, or chromium. Similarly, for solder bonding, eutectic bonding, compliant layer bonding, or brazing bonding, the surfaces of one or both wafers, and the diamond dies may be metallized with the outer surface copper, gold, silver, titanium, nickel, or chromium. A reactive multi-layer foil or film, e.g., repeating alternating layers of aluminum and nickel, may be used as a bonding and/or smoothening layer and/or compliant material during bonding (e.g., TCB) with one or both wafers, and one or both wafers optionally metallized, and the diamond dies optionally metallized, with the metallization outer surface e.g., copper, gold, silver, titanium, nickel, or chromium. These reactive multilayer foils or films may be initiated by a heat pulse, laser pulse, electric spark, or other means, and this initiation may result in a self-sustaining exothermic reaction raising the local temperature to aid bonding, and may produce intermetallic compounds. Other multi-layer materials may be aluminum with titanium, or titanium with amorphous silicon. Silicon may be used as a bonding layer material and/or smoothening material in SAB or ADB. Dielectrics may be used as bonding layer and/or smoothening layer materials in PAB or fusion bonding. Metals, e.g., metal foils (e.g., aluminum, zinc, solder, eutectic), may be heated to the melting point to aid bonding, or may be heated to soften without melting to aid in bonding. Adhesive bonding may be used. Adhesives may be, without limitation, silver-filled epoxies, curable thermal interface materials, e.g., based on carbon nanotubes, or graphene.

Bonding diamond dies, e.g., rough SCD, to wafers, e.g., single crystal silicon wafers, may be performed by surface melting the silicon wafer while pressing the diamond dies into the soft (e.g., liquid) silicon surface. The silicon wafer surface may be heated through the silicon wafer by adding an absorbing layer onto the silicon surface, e.g., a doped silicon surface. The silicon wafer surface may be heated through the diamond, e.g., with visible lasers that are transmitted through the diamonds, yet get absorbed by (undoped) silicon. The silicon surface may be heated with a laser, by rapid thermal processing (RTP), e-beam heating, inductive heating, Flash Lamp Annealing (FLA), PulseForge, etc. The laser may be a kW or greater laser; IR laser (e.g., CO₂), or visible laser (e.g., green or blue), or UV laser (e.g., excimer). By way of example, and not by way of limitation, rough SCD dies may be bonded to the logic-side wafer by silicon surface melting, and subsequently the heatsink-side wafer may be attached to the diamond dies via a thick copper foil between the dies and the heat sink side wafer.

In some example methods for silicon surface melting bonding, the dies containing diamond may be inserted into very deep pockets in the heat sink side wafer or logic side wafer which are sized sufficient to cover the entire die containing diamond. Subsequently the bottoms of the pockets of the pocketed wafer may be melted by laser light transmitted through the diamond dies. A second wafer may then be placed over the pockets and bonded to the pocketed wafer. In some implementations, after the silicon surface melting step the pockets containing diamond may be filled with a smoothening material such as copper, the copper may be planarized with the top surface of the pocketed wafer, the second wafer may then be bonded to both the pocketed wafer and the smoothening layer via hybrid bonding. Alternatively the second wafer may be coated with a material selected to absorb a specific wavelength range of light and laser light may be applied up through the pocketed wafer and dies to melt the second wafer surface for bonding the dies and pocketed wafer to the second wafer. In another alternative implementation, the dies containing diamond may be bonded in the pocketed wafer via sintering, a sintering paste may be disposed on the bottom of each of the pockets and the dies may be placed in the pockets and exposed to sufficient heat and force and bond the dies to the wafer. Subsequently the second wafer may be bonded over the dies with SAB. Additionally, because the very deep pockets envelope the entire die containing diamond, the smoothening pocketed wafer and/or smoothening material may be polished and/or planarized without the risk of encountering hard diamond material.

High intensity lasers may be used to illuminate-through the diamond—the interface between the diamond and silicon to heat, melt, and cause joining. Kilowatt and multi-kilowatt lasers may be used to illuminate and heat very large areas. A highly polished diamond may not be required as the high thermal conductivity of diamond may ensure that the interface temperature is kept uniform. Ideal wavelengths for heating silicon may be shorter than 1.1 micrometer, and ideally much shorter, e.g., 550 nm to 350 nm, where there are a range of fiber and fiber delivered lasers available that can deliver large, square or rectangular, spots (e.g., from Nuburu®, Laserline®, or Trumpf®). According to the graph below, the absorption depth for these shorter wavelength lasers may be on the order of ˜100 nm compared to many microns near 1000 nm, ensuring that the interaction volume of the laser, silicon/diamond interface may be kept highly localized and efficient.

In an alternative method of bonding diamond to silicon wafers according to aspects of the present disclosure, a nickel metal interface may be used. A layer of nickel may be deposited between the diamond and silicon, and then the assembly may be annealed, creating two hetero-interfaces: one where nickel may form a Ni—C bond with the diamond, and another where it may form a Ni—Si bond with the silicon. The goal of this method may be promoting interdiffusion at both interfaces, resulting in a robust and durable bond. This implementation may involve depositing a controlled thickness of nickel onto either the diamond or silicon wafer, followed by the placement of the opposing material. Alternatively, the nickel may be partially or completely provided as a foil. The assembly may then be subjected to an annealing process at temperatures between 750 Celsius and 1200 Celsius. During annealing, the nickel may facilitate the formation of a strong chemical bond with both the diamond and the silicon. The interdiffusion between the Ni—C and Ni—Si interfaces may enhance the overall strength and stability of the bond, making this method particularly useful for applications where a durable, high-temperature-resistant bond between diamond and silicon may be required. Alternatively, instead of nickel, titanium, or chromium may be used. The bonding of two metal films, e.g., the nickel film on the diamond, and the nickel film on the silicon, may be accomplished by appropriate pretreatments (e.g., to remove oxide), and thermocompression bonding. In one embodiment, the nickel is deposited on both surfaces, followed by a high temperature anneal, followed by a surface treatment, followed by thermocompression bonding. In another implementation, after film deposition and surface treatment, the pair is bonded at high temperature.

The thermal conductivity of copper (foil) and its alloys may range from 80 W/m-K to 400 W/m-K (e.g., pure copper) depending on the alloy composition, and microstructure, the latter impacted by manufacturing method, and additional processing. Annealing copper (foil) may improve thermal conductivity and soften the foil for temperatures of e.g., 300 Celsius up to its melting point. Copper may be deposited as a thin film, e.g., by electroplating, electroless plating, e-beam deposition, or sputtering with a thermal conductivity close to the copper bulk thermal conductivity (˜400 W/m-K). Additionally, copper may be introduced as a thin foil with a thermal conductivity in the range of 80 W/m-K to 400 W/m-K. Furthermore, copper may be introduced as a paste followed by sintering with a thermal conductivity after sintering as high as 300 W/m-K. Additionally, the crystal orientation of the copper may be controlled to aid in bonding, e.g., nanotwinned (111) copper.

The thermal conductivity of aluminum (foil) and its alloys may range from 80 W/m-K to 237 W/m-K (e.g., pure aluminum) depending on the alloy composition, and microstructure, the latter impacted by manufacturing method, and additional processing. Annealing aluminum (foil) may improve thermal conductivity and soften the foil for temperatures of e.g., 300 Celsius up to its melting point. Aluminum may be deposited as a thin film, e.g., by e-beam deposition or sputtering, with a thermal conductivity close to the aluminum bulk thermal conductivity (˜237 W/m-K). Additionally, aluminum may be introduced as a thin foil with a thermal conductivity in the range of 80 W/m-K to 237 W/m-K.

The thermal conductivity of silicon may range from 1 W/m-K to 140 W/m-K. Amorphous silicon films may have thermal conductivities of ˜1 W/m-K, whereas polycrystalline silicon (films) may have thermal conductivities around 50 W/m-K, and single crystal silicon as high as 140 W/m-K, albeit heavily dependent on doping, and crystal defect concentration. Silicon may be introduced as an amorphous film, polycrystalline film, single crystal wafer, polycrystalline wafer, or as a powder. Silicon introduced as a powder may be used as gap-filler, or may be used between one or both wafers and the diamond dies. Silicon powder may be sintered or fused together by a heat source, e.g., by laser annealing.

Materials like titanium and chromium may be deposited by any suitable deposition method for example and without limitation physical vapor deposition such as sputtering. Materials like nickel, copper, tin, zinc, gold, and silver may be deposited as a film by physical vapor deposition or plating, e.g., electroplating or electroless plating. Diffusion barrier layers like TiN or TaN may be deposited by physical vapor deposition, e.g., sputtering. Indium may be deposited by vapor deposition or plating.

The placement and bonding of diamond dies to form the reconstituted wafer product may be performed by sequential dies to wafer (SD2 W) bonding, or collective dies to wafer bonding (CD2 W). The bonding of the second wafer, e.g., heat sink side wafer, may be a separate bonding step after the SD2 W or CD2 W bonding. Alternatively, the diamond dies may be placed onto the first wafer, and the second wafer is placed onto the diamond dies, and the whole stack may be bonded by temperature and/or force in one step.

ADB and SAB are generally performed between ultrasmooth layers, e.g., silicon with a roughness (Sa) of less than 0.5 nanometers. A silicon smoothening layer may be deposited or otherwise formed on the surfaces of the diamond dies and, in some implementations, the gap filler prior to bonding. The silicon smoothening layer may be formed by thin film deposition followed by smoothening, e.g., CMP. The silicon smoothening layer may be amorphous, nanocrystalline, microcrystalline, or polycrystalline. Deposition of the silicon layer may be by any known method for example and without limitation, Physical Vapor Deposition (PVD) or chemical vapor deposition (CVD). In the SAB process the respective bonding surfaces are cleaned of contaminants, e.g., organics, metals, and particles, prior to entering the ultra-high-vacuum environment. The bonding surfaces are treated with beams of atoms or ions in an ultra-high-vacuum (UHV) environment to remove remaining contaminants (e.g., organics, metals, and oxides) and create reactive dangling bonds and typically amorphize a few nanometers of each bonding surface (e.g., 1-5 nm). Typically, Argon atoms or ions are used. Amorphizing the bonding surfaces avoids potential issues with lattice mismatch. The treated surfaces are then subject to bonding pressure (force) under UHV. The UHV environment allows for a few minutes to bring surfaces into contact and form strong (e.g., covalent) bonds. The bonding may be done at relatively low temperature, e.g., in the range of room temperature (about 25° C.). The resulting bonds are free of a significant thickness of intermediate material. As a result of the amorphization, there may be an interface region of amorphous material between the bulk crystalline silicon wafer and the silicon smoothening layer with an interface between the two amorphous materials. In some implementations SAB may be used to bond a polished diamond die to one or more of the silicon wafers without a smoothening layer and/or bond layer. SAB may be used to form a reconstituted wafer product based on one or two silicon wafers bonded to diamond dies, e.g., smoothened diamond dies with silicon smoothening layers. The silicon may be deposited by CVD, and smoothened by CMP. Optionally, there may be a laser annealing step between CVD silicon deposition and CMP to increase the crystallinity and thermal conductivity of the thin silicon film.

In ADB, the bonding surfaces are cleaned and UHV thin films (e.g., 1-5 nm) of metal (e.g., Ti) or semiconductor (e.g., Si or AlN) or oxide are formed on the bonding surfaces e.g., by sputtering of atoms, ions, neutral species, or clustered species. The thin films may be amorphous or crystalline films. Because the films are freshly created in UHV they bond together very effectively by bringing the surfaces into contact with each other and subjecting them to little or no pressure (force) and minimal/no heating. The resulting structure has at least two interfaces, one between the wafer and an interfacial bonding layer and another between the interfacial bonding layer and the smoothening layer. ADB equipment is commercially available, e.g., from Canon Anelva Corporation of Kanagawa®, Japan. ADB may be used to form a reconstituted wafer product based on one or two silicon wafers bonded to diamond dies, e.g., smoothened diamond dies with silicon smoothening layers. The silicon may be deposited by CVD, and smoothened by CMP. Optionally, there may be a laser annealing step between CVD silicon deposition and CMP to increase the crystallinity and thermal conductivity of the thin silicon film. The thin films used for bonding may be titanium, silicon or an oxide.

Plasma-assisted bonding (PAB) of silicon substrates is commonly used in CMOS foundries for advanced packaging, e.g., hybrid bonding, with process temperatures from 150° C. to 400° C. PAB bonding is very mature for wafer-to-wafer bonding. Furthermore, PAB may not require ultra-high vacuum. These are all benefits of PAB. However, the PAB bond relies on dielectric films (e.g., SiO₂ or SiCN) with a very low thermal conductivity (˜1 W/m-K) resulting in a relatively high thermal barrier resistance despite the relatively low film thickness of 100's nanometers. Thus, there may be a need to reduce the thermal resistance for PAB by further thinning the bond layers and/or increasing the thermal conductivity of these bond layers. Furthermore, PAB has strict roughness requirements (e.g., Sa<0.5 nm). PAB may be used to form a reconstituted wafer product based on one or two silicon wafers bonded to diamond dies, e.g., smoothened diamond dies with silicon or dielectric smoothening layers. The thin films used for bonding may be silicon oxide, silicon nitride, silicon carbon-nitride, or similar dielectrics. The smoothening and bonding films may be deposited by CVD, and smoothened by CMP.

Thermo-compression bonding (TCB) historically is mainly used for vertical interconnects and perimeter sealing (e.g., MEMS) with silicon at temperatures of 300° C. to 500° C. and requires significant force (e.g., 10's MPa). Typical bond line thickness for TCB is in the micrometer range (e.g., 1-10 micrometers). TCB's roughness requirements are less strict (e.g., Sa<3 nm). Process temperature and force in TCB may be reduced by improved smoothness, flatness, and cleanliness of the metal surfaces. Improved smoothness, flatness, and cleanliness may also allow for thinner films. Furthermore, coefficient-of-thermal expansion (CTE) matching of the diamond and wafers may allow a further thickness reduction of the metal films. As such, the similar CTE for silicon and diamond may be very beneficial for a further (bond) film thickness reduction when silicon wafers are used to build the reconstituted wafer product. Common materials used for metal bonding are gold and copper. Process temperature and force reduction may allow for fragile stacks (e.g., avoiding device, lateral or vertical interconnect damage), compatibility with temporary adhesives, alignment accuracy improvement, reduced warpage, reduced thermal stress, etc. TCB is a form of metal bonding that involves solids only. TCB may be used to form a reconstituted wafer product based on one or two silicon wafers bonded to diamond dies, e.g., smoothened diamond dies with copper smoothening layers. Copper may be deposited by plating onto e.g., titanium and/or nickel deposited by PVD onto the diamond dies, and the copper may be smoothened by CMP. The bond layer on the wafers may be copper with an adhesion layer (e.g., titanium), and a diffusion barrier layer (e.g., titanium nitride, nickel, etc.) between the silicon wafer and the copper. A copper foil in a range of 50 micrometers to 750 micrometers may be sandwiched between the diamond dies and the heat sink side wafer. Alternatively, a foil of aluminum may be sandwiched between the diamond dies and the heatsink-side wafer. The aluminum foil may be coated, e.g., with an adhesion layer, diffusion barrier layer, and copper. Instead of a metal foil, dies or wafers of silicon carbide may be used. The silicon carbide may be coated, e.g., with an adhesion layer, diffusion barrier layer, and copper. Instead of copper for smoothening and bonding, aluminum films may be used.

In some implementations the smoothing layer may be omitted by using solders and/or eutectics with process (liquification) temperatures above 300° C. Metal bonding that involves a liquid includes solder bonding, eutectic bonding, and transient liquid phase bonding (TLPB). These liquid-based forms of metal bonding have the added benefit of further lowering temperature (e.g., 180° C. to 300° C.) and force requirements (e.g., <1 MPa), and reduced roughness requirements (e.g., Sa<100 nm). In addition, organic or polymer bonding involves deposition of a precursor, molecule, monomer, oligomer, or polymer on one or two surfaces followed by bonding. This implementation may require only metallization of the wafer (e.g., Ti/Ni) and diamond die (e.g., Ti), with no smoothening layers. Deposition may be performed by dispensing, pre-forms, or printing. Example materials for this process may be for example and without limitation lead-containing eutectics, solders, and/or brazing materials of the Pb—Ag, Pb—Sn—Ag, Pb—In—Ag, Zn, Zn—Sn, and Zn—Al family. Some non-limiting examples include Pb90Sn5Ag5, Pb95.5Sn2Ag2.5, Pb90In5Ag5, Pb95Ag5. Other examples of TLPB bonding materials include tin or indium containing materials for example, without limitation, Cu—Sn, Ni—Sn, Au—Sn, Ag—Sn, Ag—In, and Au—In. TLPB may be used to form a reconstituted wafer product based on one or two silicon wafers bonded to diamond dies. Copper may be deposited by plating onto e.g., titanium and/or nickel deposited by PVD onto the diamond dies, and subsequently tin may be plated over the copper. The bond layer on the wafers may be copper with an adhesion layer (e.g., titanium), and a diffusion barrier layer (e.g., titanium nitride, nickel, etc.) between the silicon wafer and the copper. Optionally, tin may be plated over the copper on the silicon wafer. A copper foil in a range of 50 micrometers to 750 micrometers may be sandwiched between the diamond dies and the heat sink side wafer. Alternatively, a foil of aluminum may be sandwiched between the diamond dies and the heat sink side wafer. The aluminum foil may be coated, e.g., with an adhesion layer, diffusion barrier layer, and copper. Instead of a metal foil, dies or wafers of silicon carbide may be used. The silicon carbide may be coated, e.g., with an adhesion layer, diffusion barrier layer, and copper.

Sintering may be also used to bond the surfaces. A silver sintering paste, gold sintering paste or copper sintering paste may be applied as the bond layer. Sufficient heat and pressure may be applied at the bonding surface to cause the sintering paste to form a bond with the sintering paste. For example and without limitation, sintering with copper paste may be used. Sintering may be done at temperatures below 250° C., either with minimal force (e.g., <1 MPa), or high force (e.g., >10 MPa). The final bond line thickness may be 50 microns, or 10 microns. The sintered layer may be porous or dense. The sintered layer may have a thermal conductivity over 100 W/m-K, even over 150 W/m-K. Sintering may be used to form a reconstituted wafer product based on one or two silicon wafers bonded to diamond dies. Copper, or silver, or gold may be deposited by plating onto, e.g., titanium and/or nickel deposited by PVD onto the diamond dies. Copper, or silver, or gold may be deposited with an adhesion layer (e.g., titanium), and a diffusion barrier layer (e.g., titanium nitride, nickel, etc.) between the silicon wafer and the copper, or silver, or gold. A sintering paste, e.g., silver paste, may be placed between the silicon wafer and the diamond dies. A copper foil in a range of 50 micrometers to 750 micrometers may be sandwiched between the diamond dies and the heat sink side wafer. Alternatively, a foil of aluminum may be sandwiched between the diamond dies and the heatsink-side wafer. The aluminum foil may be coated, e.g., with an adhesion layer, diffusion barrier layer, and copper, silver, or gold. Instead of a metal foil, dies or wafers of silicon carbide may be used. The silicon carbide may be coated, e.g., with an adhesion layer, diffusion barrier layer, and copper, silver, or gold.

In implementations using adhesives the adhesive material may be any material suitable for adhering the two surfaces together. Some examples include without limitation, pressure sensitive adhesives, UV curing adhesives, thermoplastics, solvent curing adhesives, carbon-nanotube filled adhesives, graphene filled adhesive, brewerBOND® material, waferBOND® material, etc. These adhesives may be permanent (permanent bonding) or removed (temporary bonding) during manufacturing using the appropriate removal technique for the type of temporary adhesive. Curing of the adhesives (e.g., cross linking) may be based on heat, irradiation (e.g., UV), or water for adhesives, or based on cooldown for thermoplastic materials. The thickness of the organic bond line may be 100 nanometers, or as thin as 5 nanometers. Deposition may be performed by spin coating, spraying, dipping, or jetting. Materials may be polymers, epoxies, photoresists, benzocyclobutene (BCB) derivatives, spin-on photo-dielectrics, silicones, molecules, head-to-tail oligomers, siloxanes, or polyimides. Similarly, spin-on glass or polymer-derived ceramics may be used, e.g., polysilazane derivatives (e.g., polyborosilazane), polysiloxane derivatives, polysilane derivatives (e.g., polycarbosilane), polysilsesquioxanes, polysilsesquiazanes, polysilylcarbodiimides, etc. These materials may be filled with nano-sized materials with a high thermal conductivity (and lower CTE), e.g., diamond nanopowder, aluminum nitride (AlN) nanopowder, silicon nitride (SiNₓ) nanopowder, beryllium oxide (BeO) nanopowder, aluminum oxide (Al₂O₃) nanopowder, graphite, carbon nanotubes, graphene, etc. In some implementations the powder is part of a formulation that includes additives to control stability, e.g., surfactants, and application, e.g., rheology modifiers. A non-exhausting list of additive examples are binders, anti-settling agents, dispersants, curing agents, anti-foaming agents, and thinners (e.g., solvents).

Temporary bonding may be used in multiple steps during the processing. Temporary bonding may be used for thinning the wafers. Temporary bonding may be used with thinning the heatsink side wafer. The thinned logic side wafer may be placed onto the temporary carrier prior to thinning the heatsink side wafer. The temporary carrier may be made of glass, silicon, sapphire, quartz, or silicon carbide. The temporary carrier may match in CTE with the bonded wafer or dies. The temporary carrier may have through holes, e.g., to aid in chemical or solvent debonding. The temporary carrier may be optically transparent, e.g., to aid in optical debonding. The temporary carrier may support electrostatic bonding and debonding. The temporary carrier may contain a buried layer or surface layer that supports optical debonding. The temporary adhesive may be organic or inorganic. The temporary adhesive may cross-link or be a thermoplastic. Alternatively the temporary bonding may be performed by Van Der Waals bonding, e.g., based on hydrophilic surfaces. The temporary adhesive may contain one coating, or more than one coating. One of these coatings may absorb light, e.g., laser, UV, or pulsed light, which aids in debonding. The temporary carrier may have alignment marks. The temporary carrier may be bonded by a permanent bonding method, e.g., SAB, ADB, PAB, or TCB. The temporary bonding may be accomplished by a mobile electrostatic carrier. The final removal of the temporary carrier may be based on (visible or IR) laser debonding, UV debonding, thermal (slide) debonding, chemical debonding, (thermo-) mechanical debonding, (thermal) solvent debonding, electrostatic debonding, or abrasive and/or chemical removal of the temporary carrier.

In some implementations bonding may utilize a multi-layer thermally reactive foil that provides instantaneous or extremely rapid heating. Such a reactive multi-layer foil may be fabricated by vapor-depositing thousands of alternating nanoscale layers of Aluminum (Al) and Nickel (Ni). When activated by a small pulse of local energy from electrical, optical or thermal sources, the foil reacts exothermically to precisely deliver localized heat up to temperatures of 1500° C. in fractions (thousandths) of a second. By way of example, and not by way of limitation, an Al—Ni multi-layer thermally reactive foil is sold commercially under the name NanoFoil® by Indium Corporation of Clinton New York. Nanofoil® is a registered trademark of Thermal Conductive Bonding, Inc. of Sacramento, California. Other foil compositions may be boron-titanium, aluminum-titanium, and titanium-silicon. In addition to the energetic multi-layer material other materials may be included in the stack that specifically melt, comply with surfaces, and react with the wafers or diamond dies to be bonded.

### Gap Filler

The gap filler material may be a depositable material or a through-hole gap filler wafer as discussed above. Alternatively, the gaps are filled by the walls of one or more pocketed wafers. The gap filler material preferably has a Coefficient of Thermal Expansion (CTE) matched closely with both Si and the die containing diamond and some stiffness to support ultrathin silicon between the dies containing diamond. Additionally, it is desirable that the gap filler material is a material suitable for dicing by traditional dicing means (e.g., saw, laser, or plasma dicing) and when fully filling the gaps easily planarized. Some implementations may use gap fillers such as and without limitation: spin-on-glass (SOG), machined silicon through-hole wafer, low-CTE polyimide (2-3 ppm/C), borosilicate or silica glass in sol-gel form (3-5 ppm/C), or glass powder filled adhesives/polymers, polybenzimidazole (5 ppm/C). Additionally, in some implementations, the gap filler may help with avoiding edge rounding when smoothening the smoothening layer (e.g., CMP).

### Smoothening Layer

It is often economically desirable to be able to use diamond dies with surfaces that are not perfectly smooth and with a relaxed thickness tolerance in a reconstituted wafer product. In such cases, a smoothening layer may be formed on the surface(s) of the diamond dies to accommodate for imperfections in the diamond die surface(s). The smoothening layer may deal with surface roughness, but also with dimensional (thickness) tolerances (e.g., bow, warp, flatness, total thickness variation (TTV), or target thickness). The smoothening layer allows the reconstituted wafer product to use incoming rough diamond dies with a broad range in dimensional (thickness) and roughness tolerances. After smoothening (e.g., CMP) the smoothening layer, the surfaces are smooth, and the dimensional (thickness) tolerances are tight. Smoothening may be performed by applying a coating, e.g., photoresist, followed by ion beam etching.

Smoothening layers (either of microns thickness with high thermal conductivity, or 10's to 100's nanometers when low thermal conductivity) may include but are not limited to: Copper (plated, e.g., 15 micrometer with thermal conductivity close to 400 W/m-K), silicon (polycrystalline/microcrystalline by hot CVD of microns thickness and thermal conductivity ˜50 W/m-K, or amorphous silicon by colder CVD when 10's to 100's nanometers and thermal conductivity ˜1 W/m-K). Note here that smoothening layers may be applied to the bonding surfaces of the diamond dies and may be excluded from the gaps in between the diamond dies. The bonding surfaces of the diamond dies may be lapped and, in some implementations, polished appropriately for the chosen bonding method. For example and without limitation, application of an amorphous or nanocrystalline silicon smoothening layer may be suitable to smoothen a lapped diamond die surface whereas application of a polycrystalline silicon smoothening layer may be more suitable for a diamond die with a rougher surface and more relaxed thickness tolerances.

The thickness of the smoothening layer(s) depends on the roughness and thickness variation of the diamond die. The higher the thickness variation of incoming diamond die, the thicker the smoothening layer needs to be and the higher the thermal conductivity of the smoothening layer needs to be. The surface roughness and thickness variation of the diamond die depends on where in the diamond die fabrication process the diamond die is picked. In general terms, the further upstream one picks the diamond die from the wafering line, the rougher and larger the thickness variation and generally, the lower the cost of producing the diamond die. By way of example, and not by way of limitation, at certain early stages of diamond die fabrication, e.g., before lapping has been started or is complete, the diamond die surface may be rough, e.g., 100 nm to 300 nm mean surface roughness with high thickness variation Δt, e.g., 5 μm<Δt<30 μm. At an intermediate stage, e.g., after lapping is complete, the diamond die surface may be rough, e.g., less than 100 nm mean surface roughness with a tight thickness variation Δt, e.g., Δt<5 μm. At a later stage, the diamond die surface may be smooth, e.g., <5 nm roughness with a tight thickness variation Δt, e.g., Δt<5 μm.

The previous descriptions provide a non-limiting list of multiple permutations of smoothening layers, bond layers, diamond die surface finish, gap filler type, bond methods, and wafers for the reconstituted wafer heat spreader product and their suitability for bonding to integrated circuit device package types. The overall thickness of the reconstituted wafer product may vary. As a non-limiting example, the thickness of the reconstituted wafer product may be roughly 2,325 micrometers prior to thinning the logic side and heat sink side wafers and may be roughly 800 micrometers after thinning the logic side and heat sink side wafers. The final thickness may be the result of 300 micrometers thick diamond die, e.g., SCD, and 450 micrometers copper foil, in addition to 10 to 30 micrometers silicon on the logic side and heat sink side. The manufacturing of the reconstituted wafer product may start with full thickness wafers, e.g., 775 micrometers thick, 300 millimeters diameter silicon wafers, or may start with partially thinned wafers that are easily handled, e.g., 350 micrometers thick. Alternatively, the incoming wafers may be thicker than the standard 775 micrometers when pocketed wafers may be used for the reconstituted wafers. Thus, aspects of the present disclosure represent a heat spreader product which may include one or more reconstituted wafers. The reconstituted wafer may provide structural stability to the product allowing for easier integration.

Gap filling or deposition of thick films, e.g., copper, may be performed by plasma spraying.

Planarization of two or more diamond die surfaces to the same plane to facilitate bonding to either the first, second, or both wafers may be achieved in various ways. In one example, diamond dies are planarized by lapping and polishing to a tight thickness tolerance and to create smooth surfaces. Optionally, binning may be used to remove overly thick and/or rough dies to ensure a tight thickness tolerance for the diamond dies on the same wafer. The diamond dies may optionally be arranged such that the thickness gradually changes from side to side or center to edge on the same wafer. For example and without limitation the thickness may change such that thicker dies are in the center with the thickness decreasing towards the edge or vice versa. In another example, diamond dies may be bonded to the first wafer, metal, e.g., copper, may then be plated globally (e.g., at wafer level) over the diamond dies, followed by planarizing the copper film, e.g., by CMP. The diamond dies may be placed in pockets with the diamond die surfaces below the pocket wall top. Planarization by plating and CMP may result in removing all metal from the pocket wall tops, yet with metal remaining on the diamond die surfaces flush with the pocket wall tops. Subsequent bonding to the second wafer may result in perimeter sealing by bonding two silicon surfaces. Bonding may be hybrid bonding. The diamond dies may be placed in pockets with one or more diamond die surfaces above the pocket wall tops. Planarization by plating and CMP may result in metal remaining on the pocket wall tops, in addition to metal remaining on the diamond die surfaces, all in the same plane. In yet another example, planarization may be achieved by bonding diamond dies to a carrier followed by height correcting the diamond dies to the same plane by use of a laser. Alternatively the diamond dies may be height corrected to the same plane by etching, e.g., by ion beam etching or ion beam trimming. Alternatively, the diamond dies may be height corrected to the same plane by abrasive techniques, e.g., lapping or grinding. In yet another example, the need for planarization may be reduced or avoided by bonding diamond dies with materials compliant during the bond process, e.g., sinter paste, sinter die attach film, zinc, solder, eutectic, TLPB materials, adhesives, or surface melting the wafer surface. Compliance may result in squeezing out of the compliant material outside the diamond die area.

The bonding of the diamond dies to form the reconstituted diamond wafer (either based on one wafer with diamond dies or diamond dies sandwiched between two wafers) may be performed by sequential die to wafer bonding followed by wafer to wafer bonding, collective dies to wafer bonding followed by wafer to wafer bonding, or placing the diamond dies followed by wafer to wafer bonding with the latter bonding the diamond dies to both wafers in one step. The bonding may be SAB, ADB, PAB, LAB, TCB, TLPB, eutectic, solder, brazing, or sinter bonding to bond the diamond dies to the first wafer. The bonding may be SAB, ADB, PAB, LAB, TCB, TLPB, eutectic, solder, brazing, or sinter bonding to bond the diamond dies to the second wafer. SAB may be with a thin intermediate film, e.g., sputtered silicon, or without an intermediate film. PAB may be with a dielectric film deposited on the diamond die, e.g., silicon dioxide, or without a dielectric film deposited on the diamond die. LAB may use a laser that emits light of a wavelength that is readily absorbed by the wafer, e.g., a silicon wafer, and reaching the bond interface through the diamond die, or LAB may be using a laser that is reaching the bond interface through the wafer, e.g., a silicon wafer, that is absorbed by a dedicated absorber layer at the bond interface, e.g., germanium. TCB may be using films containing aluminum, zinc, nickel, copper, silver, or gold. TLPB (or SLID) may be based on one or more high-melting metals, e.g., nickel, copper, silver, or gold with one or more low-melting point metals, e.g., tin, bismuth, or indium. A high melting point metal (e.g., Ni, Cu, Ag, Au) may be deposited on the wafer or diamond die before depositing the low melting point metal (e.g., Sn, Bi, In) onto the high melting point metal. A thin temporary barrier layer, e.g., titanium, may be deposited between the high melting point metal and the low melting point metal. Eutectic or elemental bonding may be done using a zinc film, formed e.g., by plating, onto one or both silicon wafers, and a metal layer on the diamond die, e.g., titanium, or nickel. Eutectic bonding may use aluminum-germanium, e.g., deposited onto one or both silicon wafers, and a metal layer on the diamond die, e.g., titanium, or nickel. The bonding may be performed by heating the wafer and dies globally, or by heating the bond interface locally, e.g., with a laser. Laser-assisted heating may be used in conjunction with a solder, eutectic, brazing material, or metal, e.g., zinc. Sintering may be performed with a silver paste, silver die attach film, copper paste, or copper die attach film. Sintering may be performed in an inert atmosphere.

The bonding of the diamond dies or reconstituted diamond wafer (either based on one wafer with diamond dies or diamond dies sandwiched between two wafers) to the logic wafer or logic element dies may be performed by sequential die to wafer, collective dies to wafer, collective dies to collective dies, wafer to wafer, or die to die. Sequential die to wafer bonding may be performed by diamond die to logic wafer, or logic element die to reconstituted diamond wafer. Collective dies to wafer may be performed by collective diamond dies to logic wafer, or collective logic element dies to reconstituted diamond wafer. The bonding may be SAB, ADB, PAB, LAB, TCB, TLPB, eutectic, solder or sinter bonding. SAB may be with a thin intermediate film, e.g., sputtered silicon, or without an intermediate film. PAB may be done with a dielectric film deposited on the diamond die, e.g., silicon dioxide, or without a dielectric film deposited on the diamond die. LAB may be using a laser that emits radiation that is readily absorbed by the wafer, e.g., silicon wafer, and that reaches the bond interface through the diamond die. Alternatively, LAB may be done using laser radiation that reaches the bond interface through the wafer, e.g., silicon wafer, and is absorbed by a dedicated absorber layer at the bond interface, e.g., germanium. TCB may be done by bonding via films containing copper, silver, or gold. TLPB (or SLID) may be based on one or more high-melting (i.e., high melting point) metals, e.g., copper, silver, or gold with one or more low-melting metals (i.e., low melting point metals), e.g., tin, bismuth, or indium. The high-melting metal (e.g., Cu, Ag, Au) may be deposited on the wafer or diamond die before depositing the low-melting metal (e.g., Sn, Bi, In) onto the high-melting metal. A thin temporary barrier layer, e.g., titanium, may be deposited between the high-melting metal and the low-melting metal. Eutectic or elemental bonding may be using a zinc film, e.g., by plating, deposited onto one or both silicon wafers, and a metal layer on the diamond die, e.g., titanium, or nickel. Eutectic bonding may be using aluminum-germanium, e.g., deposited onto one or both silicon wafers, and a metal layer on the diamond die, e.g., titanium, or nickel. The bonding may be performed by heating the wafer and dies globally, or by heating the bond interface locally, e.g., by absorption of laser radiation. Laser-assisted heating may be used in conjunction with a solder, eutectic, or metal, e.g., zinc. Sintering may be performed with a silver paste, silver die attach film, copper paste, or copper die attach film. Sintering may be performed in an inert atmosphere.

In an implementation, the diamond dies may be fabricated with a target thickness of for example and without limitation 300 micrometers and a thickness range around the target thickness within 40 micrometers, preferably within 20 micrometers, even more preferred within 10 micrometers, yet most preferred within 5 micrometers. The diamond dies may have a roughness of less than 100 nanometers. The diamond dies may be single crystal diamonds with a surface crystal orientation of (100), and a die edge crystal orientation of (100). The diamond dies may have bevels. The diamond dies may have a thermal conductivity larger than 2000 W/m-K. The wafers may be deposited with an optional adhesion layer (e.g., sputtered titanium or tantalum), followed by an optional barrier layer (e.g., TIN, TaN, nickel, or nickel-vanadium), followed by a bond layer of e.g., silver, gold, or copper, with a thickness of e.g., 0.5 micrometers to 2 micrometers. The bond layer may be deposited by plating, evaporation, or sputtering. The diamond dies may be deposited by titanium or chromium, optionally followed by e.g., nickel or nickel-vanadium. On top of these metal layers on the diamond dies, a bond layer of e.g., silver, gold, or copper, with a thickness of e.g., 0.5 micrometers to 2 micrometers may be deposited. Subsequently, the wafers and the diamond dies may be bonded together by sintering, e.g., by applying a silver paste or silver sinter film for die attachment between the first wafer and the diamond dies. Sintering may include a drying step, e.g., for 20 minutes at 120 Celsius after applying the sintering material. The sintering may also include a planarization step. The planarization step may include pressing on the diamond dies after placing the diamond dies on the sintering material on top of the first wafer. The planarization step may be performed at a temperature and force that does not result in full sintering. In some non-limiting example methods sintering may be performed for 1 minute at a pressure of 12-16 MPa at a temperature of 220 Celsius. The bond surfaces may be cleaned from organics, and/or particles and/or oxides prior to bonding. Particles may be removed via an ultrasonic spin rinse, or ultrasonic bath treatment. Oxides may be removed via a suitable wet acid clean (e.g., citric acid rinse for copper), a (vacuum) anneal (e.g., decomposing silver oxide), or a (vacuum or atmospheric) plasma clean. The particle and/or oxide removal may be performed offline or inline. The bonding may be performed in air, in a controlled environment, in an inert environment, or in a vacuum environment. Instead of silver sintering, copper may be used for sintering. Subsequently, the second wafer may be bonded to the first wafer resulting in a wafer-to-diamond-dies-to-wafer stack. The second wafer may be bonded in a similar manner by sintering. The second wafer may be bonded simultaneously while bonding the diamond dies to the first wafer. The second wafer may be bonded in a separate bonding step. The second wafer may be bonded by a method other than sintering, e.g., SAB, ADB, PAB, LAB, TCB, TLPB, brazing, eutectic, or solder bonding. The first wafer, second wafer, or both wafers may be silicon wafers. The gaps between the diamond dies may be filled partially or completely prior to bonding the second wafer, e.g., by spin-on-glass (SOG). The gaps between the diamond dies may get filled post bonding, e.g., by a process similar to applying underfill in chip packaging. Alternatively, the gaps may be filled post bonding through small holes or slits in one or both wafers. The gaps may be filled by using one or more pocket wafers. The gaps may be filled by using a through-hole wafer. The gaps may be partially or completely filled by copper plating. The gaps may be filled by a combination of two or more methods. The perimeter between both wafers may be filled prior to or post bonding by underfill materials, molding materials, photoresist materials. The perimeter may be filled by one or more pocket wafers. The perimeter may be filled by a through-hole wafer. The perimeter may be filled in a similar fashion to the gaps between the diamond dies. The perimeter may be filled simultaneously with filling the gaps between the diamond dies. The perimeter may contain silicon dummy dies bonded between the first and second wafer to mechanically strengthen the outer perimeter of the bonded stack. These silicon dummy dies may be bonded simultaneously with the diamond dies. The diamond dies may be bonded to the first wafer by a sequential die to wafer bonding method, e.g., on a flip chip die bonder. The diamond dies may be bonded to the first wafer by collective diamond dies to wafer bonding. This collective bonding may be on a bonder with die-level force (or pressure) control, e.g., by individually controlled die-level bond heads, or by incorporating compliant materials, e.g., elastomers, during bonding. In yet another implementation, the diamond dies may only be bonded to the first wafer without bonding to a second wafer. As such, the product may be diamond dies sandwiched between two wafers, or diamond dies bonded to only one wafer. Alternatively, the diamond dies may be bonded to silicon coupons instead of one or more wafers, or the diamond dies are bonded to one or more wafers followed by dicing, and these diamond dies are placed onto a temporary carrier, e.g., film frame (tape in frame), tape-and-reel, waffle packs, or a wafer carrier (e.g., glass) with a temporary adhesive. The diamond dies may be bonded to a first and second wafer followed by thinning one or both wafers. The thinning may be performed by a single-sided process tool, e.g., a single-sided grinder, or a double-sided process tool, e.g., a double-sided lapper or grinder. The thinning may be performed by first thinning the stack by processing on a double-sided tool, followed by thinning on a single-sided tool. In addition to thinning, the wafers in the stack may be beveled, e.g., prior to lapping. Furthermore, one or both wafers may be smoothened, e.g., by CMP. The diamond chiplets may be bonded to one wafer or sandwiched between two wafers or individual diamond chiplets may be integrated by bonding to a partially or fully finished logic wafer or logic element dies. Alternatively, the diamond chiplets bonded to one wafer or sandwiched between two wafers may be integrated prior to (logic or CMOS) device fabrication. This means that the devices are built on top of the diamond reconstituted wafer. As such, the diamond reconstituted wafer needs to be compatible with all the processing steps for the device fabrication which include e.g., vacuum compatibility, temperature compatibility, chemistry compatibility, and mechanical compatibility. Process temperatures during certain stages of device fabrication may reach over one thousand degrees Celsius, e.g., during dopant activation. As a result, metals that diffuse easily into the semiconductor, e.g., into silicon semiconductor, and/or easily contaminate the semiconductor, e.g., silicon semiconductor, may not be used, e.g., copper, silver, gold, or iron. Examples of metals that may be used include tungsten, molybdenum, and ruthenium.

The manufactured product may be metallized diamond dies (e.g., Ti/Ni/Ag) sandwiched between two metallized silicon wafers (e.g., Ti/Ni/Ag) with the wafers bonded to the diamond via silver sintering. The thickness of each of the dies containing diamond may vary from e.g., 100 micrometers to 800 micrometers. The diamond die size may be close to the full reticle limit of 33×26 mm. In another embodiment, the product may be metallized diamond dies sintered to one metallized silicon wafer. The diamond die surface facing away from the sintered bond interface with the bonded wafer may be metallized (e.g., Ti/Ni/Ag) and suitable for bonding to a logic wafer or logic element die e.g., by sintering. The diamond die surface facing away from the sintered bond interface with the bonded wafer may be metallized with a precursor to TLPB, e.g., a layer containing Cu, Ag, or Au followed by a layer containing Sn, Bi, or In on top, and suitable for TLPB to a logic wafer or logic element die. The diamond die surface facing away from the sintered bond interface with the bonded wafer may be metallized with a eutectic, e.g., a layer containing aluminum and germanium, and suitable for eutectic bonding to a logic wafer or logic element die, either with global (e.g., wafer-level) or localized (e.g., die-level) heating. The diamond die surface facing away from the sintered bond interface with the bonded wafer may be metallized with a metal film, e.g., a layer containing zinc, and suitable for bonding to a logic wafer or logic element die, either with global (e.g., wafer-level) or localized (e.g., die-level) heating. The diamond die surface facing away from the sintered bond interface with the bonded wafer may be metallized with a metal film, e.g., a layer containing Cu, Ag, or Au, and suitable for TCB to a logic wafer or logic element die. The diamond die surface facing away from the sintered bond interface with the bonded wafer may be sufficiently flat and smooth with the diamond die surfaces in a sufficiently tight topographical plane for bonding the diamond die surface to a logic wafer or logic element die by SAB, ADB, or PAB. The diamond die surface facing away from the sintered bond interface with the bonded wafer may be bonded by LAB to a logic wafer or logic element die. The wafer may be thinned sufficiently, e.g., below 50 micrometers that it provides sufficient flexibility to alleviate potential diamond die height variations for wafer to wafer bonding.

The manufactured product may be metallized diamond dies (for example and without limitation metalized with Ti/Ni) sandwiched between two metallized silicon wafers (for example and without limitation metalized with Ti/Ni/Zn) with the wafers bonded to the diamond dies via zinc softening or zinc melting. The thickness of the dies containing diamond may vary from, e.g., 100 micrometers to 800 micrometers. The horizontal length and width of the diamond die may be close to the full reticle limit of 33 mm×26 mm. In another embodiment, the product may be metallized diamond dies zinc bonded to one metallized silicon wafer. The diamond die surface facing away from the zinc bond interface with the bonded wafer may be metallized (by, for example and without limitation, Ti/Ni/Ag) and suitable for bonding to a logic wafer or logic element die e.g., by sintering. The diamond die surface facing away from the zinc bond interface with the bonded wafer may be metallized with a precursor to TLPB, e.g., a layer containing Cu, Ag, or Au followed by a layer containing Sn, Bi, or In on top, and suitable for TLPB to a logic wafer or logic element die. The diamond die surface facing away from the zinc bond interface with the bonded wafer may be metallized with a eutectic, e.g., a layer containing gold and silicon, and suitable for eutectic bonding to a logic wafer or logic element die, either with global (e.g., wafer-level) or localized (e.g., die-level) heating. The diamond die surface facing away from the zinc bond interface with the bonded wafer may be metallized with a metal film, e.g., a layer containing Cu, Ag, or Au, and suitable for TCB to a logic wafer or logic element die. The diamond die surface facing away from the zinc bond interface with the bonded wafer may be sufficiently flat and smooth with the diamond die surfaces in a sufficiently tight topographical plane for bonding the diamond die surface to a logic wafer or logic element die by SAB, ADB, or PAB. The diamond die surface facing away from the zinc bond interface with the bonded wafer may be bonded by LAB to a logic wafer or logic element die. The wafer may be thinned sufficiently, e.g., below 50 micrometers that it provides sufficient flexibility to alleviate potential diamond die height variations for wafer to wafer bonding.

The manufactured product may be diamond dies sandwiched between two silicon wafers with the wafers bonded to the diamond dies via laser assisted bonding (LAB). The laser may have a wavelength in the UV, e.g., 308 nm, in the visible range, e.g., 445 nm, in the infrared range, e.g., 1070 nm, 1567 nm, or 10.6 μm. The laser may reach the bond interface through the silicon, e.g., 1567 nm, or through the diamond, e.g., 308 nm, 445 nm, 1070 nm, or 10.6 μm. The laser may have a pulse length in the fs, ps, ns, us, or ms range. The laser may be multi-kilowatt power. The laser may be defocused to a large area, e.g., around 33×26 mm. The laser may be rastered over a large area, e.g., around 33×26 mm. The laser pulse may have a Guassian shape, rectangular shape, triangular shape, or a customized shape. One or more lasers may be used simultaneously, either from one side, or both sides of the bond interface. The wafers and/or diamond dies may be additionally heated by conventional means, e.g., lamp heating, or resistive heating prior to or during the laser-assisted bonding. One or both silicon wafers may be coated with a dedicated absorption layer, e.g., doped silicon, or germanium. The diamond thickness may vary from e.g., 100 micrometers to 800 micrometers. The diamond die size may be close to the full reticle limit of 33×26 mm. In another embodiment, the product may be diamond dies bonded by laser assist to one silicon wafer. The diamond die surface facing away from the LAB bond interface with the bonded wafer may be metallized (by for example and without limitation, Ti/Ni/Ag) and suitable for bonding to a logic wafer or logic element die e.g., by sintering. The diamond die surface facing away from the LAB bond interface with the bonded wafer may be metallized with a precursor to TLPB, e.g., a layer containing Cu, Ag, or Au followed by a layer containing Sn, Bi, or In on top, and suitable for TLPB to a logic wafer or logic element die. The diamond die surface facing away from the LAB bond interface with the bonded wafer may be metallized with a eutectic, e.g., a layer containing aluminum and germanium, and suitable for eutectic bonding to a logic wafer or logic element die, either with global (e.g., wafer-level) or localized (e.g., die-level) heating. The diamond die surface facing away from the LAB bond interface with the bonded wafer may be metallized with a metal, e.g., a layer containing zinc, and suitable for bonding to a logic wafer or logic element die, either with global (e.g., wafer-level) or localized (e.g., die-level) heating. The diamond die surface facing away from the LAB bond interface with the bonded wafer may be metallized with a metal film, e.g., a layer containing Cu, Ag, or Au, and suitable for TCB to a logic wafer or logic element die. The diamond surface facing away from the LAB bond interface with the bonded wafer may be sufficiently flat and smooth with the diamond die surfaces in a sufficiently tight topographical plane for bonding the diamond die surface to a logic wafer or logic element die by SAB, ADB, or PAB. The diamond die surface facing away from the LAB bond interface with the bonded wafer may be bonded by LAB to a logic wafer or logic element die. The wafer may be thinned sufficiently, e.g., below 50 micrometers that it provides sufficient flexibility to alleviate potential diamond die height variations for wafer to wafer bonding.

In addition to the previous examples of bonding the diamond dies to one or both silicon wafers to form a reconstituted diamond wafer by sintering, zinc softening or melting, or LAB, the diamond dies may be bonded to one or both wafers by PAB, TCB, TLPB, eutectic, solder, brazing, SAB, ADB, or adhesive bonding. In yet another embodiment, the first silicon wafer may be bonded to the diamond dies by LAB, and the second wafer may be bonded to the diamond dies by SAB. In yet another embodiment, the first silicon wafer may be bonded to the diamond dies by LAB, and the second wafer may be bonded to the diamond dies by zinc softening or melting. In yet another embodiment, the first silicon wafer may be bonded to the diamond dies by LAB, and the second wafer may be bonded to the diamond dies by sintering. In yet another embodiment, the first wafer may be bonded to the diamond dies by sintering, and the second wafer may be bonded to the diamond dies by SAB. In yet another embodiment, the first wafer may be bonded to the diamond dies by sintering, and the second wafer may be bonded to the diamond dies by copper bonding via either TCB, SAB, or PAB. The copper may be deposited and planarized on a wafer level after bonding the diamond dies to the first wafer. The first wafer may be the logic facing wafer or the heat sink facing wafer. One or both wafers may be silicon wafers with one or more pockets. Gaps may be filled by a through-hole silicon wafer. Gaps may be filled by spin-on-glass, sol-gel, low stress photo-dielectrics, spin-on photo-dielectrics, polyimide, BCB, underfill, photoresist, or similar thermoplastic or curable polymers or adhesives optionally filled with particles. Gaps may be filled by plating, e.g., with copper, zinc, or nickel.

It is often economical to utilize diamond-containing dies that are somewhat non-uniform in thickness and have rough surfaces. This can reduce the expense of lapping the diamond-containing dies to a uniform thickness and polishing their surfaces to a desired degree of smoothness. However, it is challenging to integrate single crystal diamonds with thickness variations between SCD dies, and rough SCD surfaces for advanced AI chip packages where height matching is required to integrate logic die structures with HBM stacks and where processing often involves a planarization step after integrating the HBM stacks and logic dies.

According to aspects of the present disclosure, sintering (e.g., with silver or copper, in either paste form, film form, or both) or laser assisted bonding (laser compression bonding) may be used to accommodate the rough SCD surfaces, within-plate thickness variations, and thickness variations between dies. To deal with the die to die height variations (thickness variations between dies), bonding may be performed where, during bonding, thickness variations may be accommodated by the hardware, e.g., using a sintering tool with die level height or force control, or laser compression bonding with die level height or force control. Both sintering and laser compression bonding may be performed by collective dies to wafer bonding. Similarly, sequential die to wafer bonding may be used as well. Bonding with zinc (Zn), or aluminum (Al) may be used as well. These metals may be introduced by thin film deposition, or by using pre-forms, e.g., die-sized sheets. The bonding may occur above or below the metal melting temperature. The heating may occur globally (e.g., on wafer or die level), or locally (e.g., on die or sub-die level), e.g., by laser assisted heating.

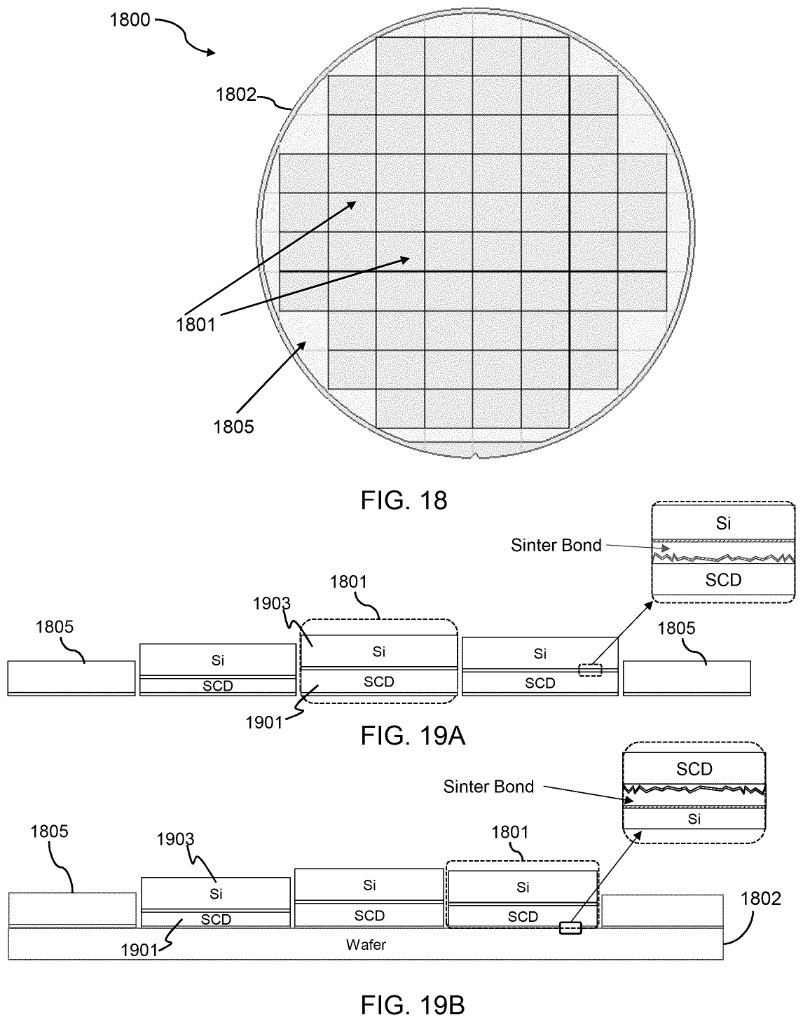

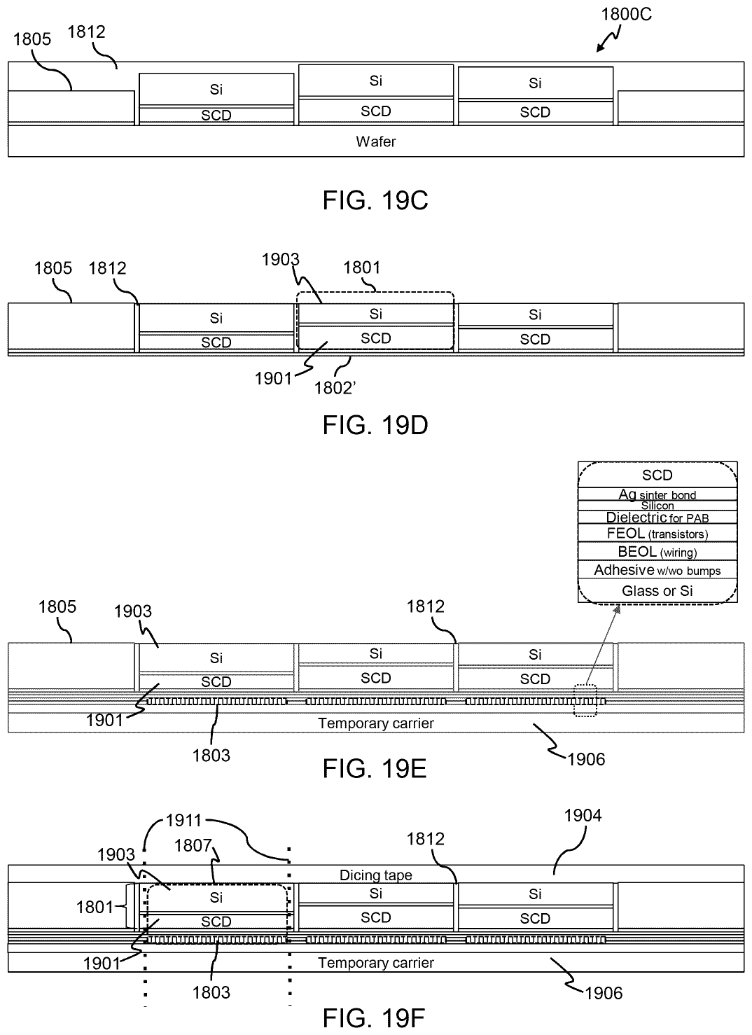

As shown in FIG. 18 and FIGS. 19A-19F, a reconstituted wafer product 1800 may have multiple individual die structures 1801 on a wafer 1802. Processing to form such a product is shown in FIGS. 19A-19F. As shown in FIG. 19A, each of the die structures 1801 includes a die containing diamond (aka, diamond-containing die) 1901, e.g., an SCD die and (optionally) a corresponding heatsink-side die 1903, e.g., a silicon die. The heatsink-side dies may be made of material other than silicon, so long as the material is compatible with semiconductor processing, such as planarization and dicing processes. In some implementations, the heatsink-side die may contain silicon, copper, or silicon carbide. The diamond containing die may be attached to the heatsink-side die using a bond material. Examples of suitable bond materials include, but are not limited to copper, silicon, germanium, silver, zinc, aluminum, or a dielectric. In some implementations the bond material may include silver either alone or in a combination with other metals, e.g., a combination of titanium, nickel, and silver. It is noted that in some implementations, the heatsink-side dies may be omitted from the die structures.

By way of example, and not by way of limitation, the die structure 1801 may include an SCD die bonded to a single crystal silicon die. Bonding may be performed by silver (or copper) sintering, laser assisted bonding, zinc bonding, or aluminum bonding. The die structure may be an SCD die bonded to a copper foil. The copper foil may be bonded to a single crystal silicon die creating a stack of SCD, copper foil, and single crystal silicon. The copper foil may be deposited by a thin film stack including an adhesion layer, barrier layer, and heatsink-facing silicon layer instead of a single crystal silicon die. The copper foil may be in contact with a thermal interface material between the copper foil and the heatsink. Besides copper foil or silicon dies, silicon carbide dies may be used as well. The advantage of silicon dies is the compatibility with semiconductor processing. The advantage of copper foil or silicon carbide dies is the higher thermal conductivity over silicon. The die structure may be in direct contact with a cooling fluid, e.g., by jet impingement cooling as discussed above. The surface of the die structure may be patterned to improve cooling.

As used herein, the term “heatsink side” of the wafer refers to the side of the wafer to which the die structures are attached for a reconstituted wafer based on one wafer with the wafer facing the logic wafer. The term “heatsink-facing” is similarly used to refer to a location or orientation within the die structure on a side of the diamond-containing die that faces away from the logic wafer. The term “heatsink-side surface” is similarly used to refer to the surface on the heatsink side of the wafer for a reconstituted wafer based on one wafer with the wafer facing the logic wafer. As used herein, the term “logic side” refers to the side of the wafer to which the die structures are not attached and the term “logic-side surface” is used to refer to the surface on the logic side of the wafer.

In one implementation, the diamond-containing dies in the die structure may have a target thickness of for example and without limitation 300 micrometers and a thickness variation around the target thickness within 40 micrometers, preferably within 20 micrometers, even more preferred within 10 micrometers, yet most preferred within 5 micrometers. The diamond-containing dies may have a roughness of less than 5 micrometers, even more preferred less than 1 micrometer, even more preferred less than 100 nanometers. The diamond-containing dies may be single crystal diamonds with a surface crystal orientation of (100), and a die edge crystal orientation of (100). The diamond dies may have bevels. In alternative implementations, the diamond-containing dies may be made of polycrystalline diamond.

As shown in the inset in FIG. 19A, the process used to bond the diamond-containing dies 1901 to the heatsink-side dies 1903 may accommodate for the surface roughness of each diamond-containing die. By way of example, and not by way of limitation, silicon dies may be bonded to rough SCD dies using a layer of silver sintering material, e.g., a printed and dried silver paste or a silver sintering film, as shown in the inset in FIG. 19A. The silver sintering material may be sandwiched between metallization stacks on the surfaces to be sintered. The metallization stacks may contain an adhesion layer, barrier layer, and bond layer with the bond layer facing the sintering paste or sinter film. The adhesion layer for the diamond-containing dies may be titanium, titanium carbide, chromium, or chromium carbide. The barrier layer on the diamond-containing dies may be titanium, titanium nitride, titanium tungsten, tungsten, tungsten nitride, tantalum, tantalum nitride, molybdenum, nickel, or cobalt. The bond layer may be silver, copper, or gold. The adhesion layer for the silicon dies may be titanium, tantalum, or nickel-based. The barrier layer on the silicon dies may be titanium, titanium nitride, titanium tungsten, tungsten, tungsten nitride, tantalum, tantalum nitride, molybdenum, nickel, or cobalt. The bond layer may be silver, copper, or gold. Such layers may be deposited by any suitable deposition process, such as physical vapor deposition, plating, or chemical vapor deposition. A similar sintering material and metallization stack may be similarly applied to the other side of the diamond-containing dies to facilitate attachment to a wafer. However, this is optional and other bonding materials and/or bonding processes may be used to attach the die structures to the wafer. It is noted that if the semiconductor dies in each die structure are of a common nominal thickness and two or more of the diamond-containing dies vary in thickness there will be a variation in height of the die structures. By way of example, and not by way of limitation, the diamond-containing dies may be nominally ˜300 μm with a thickness variation of 10-50 μm. The heatsink-side dies may be ˜425 μm. The bondline thickness between the semiconductor dies and the diamond-containing dies may be 20-30 μm.

As may be seen in FIG. 19A, two or more diamond-containing dies in the die structures are of different thickness. At the stage of processing depicted in FIG. 19A, the die structures 1801 have not yet been bonded to a wafer. In some implementations, the die structures may be sorted according to diamond-containing die thickness for placement on the wafer in a desired order. In some implementations, the die structures may be sorted according to the die structure thickness for placement on the wafer in a desired order. For example, the die structures 1801 may be arranged for placement on the wafer in order of increasing diamond-containing die thickness from one side of the wafer to another. Alternatively, the die structures may be arranged for placement on the wafer in order of increasing diamond-containing die thickness from a center of the wafer to an edge of the wafer or from an edge of the wafer to a center of the wafer. In some implementations, the die structures may be arranged so that die structures with diamond-containing dies 1901 of a given thickness range are placed on the same wafer. The diamond-containing die 1901 and heatsink-side (e.g., semiconductor) die 1903 in each die structure 1801 may have substantially the same footprint. As used herein, substantially the same means the same to within processing tolerances.

Turning to FIG. 19B, each of the individual die structures 1802 may be placed on a wafer 1802 for bonding in the desired order. The die structures may be placed such that there are gaps between adjacent die structures. The wafer 1802 may be of a standard material, a standard thickness and a standard lateral size and shape used in the semiconductor industry. By way of example, but not by way of limitation, the wafer 1802 may be a silicon wafer nominally 300 millimeters in diameter with a thickness of 750 to 775 micrometers. The process used to bond the die structures to the wafer may accommodate for the roughness of the surface of the diamond-containing die that is bonded to the wafer surface. By way of example, and not by way of limitation, rough SCD dies may be bonded to a silicon wafer using a layer of silver sintering material, as shown in the inset in FIG. 19B. The bondline thickness between the diamond-containing dies and the wafer may be 20-30 μm.

Referring again to FIG. 18, the reconstituted wafer product may further include perimeter dies 1805 bonded to the wafer 1802 at one or more edge portions of the wafer. The perimeter dies may be shaped to fit into edge portions of the wafer that do not contain any of the die structures 1801 without extending beyond a perimeter of the wafer 1802. The perimeter dies 1805 may be made of a material compatible with semiconductor processing, e.g., planarization and dicing. By way of example, and not by way of limitation, the perimeter dies 1805 may be made of silicon. The perimeter dies and die structures may be placed on the wafer such that there are gaps between adjacent perimeter dies and each other and between perimeter dies and adjacent die structures. The perimeter dies may be of a common nominal thickness. The perimeter dies 1805 may be bonded to the wafer 1802 using the same type of process used to bond the die structures 1801 to the wafer or any suitable bonding process.

After the die structures 1801 and perimeter dies 1805 have been bonded to the wafer 1802, gaps between adjacent perimeter dies and each other and between perimeter dies and adjacent die structures may be filled with a gap-filling material 1812 that is compatible with semiconductor fabrication processes, such as planarization. The gap-filling material may be any of a number of typical 3D hetero-integration materials, e.g., molding compounds, in addition to cross-linkable adhesives, thermally cured adhesives, photo-cured adhesives, thermoplastics, and the like. The gap-filling material 1812 may cover the top surfaces of the die structures 1801 and perimeter dies 1805, as shown in FIG. 19C. The resulting reconstituted wafer product 1800C may then be planarized, e.g., by grinding, to bring the die structures 1801 and perimeter dies 1805 to a common height within manufacturing tolerances, as shown in FIG. 19D.

In alternative implementations, the perimeter dies may be replaced with a gap filler of any of the types described herein. Furthermore, in some implementations, the (logic-facing) wafer may be a pocketed wafer of the type shown in FIG. 12A, FIG. 12D or FIG. 12E and described hereinabove. The pockets may be made sufficiently deep that the perimeter of the (logic-facing) pocketed wafer acts as the perimeter dies 1805 shown in FIG. 19A to FIG. 19F. Alternatively, instead of perimeter dies, gap fillers, or a pocketed wafer, a through-hole wafer may be used, described hereinabove, to fill the space around the die structures near the wafer perimeter.

In some implementations, logic dies may be fabricated at the logic side of the reconstituted wafer. In some implementations, logic dies or wafers are fabricated for bonding to the logic side of the reconstituted wafer. Prior to fabricating such logic dies, the logic-side wafer may be thinned, as depicted in FIG. 19D, e.g., via a grinding process, resulting in a thinned logic-side wafer 1802′. In some implementations, the logic-side wafer may be thinned so that the resulting thinned wafer is 1-150 micrometers (μm) in thickness. The logic-side surface may be polished to a desired smoothness. In some implementations, a device layer or wafer of semiconductor material may be deposited, grown, e.g., by epitaxy, attached, e.g., by silicon-on-insulator (SOI) processes or plasma assisted bonding, or otherwise formed on the surface of the logic-side wafer and the logic structures may be fabricated on or in this layer or wafer.

FIG. 19E schematically illustrates the reconstituted wafer product with logic structures 1803 formed from a device layer on the logic side of the wafer 1802. The logic structures may be formed by a sequence of processing steps, such as lithography, etch, deposition, planarization, and the like. The logic structures 1803 may be formed on the wafer 1802 as individual logic dies at locations that correspond to locations of the die structures 1801. Each die structure and its corresponding logic die may have substantially the same footprint. In some implementations, it may be desirable for the die structures to be slightly larger than the corresponding logic dies to facilitate dicing. As used herein, slightly larger means larger by an amount greater than processing tolerances. The inset in FIG. 19E shows one non-limiting example of a possible configuration of layers in the reconstituted wafer product at this stage of manufacture. Starting from the top of the inset, a lower portion of the diamond-containing die may be seen followed by sinter bond material, and wafer material, e.g., semiconductor, such as Si. In some implementations a device wafer made of semiconductor material may be bonded to the wafer material and the logic structures may be formed on or in the device wafer. In some such implementations there may be an optional bonding layer between the wafer material and the device wafer. The type of bonding material depends on the bonding process used. For example a dielectric bonding layer may be used for plasma assisted bonding (PAB). Front-end-of-line (FEOL) logic structures (e.g., transistors, capacitors, resistors) are formed in the next layer(s) followed by back-end-of-line, (BEOL) structures including wiring and interconnects. In some implementations, it may be desirable to attach a temporary carrier wafer 1906 to the BEOL surface of the device wafer after device fabrication is complete in order to protect the logic dies during subsequent processing, such as dicing. In such cases, an adhesive layer may be used to attach a temporary carrier, e.g., glass or silicon. The adhesive layer may optionally include solder bumps or copper pillars attached to the device wafer to facilitate subsequent external electrical contacts.

Once logic die fabrication is complete, the finished reconstituted wafer product 1800 may be diced into individual die stacks 1807, each containing a die structure 1801 and a logic die 1803 as depicted in FIG. 19F. The die structures 1801 and perimeter dies may be covered with a dicing tape 1904 for this process. Dicing may be done at dicing locations 1909, e.g., by laser dicing through the die structures near their edges, as opposed to at the location of the gap filler to ensure identical sizes throughout the die stack. Also, dicing in this way allows use of a gap fill material that need not be compatible with being diced through, e.g., with a laser.

In one non-limiting example the die structures 1801 may be built by die-to-die sintering of diamond-containing dies to heatsink-facing single crystal silicon dies, e.g., by collective dies-to-dies sintering. In some implementations, the diamond-containing dies may be sintered to a 300 mm silicon wafer, and subsequently the silicon wafer may be diced into individual die structures. Subsequently the die structures may be placed onto a 300 mm silicon wafer and sintered to the logic-facing wafer. Gaps may be filled by a molding compound, e.g., by overmolding. The molding compound may be a granular, powdered, sheet, or liquid molding compound. Molding may be performed by compression molding or transfer molding. The molding compound may provide high adhesion, low shrinkage, optimal CTE and Young's Modulus, and low warpage. The reconstituted SCD wafer may be planarized and thinned on the heatsink side, and thinned and smoothened on the logic side. The reconstituted wafer may be fabricated to meet stringent advanced bonding requirements, e.g., with tight bow, TTV, and particle requirements. The metallization stack on the silicon wafer and silicon dies may be 100 nm-titanium (Ti)/100 nm-Nickel (Ni)/2 μm-Silver (Ag), or may be 50 nm-Ti/100 nm-Tungsten (W)/0.5 μm-Ag. The metallization stack on the SCD dies may be 100 nm-Ti/100 nm-Ni/2 μm-Ag, or may be 50 nm-Ti/0.5 μm-Ag. The sinter material may be applied by printing followed by drying. In some implementations, the sinter material may be applied by a die-to-film transfer process of pre-fabricated sinter films. The sintering material may be silver. The sintering material may be copper. The reconstituted wafer may include fiducials or alignment marks to facilitate alignment with the logic dies. The fiducials may be located on the logic facing wafer 1802. The fiducials may be formed near the perimeter of the logic facing wafer. The die containing diamond in each die structure may be sinter bonded to either the heatsink-side die, the logic-facing wafer, or both with a copper-containing sinter material.

In another non-limiting example, the diamond-containing dies 1901 may be attached to the logic facing wafer 1802 by laser assisted bonding, e.g., by melting the silicon near the SCD die surface. Subsequently the assembly of SCD dies on the logic facing wafer may be metalized, e.g., with 100 nm-Ti/100 nm-Ni/2 um-Ag or 50 nm-Ti/100 nm-W/0.5 um-Ag. Metalized heatsink-facing dies, e.g., single crystal silicon dies, may be sintered to the assembly of SCD dies on the logic facing wafer. Gaps may be filled by a molding compound, e.g., a granular, powder, sheet, or liquid molding compound. The molding compound may be applied by compression molding, or transfer molding. The molding compound may provide high adhesion, low shrinkage, optimal CTE and Young's Modulus, and low warpage. The reconstituted SCD wafer may be planarized and thinned on the heatsink side, and thinned and smoothened on the logic side. The reconstituted wafer may be fabricated to meet stringent advanced bonding requirements, e.g., with tight bow, TTV, and particle requirements. The reconstituted wafer may include fiducials or alignment marks to facilitate alignment with the logic dies. The fiducials may be located on the logic facing wafer. The fiducials may be formed near the perimeter of the logic facing wafer.

In yet another non-limiting example, the diamond-containing dies 1901 may be attached to the logic facing wafer by laser assisted bonding, e.g., by melting the silicon near the SCD die surface. Subsequently the assembly of SCD dies on the logic facing wafer may be metalized, e.g., with 100 nm-Ti/100 nm-Ni/2 um-Cu or 50 nm-Ti/100 nm-W/0.5 um-Cu. Bond layers other than copper to bond to zinc may be nickel, silver, gold, tin, or titanium. Metalized heatsink-facing dies, e.g., single crystal silicon dies, may be zinc bonded to the assembly of SCD dies on the logic facing wafer. The zinc may be applied by thin sheets. The zinc may be applied by thin films. Both the SCD dies and heatsink-facing dies may be deposited by an adhesion layer, barrier layer, and zinc film. Deposition may be by physical vapor deposition or plating. Gaps may be filled by a molding compound, e.g., a granular, powder, sheet, or liquid molding compound. The molding compound may be applied by compression molding, or transfer molding. The molding compound may provide high adhesion, low shrinkage, optimal CTE and Young's Modulus, and low warpage. The reconstituted SCD wafer may be planarized and thinned on the heatsink side, and thinned and smoothened on the logic side. The reconstituted wafer may be fabricated to meet stringent advanced bonding requirements, e.g., with tight bow, TTV, and particle requirements. The reconstituted wafer may include fiducials or alignment marks to facilitate alignment with the logic dies. The fiducials may be located on the logic facing wafer. The fiducials may be formed near the perimeter of the logic facing wafer.

During the manufacture of the reconstituted wafer and integration of the reconstituted wafer with the logic wafer various carriers (e.g., glass or silicon), various temporary adhesives, and various debonding methods (e.g., laser debonding, thermo-mechanical debonding, chemical debonding, etc.) may be used. The carriers may be used to minimize warpage during processing. The carriers may be used to increase yield, e.g., by reducing cracking or delamination.

The reconstituted wafer 1800 may be designed to facilitate integration with existing advanced chip packaging process flows, e.g., CoWoS packaging. The reconstituted wafer may be designed to facilitate integration of direct liquid cooling on a chip level, e.g., microchannel cooling or jet impingement cooling. In some implementations, the heatsink-side die may be in direct contact with a cooling liquid in a cooled final device package. In some implementations, the heatsink-side die may be omitted and the diamond-containing die may be in direct contact with a cooling liquid in a cooled final device package. By way of a non-limiting example, the reconstituted wafer may be designed for jet impingement cooling on the die structure with single crystal silicon facing the jet impingement. The reconstituted wafer may be designed for jet impingement cooling on the die structure with copper facing the jet impingement. The reconstituted wafer may be designed for jet impingement cooling on the die structure with silicon carbide facing the jet impingement. The reconstituted wafer may be designed for jet impingement cooling on the die structure with SCD facing the jet impingement. The surface exposed to the jet impingement may be patterned or coated for improved cooling efficiency and reliability.

The thickness of the logic facing silicon wafer 1802 and heat sink facing silicon dies 1903 may be adjusted at various stages of the reconstituted wafer manufacturing process. The silicon wafer and dies may start at standard thickness (e.g., ˜775 μm), and be planarized, and thinned after all bonding and gap filling. In some implementations, the silicon wafer or dies may start at a thickness closer to the final product thickness, or may be partially or completely thinned prior to gap filling. The thickness of the silicon wafer may start at a thickness significantly thicker than standard wafer thickness. The silicon may be thinned by abrasive techniques, e.g., grinding, lapping, and polishing. In some implementations, the silicon may be thinned by wet or dry etching, e.g., with an etch stop layer inside the silicon near the diamond-containing dies. In some implementations, the silicon may be thinned by (IR) laser debonding. In yet another non-limiting example, the silicon may be thinned by SmartCut. In yet another non-limiting example, the silicon may be thinned by spalling. It should be understood that thinning may be performed by a combination of two or more of the aforementioned methods.

Dicing may be performed through the die structures after bonding to the logic wafer. Dicing may be performed through the silicon of the die structures, yet around the diamond-containing dies, e.g., prior to or after bonding to the logic dies or logic wafer. Dicing may be performed around the die structures, prior to or after bonding to the logic dies or logic wafer. Dicing through the stack of the bonded reconstituted wafer to logic wafer may be a one-step or multi-step dicing process. Dicing may first be performed by plasma dicing through the thinned logic wafer, followed by dicing through the reconstituted wafer. After dicing the logic die may be smaller, of the same size, or larger than the diamond-containing die.

The gaps may be less than 100 micrometers wide, and 1, 100 micrometers high prior to thinning. The gaps may be less than 60 micrometers wide. The gaps may be filled by compression or transfer molding. The gaps may be filled by granular, powdered, sheet, or liquid molding compound. The gaps may be filled by low-CTE polyimides or polyimide precursors or the gap filler may include polyimide. The gaps may be filled by an epoxy or an epoxy containing material. In some implementations, the gap-filling material may include an epoxy mixed with other materials that modify the physical properties, e.g., Young's Modulus of the resulting material. The gaps may be filled by low-CTE liquid crystal polymers or the gap filler may include liquid crystal polymers. The gaps may be filled by screen or stencil printing, jet printing, coating, or dispensing. The gaps may be filled by photo-sensitive dielectrics. The curing or annealing of the gap filler may be performed on a wafer level, die level, or gap level. Local curing or annealing may be performed by masking (e.g., UV cure) or laser-assisted heating. The gap fillers may include adhesives, sealants, molding compounds, polymers, thermoplastics, epoxies, photoresists, benzocyclobutene (BCB) derivatives, spin-on photo-dielectrics, silicones, or polyimides. Similarly, photo-dielectric, spin-on glass or polymer-derived ceramics may be used, e.g., polysilazane derivatives (e.g., polyborosilazane), polysiloxane derivatives, polysilane derivatives (e.g., polycarbosilane), polysilsesquioxanes, polysilsesquiazanes, polysilylcarbodiimides, etc. For solvent-based materials or high shrinkage materials, the gaps may be filled by a repeated cycle of deposition, drying, and curing. The gaps at the perimeter may be filled with the gap filler. The gaps at the perimeter may be filled by semiconductor dies, e.g., silicon or silicon carbide dies. A dam material may be used at the perimeter. The gaps at the perimeter may be filled by a combination of two or more of the following: semiconductor dies, diamond-containing dies, gap fillers, or dam materials.

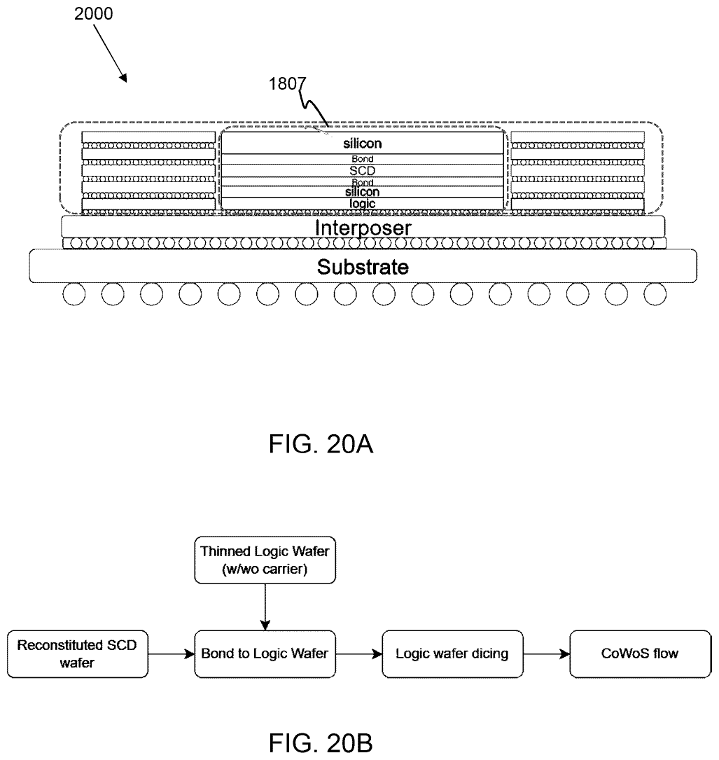

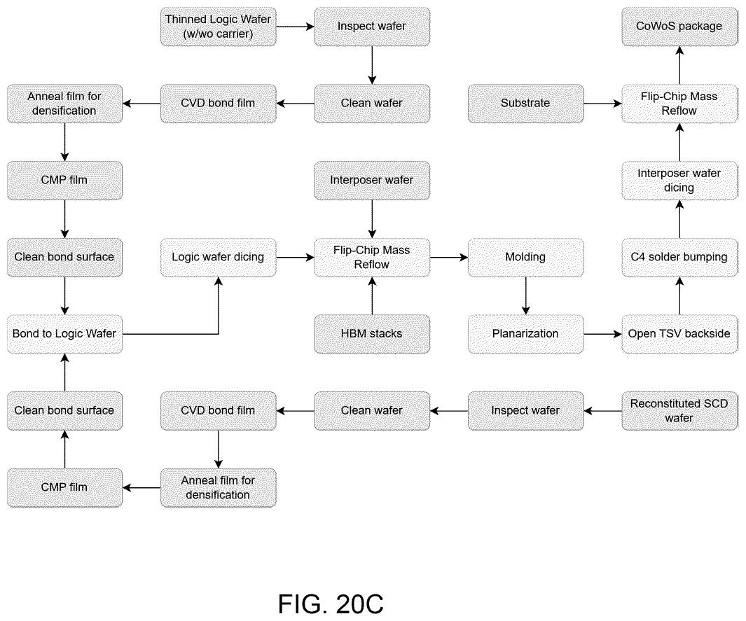

The resulting reconstituted wafer product die stacks 1807 with die structures 1801 and logic devices 1803 may be integrated into a device package 2000 containing two or more logic dies. By way of example, and not by way of limitation, the device package may contain two or more of the following either next to one another or on top of one another: high bandwidth memories, memory dies, logic dies, compute dies, accelerator dies, ASIC dies, backside power delivery dies, SRAM dies. In some implementations, the die stacks 1807 may be integrated into a CoWoS package, e.g., as depicted in FIG. 20A. In some implementations, the reconstituted wafer with die structures on a logic-facing wafer may be integrated into an advanced chip package with backside power delivery. In some implementations, the reconstituted wafer die stacks with die structures on a logic-facing wafer may be integrated into an advanced chip package with active die stacking. In some implementations, the reconstituted wafer with die structures on a logic-facing wafer may be integrated into an advanced chip package with one or more of the following: HBM stacks, logic dies, compute dies, memory dies, backside power delivery dies, SRAM dies, accelerator dies, ASIC dies, tensor core dies, passive dies (e.g., for heat sinking), etc.

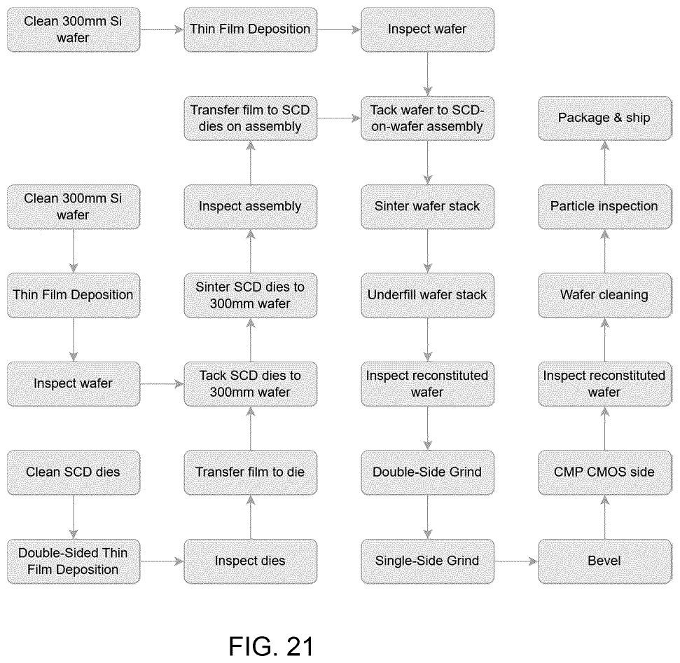

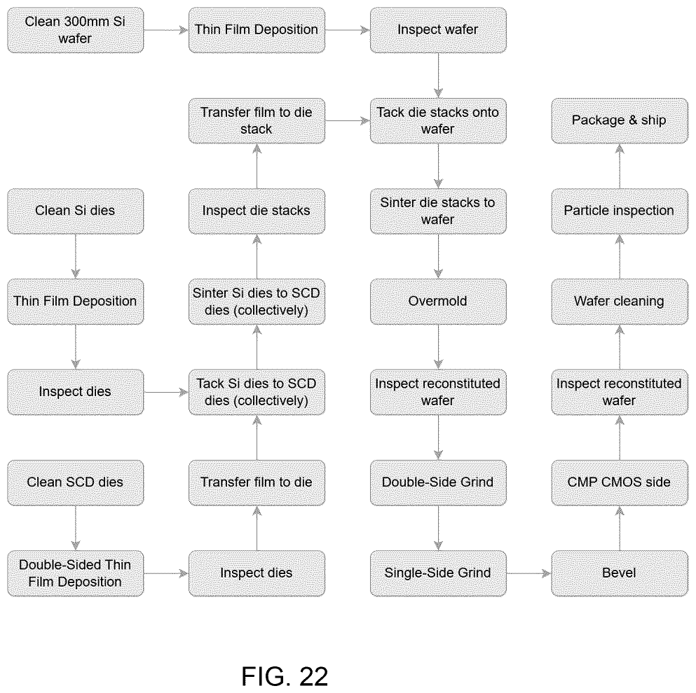

As seen in FIG. 20B, the general process flow involves bonding a reconstituted wafer product to a logic wafer, dicing the resulting bonded logic wafer and reconstituted wafer product and subjecting the resulting diced wafers to conventional CoWoS processing. FIG. 20C shows a general process flow bonding the reconstituted wafer to the logic wafer by PAB. Differences between process flow with a reconstituted wafer product having, e.g., diamond-containing dies sandwiched between two silicon wafers and process flow with die structures having individual die structures with diamond-containing dies bonded to silicon dies on one logic-facing wafer may be appreciated by comparing FIG. 21 to FIG. 22.

As seen in FIG. 21, manufacturing of a reconstituted wafer having diamond-containing dies sandwiched between two silicon wafers may involve sintering two wafers via intermediate diamond-containing dies. This may cause an increased requirement on thickness variation between diamond-containing dies, and an increased sensitivity to wafer cracking. Furthermore, this may require adding gap filler via an underfill process over an area of 300 mm, unless one or more openings are made in one or both wafers after sintering and prior to gap filling. In the process shown in FIG. 22, by contrast, die structures are sintered to one 300 mm wafer, instead of sandwiched between two wafers. So, one silicon wafer is replaced by silicon dies. This results in less stringent thickness variation requirements for the die structures. Furthermore, gap filling may be performed by traditional molding techniques, e.g., overmolding, since a planarization step follows the gap filling step. This significantly simplifies the manufacturing flow and process requirements.

Aspects of the present disclosure allow the use of rough diamond-containing dies of varying thickness through use of sinter bonding and laser assisted bonding. Use of individual die structures with diamond-containing dies, heatsink-side dies and sinter bonding allows for die-level control of thickness variations. Height matching may be achieved through grinding the heatsink-side dies.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature described herein, whether preferred or not, may be combined with any other feature described herein, whether preferred or not. In the claims that follow, the indefinite article “A”, or “An” refers to a quantity of one or more of the items following the article, except where expressly stated otherwise. The appended claims are not to be interpreted as including means-plus-function limitations, unless such a limitation is explicitly recited in a given claim using the phrase “means for.”

1. A reconstituted wafer product, comprising:
a plurality of die structures bonded to a wafer in a manner that provides a thermally conductive connection between the wafer and the plurality of die structures, wherein each die structure of the plurality of the die structures includes a die containing diamond bonded to a heatsink-side surface of the wafer, wherein two or more dies containing diamond in the plurality of die structures are of different thickness, wherein the wafer is compatible with semiconductor processing.

2. The reconstituted wafer product of claim 1, wherein the two or more dies containing diamond in the plurality of die structures that are of different thickness increase in thickness from one side of the wafer to another.

3. The reconstituted wafer product of claim 1, wherein the two or more dies containing diamond in the plurality of die structures that are of different thickness increase in thickness from a center of the wafer to an edge of the wafer.

4. The reconstituted wafer product of claim 1, wherein the two or more dies containing diamond in the plurality of die structures that are of different thickness increase in thickness from an edge of the wafer to a center of the wafer.

5. The reconstituted wafer product of claim 1, further comprising one or more perimeter dies bonded to the wafer at one or more edge portions of the wafer.

6. The reconstituted wafer product of claim 5, wherein the one or more perimeter dies are made of silicon.

7. The reconstituted wafer product of claim 5, wherein the one or more perimeter dies are shaped to fit into edge portions of the wafer that do not contain any of the die structures of the plurality of die structures without extending beyond a perimeter of the wafer.

8. The reconstituted wafer product of claim 5, wherein top surfaces of the one or more perimeter dies and top surfaces of the die structures in the plurality of die structures are at substantially the same height above a top surface of the wafer.

9. The reconstituted wafer product of claim 1, wherein the wafer is a pocketed wafer having a plurality of pockets, wherein each die structure of the plurality of die structures is disposed in a corresponding pocket of the plurality of pockets.

10. The reconstituted wafer product of claim 1, wherein the wafer is a pocketed wafer having a common pocket, wherein each die structure of the plurality of die structures is disposed in the common pocket.

11. The reconstituted wafer product of claim 1, wherein the product includes a through-hole wafer.

12. The reconstituted wafer product of claim 1, wherein the plurality of die structures are integrated onto a temporary carrier.

13. The reconstituted wafer product of claim 1, wherein the wafer is a semiconductor wafer.

14. The reconstituted wafer product of claim 13, wherein the semiconductor wafer is between 1 micron and 150 microns in thickness.

15. The reconstituted wafer product of claim 13, wherein a plurality of logic dies are formed at a logic side of the wafer, wherein locations of the logic dies at the logic side of the wafer correspond to locations of die structures on the heatsink side of the wafer.

16. The reconstituted wafer product of claim 15, wherein a footprint of the die structures corresponds to a footprint of the logic dies.

17. The reconstituted wafer product of claim 15, wherein a footprint of the die structures is slightly larger than a footprint of the logic dies.

18. The reconstituted wafer product of claim 15, wherein the wafer is 50 microns or less in thickness.

19. The reconstituted wafer product of claim 1, wherein the die containing diamond in one or more die structures in the plurality of die structures is made of single crystal diamond.

20. The reconstituted wafer product of claim 19, wherein the die containing diamond in each die structure in the plurality of die structures is a die made of single crystal diamond.

21. The reconstituted wafer product of claim 19, wherein the die made of single crystal diamond is characterized by a lateral dimension of 1 centimeter or greater.

22. The reconstituted wafer product of claim 1, wherein the die containing diamond in one or more die structures in the plurality of die structures is a polycrystalline diamond die.

23. The reconstituted wafer product of claim 1, wherein each die structure of the plurality of the die structures includes a heatsink-side die bonded to a die containing diamond, wherein the die containing diamond is stacked between the wafer and the heatsink-side die, wherein the heatsink-side die is compatible with semiconductor processing.

24. The reconstituted wafer product of claim 23, wherein the die containing diamond in each die structure in the plurality of die structures is sinter bonded to either the heatsink-side die, the wafer, or both.

25. The reconstituted wafer product of claim 23, wherein the die containing diamond in each die structure in the plurality of die structures is laser bonded to either the heatsink-side die, the wafer, or both.

26. The reconstituted wafer product of claim 23, wherein the die containing diamond in each die structure in the plurality of die structures is bonded via zinc to either the heatsink-side die, the wafer, or both.

27. The reconstituted wafer product of claim 23, wherein the die containing diamond in each die structure in the plurality of die structures is bonded via aluminum to either the heatsink-side die, the wafer, or both.

28. The reconstituted wafer product of claim 1, further comprising a gap fill material in spaces between adjacent die structures.

29. The reconstituted wafer product of claim 1, further comprising a gap fill material in spaces between adjacent die structures of the plurality of die structures and in spaces between the plurality of die structures and a perimeter of the wafer.

30. The reconstituted wafer product of claim 29, where the gap fill material is a molding compound.

31. The reconstituted wafer product of claim 29, where the gap fill material includes an epoxy.

32. The reconstituted wafer product of claim 29, where the gap fill material includes a polyimide.

33. The reconstituted wafer product of claim 29, where the gap fill material includes a liquid crystal polymer.

34. The reconstituted wafer product of claim 29, where the gap fill material includes one of the following: a photo-dielectric, spin-on glass, polymer-derived ceramic, copper, or zinc.

35. The reconstituted wafer product of claim 29, where the gap fill material is applied by compression molding, transfer molding, printing, coating, or dispensing.

36. The reconstituted wafer product of claim 24, wherein the die containing diamond in each die structure in the plurality of die structures is sinter bonded to the heatsink-side die, the wafer, or both with a silver-containing sinter material.

37. The reconstituted wafer product of claim 24, wherein the die containing diamond in each die structure in the plurality of die structures is sinter bonded to either the heatsink-side die, the wafer, or both with a copper-containing sinter material.

38. The reconstituted wafer product of claim 1, wherein one or more die structures of the reconstituted wafer product is integrated into a device package containing two or more logic dies.

39. The reconstituted wafer product of claim 38, wherein the device package contains two or more of the following either next to one another or on top of one another: high bandwidth memories, memory dies, logic dies, compute dies, accelerator dies, ASIC dies, backside power delivery dies, SRAM dies.

40. The reconstituted wafer product of claim 1, wherein the thermal resistance of the reconstituted wafer product is less than 2 mm²-K/W when integrated into a final device package.

41. The reconstituted wafer product of claim 1, wherein the thermal resistance of the reconstituted wafer product is less than 1 mm²-K/W when integrated into a final device package.

42. The reconstituted wafer product of claim 1, wherein the thermal resistance of the reconstituted wafer product is less than 0.5 mm²-K/W when integrated into a final device package.

43. The reconstituted wafer product of claim 1, wherein the die containing diamond in one or more of the die structures in the plurality of die structures is a composite diamond die containing diamond and a metal, wherein the metal includes one or more of the following: copper, silver, gold, aluminum, and zinc.

44. The reconstituted wafer product of claim 1, wherein the die containing diamond in one or more of the die structures in the plurality of die structures has a roughness on at least one side of at least 2 nanometers.

45. The reconstituted wafer product of claim 1 wherein the dies containing diamond in the plurality of die structures vary in thickness by more than 5 micrometers.

46. The reconstituted wafer product of claim 1, wherein the wafer is characterized by lateral dimensions corresponding to those of a standard-sized semiconductor wafer.

47. The reconstituted wafer product of claim 1, wherein the wafer is a silicon wafer.

48. The reconstituted wafer product of claim 1, wherein the wafer is characterized by a thickness of less than 100 micrometers.

49. The reconstituted wafer product of claim 1, wherein the wafer is characterized by a thickness of less than 10 micrometers.

50. The reconstituted wafer product of claim 1 wherein the die containing diamond in one or more of the die structures in the plurality of die structures is attached to the wafer, the heatsink-side die, or both, by either: thermocompression bonding (TCB), soldering, eutectic bonding, transient liquid phase bonding (TLPB), sintering, laser assisted bonding, surface activated bonding (SAB), atomic diffusion bonding (ADB), plasma assisted bonding (PAB), ultrasonic bonding (UB), brazing, or adhesive bonding.

51. The reconstituted wafer product of claim 1, wherein the die containing diamond in one or more dies structures in the plurality of dies structures is attached to the wafer using a bond material.

52. The reconstituted wafer product of claim 23, wherein the die containing diamond in one or more dies structures in the plurality of dies structures is attached to the heatsink-side die using a bond material.

53. The reconstituted wafer product of claim 52, wherein the bond material includes copper, silicon, germanium, silver, zinc, aluminum, or a dielectric.

54. The reconstituted wafer product of claim 52, wherein the bond material includes silver.

55. The reconstituted wafer product of claim 52, wherein the bond material includes titanium, and either silver, gold, or copper.

56. The reconstituted wafer product of claim 1, wherein the die structures of the plurality of die structures are placed on the wafer near each other based on matching die thickness resulting in a gradual change in die thickness from wafer side to side, or wafer center to edge.

57. The reconstituted wafer product of claim 23, wherein the heatsink-side die contains silicon, copper, or silicon carbide.

58. The reconstituted wafer product of claim 1, wherein the heatsink-side die is in direct contact with cooling liquid for the cooled final device package.

59. The reconstituted wafer product of claim 1, wherein the diamond-containing die is in direct contact with cooling liquid in a cooled final device package.

60. A method for semiconductor device processing with a reconstituted wafer product, comprising:
forming a plurality of die structures by bonding a plurality of dies containing diamond to a corresponding plurality of heatsink-side dies, wherein two or more dies containing diamond in the plurality of die structures are of different thickness, whereby each die structure of the plurality of the die structures includes a die containing diamond bonded to a heatsink-side die;
attaching the plurality of die structures to a wafer in a manner that provides a thermally conductive connection between the wafer and the plurality of die structures by bonding the die containing diamond in each die structure of the plurality of die structures to a heatsink-side surface of the wafer.

61. The method of claim 60, wherein bonding the plurality of dies containing diamond to the corresponding plurality of heatsink-side dies includes sinter bonding one or more dies containing diamond of the plurality of dies containing diamond to a corresponding one or more heatsink-side dies of the plurality of heatsink-side dies.

62. The method of claim 60, wherein attaching the plurality of die structures to the wafer includes sinter bonding the die containing diamond in one or more die structures of the plurality of die structures to the surface of the wafer.

63. The method of claim 60, wherein attaching the plurality of die structures to the wafer includes laser assisted bonding the die containing diamond in one or more die structures of the plurality of die structures to the surface of the wafer.

64. The method of claim 60, wherein bonding the plurality of dies containing diamond to the corresponding plurality of heatsink-side dies includes laser assisted bonding one or more dies containing diamond of the plurality of dies containing diamond to a corresponding one or more heatsink-side dies of the plurality of heatsink-side dies.

65. The method of claim 60, further comprising filling spaces between adjacent die structures and in spaces between the plurality of die structures and a perimeter of the wafer.

66. The method of claim 60, further comprising bonding one or more perimeter dies to the surface of the wafer at one or more edge portions of the wafer.

67. The method of claim 66, further comprising filling spaces between adjacent die structures and in spaces between the plurality of die structures and between one or more die structures of the plurality of die structures and the one or more perimeter dies, and in spaces between the one or more perimeter dies.

68. The method of claim 67, further comprising lapping, grinding, or polishing the heat-sink side dies and perimeter dies to a common height.

69. The method of claim 60, further comprising forming a plurality of logic dies at a logic side of the wafer at locations corresponding to locations of the die structures.

70. A method for semiconductor device processing with a reconstituted wafer product, comprising:
bonding a plurality of dies containing diamond to a corresponding plurality of locations on a heatsink side surface of a wafer, wherein two or more dies containing diamond in the plurality of dies containing diamond are of different thickness;
wherein the plurality of dies containing diamond are bonded to the wafer in a manner that provides a thermally conductive connection between the wafer and the plurality of dies containing diamond.

71. The method of claim 70, further comprising forming a plurality of logic dies at a logic side of the wafer, wherein locations of the logic dies at the logic side of the wafer correspond to a plurality of locations of the dies containing diamond on the heatsink side of the wafer.
